(19) United States
(12) Patent Application Publication
(10) Pub. No.: US 2024/0215448 A1
(43) Pub. Date: Jun. 27, 2024

(54) ORGANIC MOLECULES FOR OPTOELECTRONIC DEVICES

(71) Applicant: Samsung Display Co., Ltd., Yongin-si, Gyeonggi-do (KR)

(72) Inventor: Sebastian DÜCK, Heidelberg (DE)

(21) Appl. No.: 18/556,342

(22) PCT Filed: Apr. 25, 2022
(86) PCT No.: PCT/EP2022/060905

§ 371 Date: Oct. 19, 2023

(30) Foreign Application Priority Data
Apr. 23, 2021 (WO) PCT/EP2021/060703
Jan. 19, 2022 (EP) 22152274.1

(51) Int. Cl. H10K 85/60; C07F 5/02; C09K 11/02; C09K 11/06; H10K 50/11

(52) U.S. Cl. CPC H10K 85/658; C07F 5/027; C09K 11/02; C09K 11/06; C09K 2211/1007; C09K 2211/1018; H10K 50/11

(57) ABSTRACT

An organic molecule is disclosed, and an optoelectronic device including the organic molecule is disclosed. The organic molecule has a structure of Formula I, where n, m, p, and q are integers selected from 0 and 1, r is at each occurrence an integer selected from 0, 1, 2, 3 or 4; s is at each occurrence an integer selected from 0, 1, 2 or 3; t is an integer selected from 0, 1, 2, 3, or 4; u is an integer selected from 1, 2, 3, 4 or 5; wherein t+u<=5; Z is at each occurrence independently selected from the group consisting of a direct bond, CR³R⁴, C═CR³R⁴, C═O, C═NR³, NR³, O, SiR³R⁴, S, S(O) and S(O)₂; and R^{EWG} is selected from the group consisting of F, CF₃, CN, a substituted or unsubstituted C₆-C₆₀-aryl, and a substituted or unsubstituted C₂-C₅₇-heteroaryl.

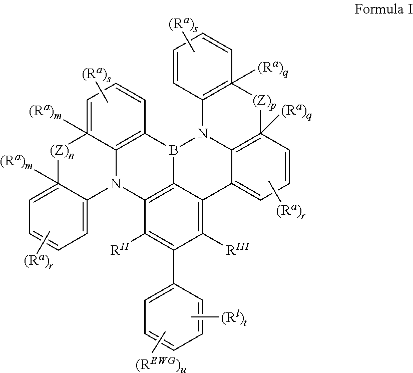

### CROSS-REFERENCE TO RELATED APPLICATIONS

This application is a U.S. National Phase Patent Application of International Patent Application Number PCT/EP2022/060905, filed on Apr. 25, 2022, which claims priority to PCT/EP2021/060703, filed on Apr. 23, 2021, and European Patent Application Number 22152274.1, filed on Jan. 19, 2022, the entire content of all of which is hereby incorporated by reference.

### BACKGROUND

### 1. Field

Embodiments of the present disclosure relate to light-emitting organic molecules and their use in organic light-emitting diodes (OLEDs) and in other optoelectronic devices.

### 2. Description of the Related Art

From among light-emitting devices, self-emissive devices have wide viewing angles, high contrast ratios, short response times, and excellent characteristics in terms of luminance, driving voltage, and response speed.

In a light-emitting device, a first electrode is located on a substrate, and a hole transport region, an emission layer, an electron transport region, and a second electrode are sequentially arranged on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. These excitons transition from an excited state to a ground state to thereby generate light.

### SUMMARY

The object of embodiments of the present disclosure is to provide molecules which are suitable for use in optoelectronic devices.

This object is achieved by embodiments of the present disclosure which provide a new class of organic molecules.

According to embodiments of the present disclosure the organic molecules are purely organic molecules, e.g., they do not contain any metal ions in contrast to metal complexes for use in optoelectronic devices.

According to embodiments of the present disclosure, the organic molecules exhibit emission maxima in the blue or sky-blue spectral range. The organic molecules exhibit emission maxima between 420 nm and 580 nm, for example, between 440 nm and 560 nm, photoluminescence quantum yields of the organic molecules according to embodiments of the present disclosure are, for example, 50% or more. The use of the molecules according to embodiments of the present disclosure in an optoelectronic device, for example an organic light-emitting diode (OLED), leads to higher efficiencies or higher color purity, expressed by the full width at half maximum (FWHM) of emission, of the device. Corresponding OLEDs have a higher stability than OLEDs with other emitter materials and comparable color. OLEDs with a light-emission layer which includes the organic molecules of embodiments of the present disclosure together with a host material, for example, with a triplet-triplet-annihilation host material, have high stabilities.

### DETAILED DESCRIPTION

An organic light-emitting molecule of embodiments of the present disclosure includes or consists of a structure of Formula I

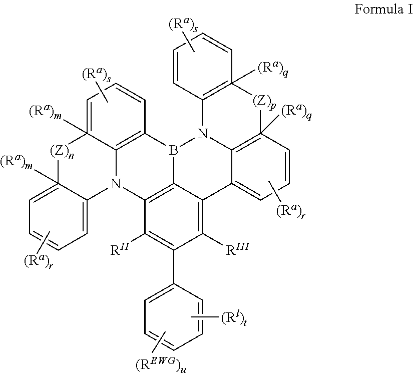

wherein
n, m, p, and q is each an integer selected from 0 and 1,
wherein n+m=1 and p+q=1;
r is at each occurrence an integer selected from 0, 1, 2, 3 or 4;
s is at each occurrence an integer selected from 0, 1, 2 or 3;
t is an integer selected from 0, 1, 2, 3, or 4;
u is an integer selected from 1, 2, 3, 4 or 5;
wherein t+u≤5, e.g., the sum of t and u is smaller or equal than 5 (1, 2, 3, 4, or 5);
Z is at each occurrence independently selected from the group consisting of a direct bond, CR³R⁴, C═CR³R⁴, C═O, C═NR³, NR³, O, SIR³R⁴, S, S(O) and S(O)₂;
R^{I}, R^{II} and R^{III} is at each occurrence independently from each other selected from the group consisting of hydrogen, deuterium, C₁-C₆-alkyl and C₆-C₁₂-aryl, which is optionally substituted with one or more C₁-C₆-alkyl substituents;
R^{EWG} is selected from the group consisting of F, CF₃, CN, a substituted or unsubstituted C₆-C₆₀-aryl, and a substituted or unsubstituted C₂-C₅₇-heteroaryl,
R^{a}, R³ and R⁴ is at each occurrence independently selected from the group consisting of: hydrogen, deuterium, N(R⁵)₂, OR⁵, Si(R⁵)₃, B(OR⁵)₂, B(R⁵)₂, OSO₂R⁵, CF₃, CN, F, Br, I,
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵;
R⁵ is at each occurrence independently from another selected from the group consisting of: hydrogen, deuterium, N(R⁶)₂, OR⁶, Si(R⁶)₃, B(OR⁶)₂, B(R⁶)₂, OSO₂R⁶, CF₃, CN, F, Br, I,
C₁-C₄₀-alkyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-alkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkenyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkynyl
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₆-C₆₀-aryl,
which is optionally substituted with one or more substituents R⁶; and
C₂-C₅₇-heteroaryl,
which is optionally substituted with one or more substituents R⁶;
R⁶ is at each occurrence independently from another selected from the group consisting of: hydrogen, deuterium, OPh, CF₃, CN, F,
C₁-C₅-alkyl,
wherein one or more hydrogen atoms are optionally, independently substituted by deuterium, CN, CF₃, or F;
C₁-C₅-alkoxy,
wherein one or more hydrogen atoms are optionally, independently substituted by deuterium, CN, CF₃, or F;
C₁-C₅-thioalkoxy,
wherein one or more hydrogen atoms are optionally, independently substituted by deuterium, CN, CF₃, or F;
C₂-C₅-alkenyl,
wherein one or more hydrogen atoms are optionally, independently substituted by deuterium, CN, CF₃, or F;
C₂-C₅-alkynyl,
wherein one or more hydrogen atoms are optionally, independently substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂, and
N(C₂-C₁₇-heteroaryl)(C₆-C₁₈-aryl);
wherein any of the substituents R^{a}, R³, R⁴, R⁵, and R⁶ may independently form a mono- or polycyclic, aliphatic, aromatic, heteroaromatic and/or benzo-fused ring system with one or more other substituent/substituents R^{a}, R³, R⁴, R⁵ and/or R⁶.

In one embodiment, R^{EWG} is selected from group A consisting of the following structures:

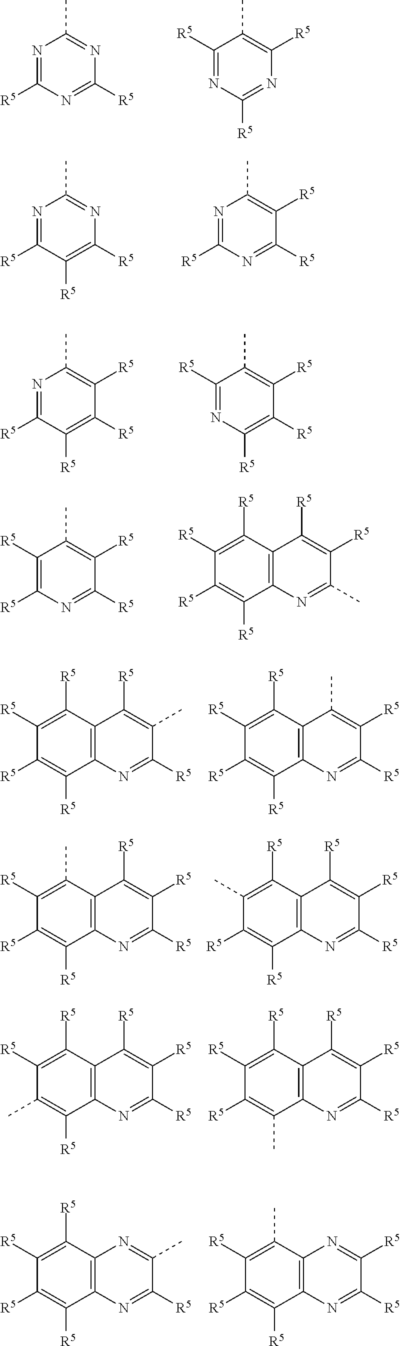

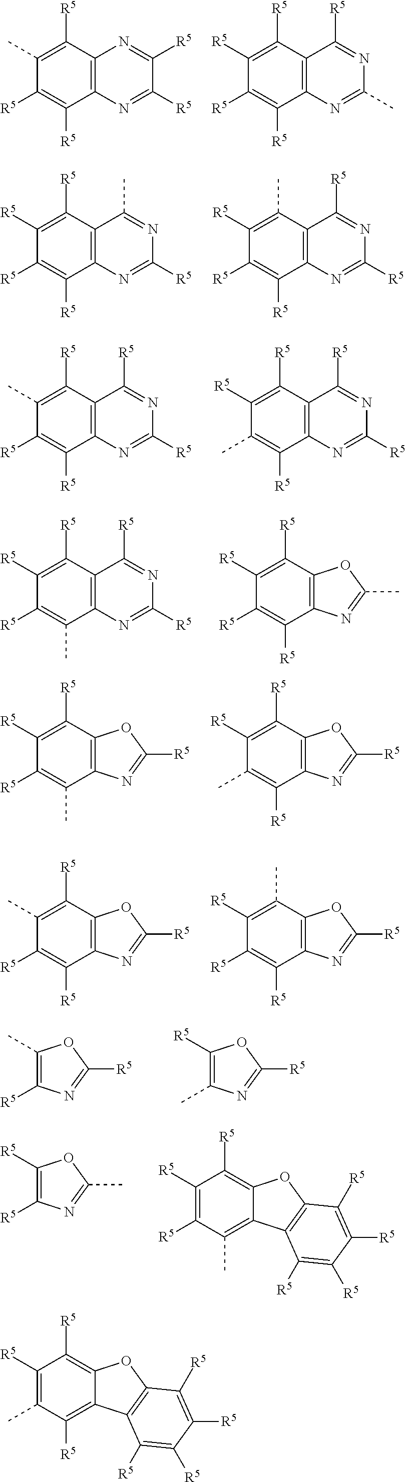

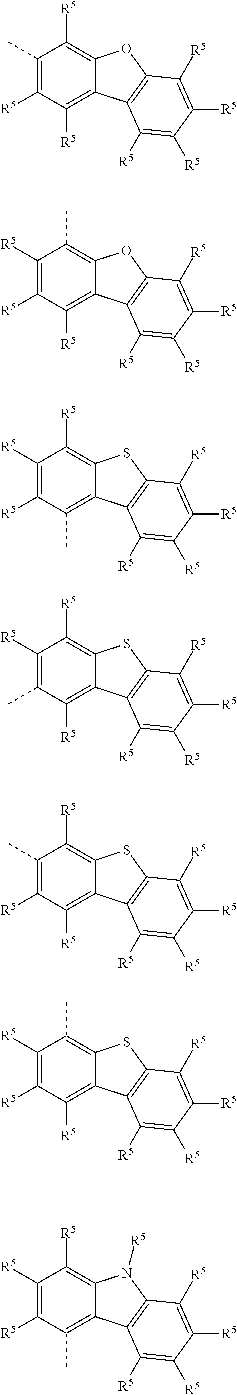

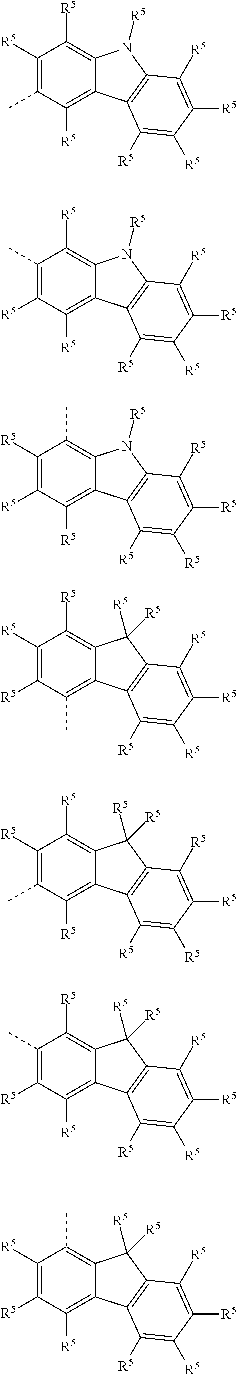

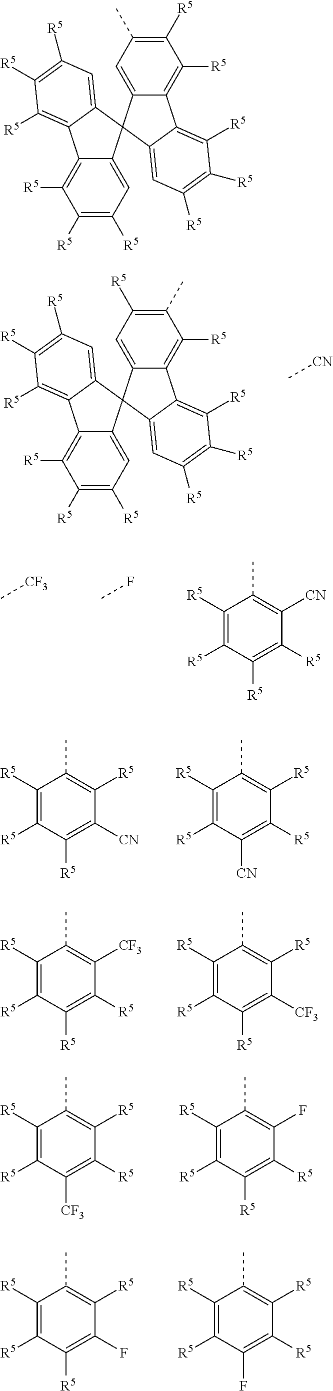

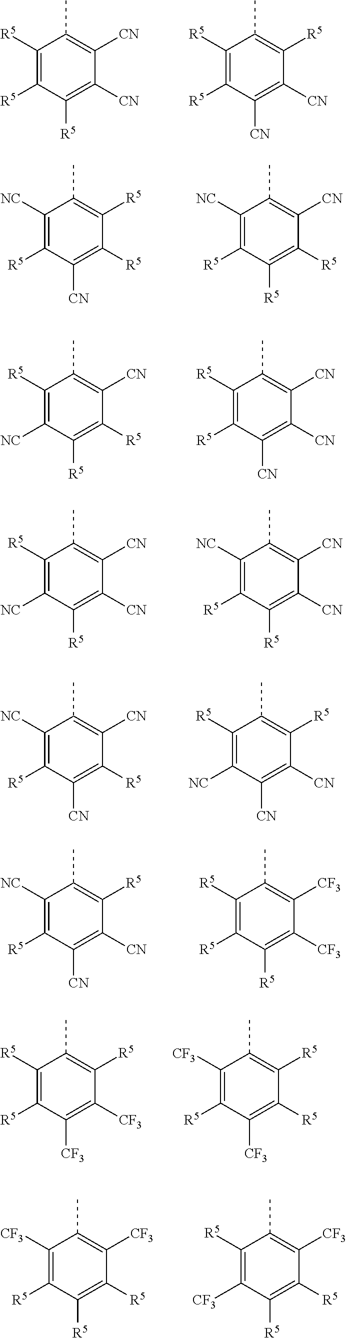

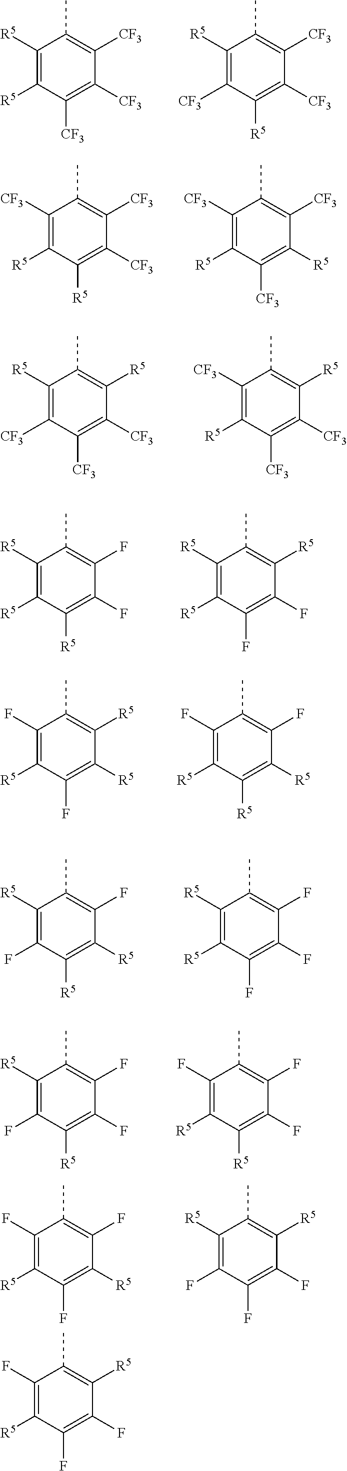

wherein
the dashed line represents a single bond linking the substituent R^{EWG} to the organic molecule as shown by Formula I;
wherein, optionally, two or more adjacent substituents R⁵ may independently of each other form a mono- or polycyclic, aliphatic, aromatic and/or benzo-fused ring system, wherein one or more hydrogen atoms of the optionally so formed ring system may be substituted by R⁶.

In one embodiment, the organic molecules include or consist of a structure of Formula IIa, Formula IIb or Formula IIc:

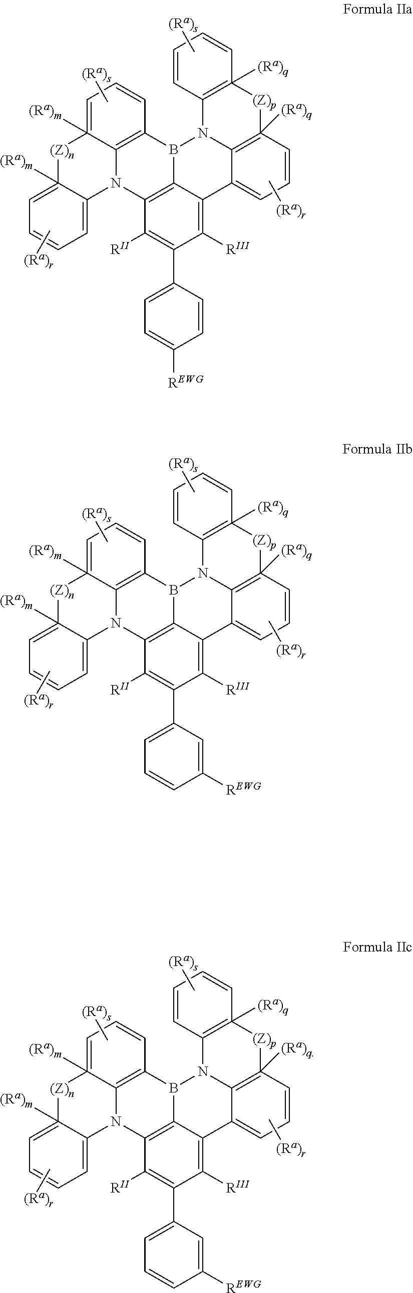

In one embodiment, Z is at each occurrence selected from a direct bond, NR³, O and S.

In one embodiment, Z is at each occurrence a direct bond.

In one embodiment, the organic molecules include or consist of a structure of Formula IIIa, Formula IIIb, Formula IIIc or Formula IIId:

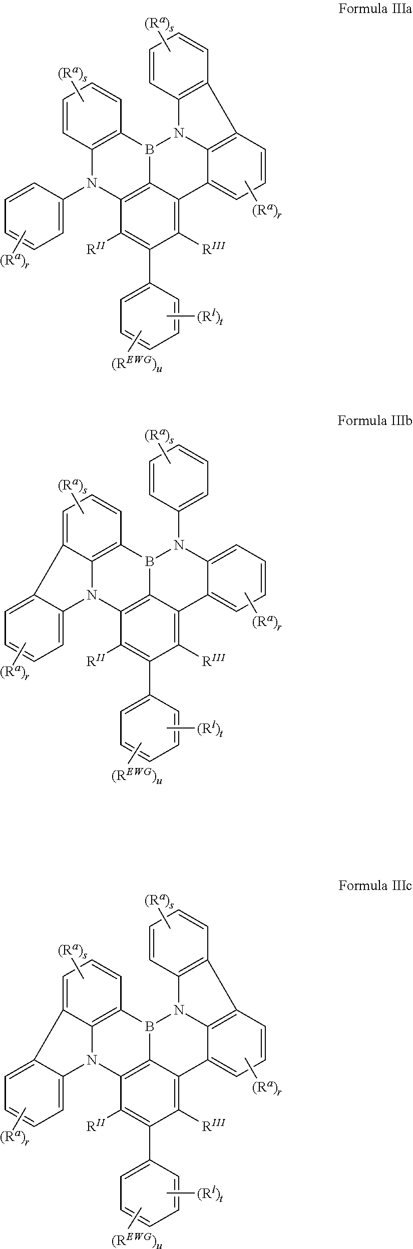

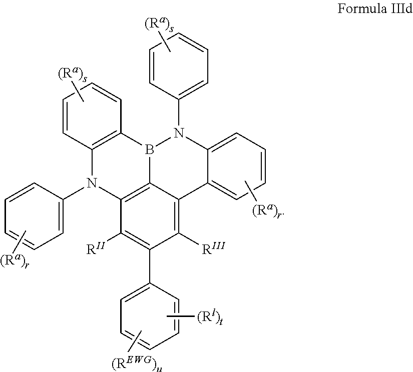

In one embodiment, the organic molecules include or consist of Formula IVa, or Formula IVb:

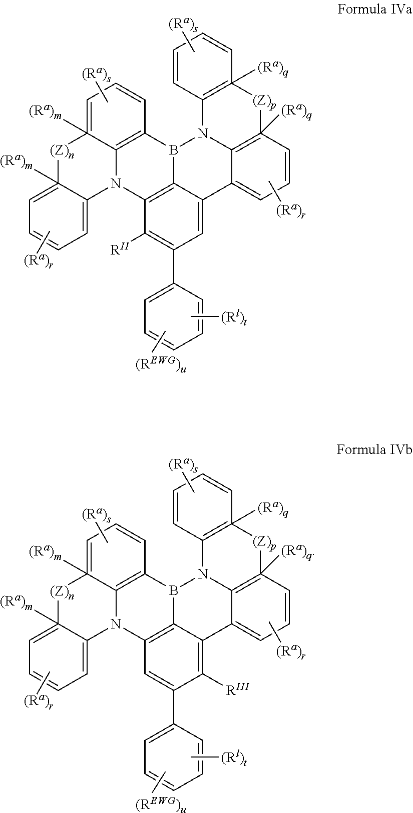

In one embodiment, R^{a} is at each occurrence independently from another selected from the group consisting of:
hydrogen,
deuterium,
Me,
ⁱPr,
^{t}Bu
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph, carbazolyl, which is optionally substituted with one or more substituents
independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph,
and N(Ph)₂, which is optionally substituted with one or more substituents independently from each other selected from the group consisting of Me, ⁱPr, ^{t}Bu, CN, CF₃, and Ph;
wherein two or more adjacent substituents R^{a} may form attachment points for a ring system selected from the group consisting of:

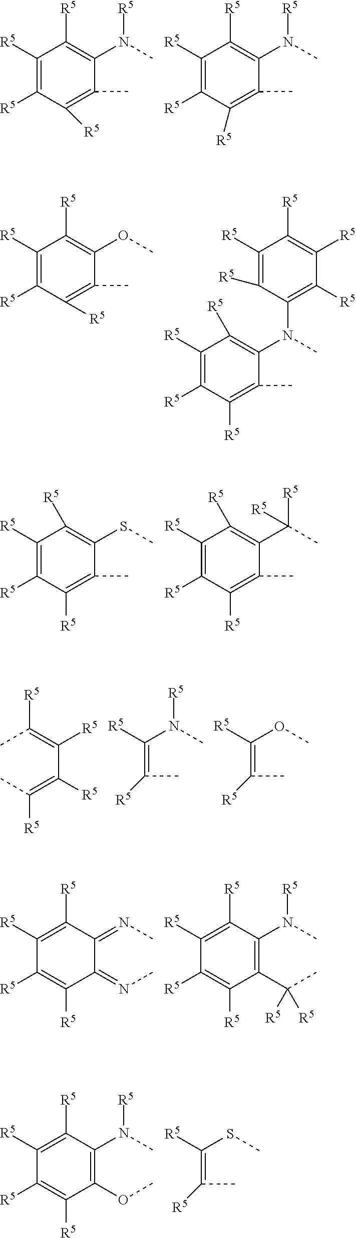

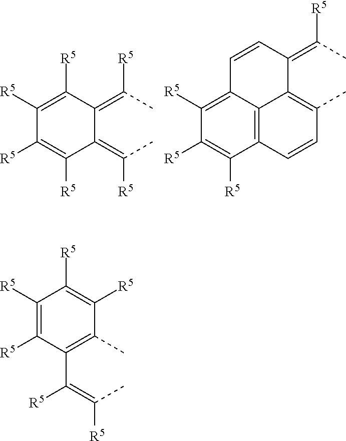

wherein each dashed line indicates a direct bond connecting one of the above shown ring systems to the positions of two adjacent substituents R^{a} such that a ring system of the group shown above is fused to the structure as shown in Formula I.

In one embodiment, R^{a} is at each occurrence independently from another selected from the group consisting of:
hydrogen,
deuterium,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph,
and N(Ph)₂, which is optionally substituted with one or more substituents independently from each other selected from the group consisting of Me, ⁱPr, ^{t}Bu, CN, CF₃, and Ph;
In one embodiment, the organic molecules include or consist of a structure of Formula Va, Formula Vb or Formula Vc:

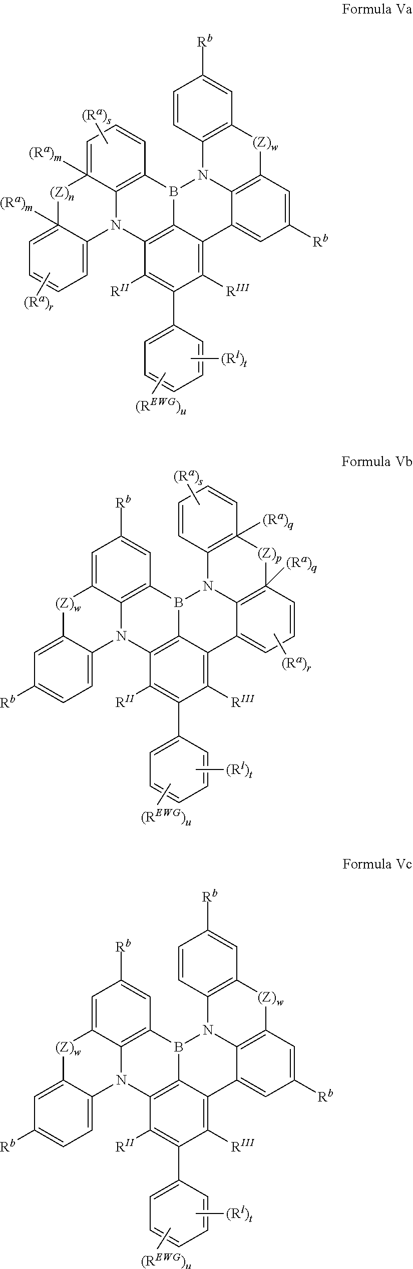

wherein
w is at each occurrence independently of each other an integer of 0 or 1;
R^{b} is at each occurrence independently from another selected from the group consisting of hydrogen, deuterium, N(R⁵)₂, OR⁵, Si(R⁵)₃, B(OR⁵)₂, OSO₂R⁵, CF³, CN, F, Br, I,
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵.

In one embodiment, R⁶ is at each occurrence independently from another selected from the group consisting of hydrogen (H), methyl (Me), i-propyl (CH(CH₃)₂) (ⁱPr), t-butyl (^{t}Bu), phenyl (Ph), CN, CF₃, and diphenylamine (NPh₂).

In one embodiment, R⁵ is at each occurrence independently from another selected from the group consisting of hydrogen (H), methyl (Me), i-propyl (CH(CH₃)₂) (ⁱPr), t-butyl (^{t}Bu), phenyl (Ph), CN, CF₃, and diphenylamine (NPh₂).

In one embodiment of the present disclosure, R^{a} is at each occurrence independently from another selected from the group consisting of:
hydrogen, deuterium,
Me,
ⁱPr
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph,
and N(Ph)₂.

In one embodiment, at least one mono- or polycyclic, aliphatic, aromatic, heteroaromatic and/or benzo-fused ring system is formed by R^{a}, R³, R⁴, R⁵, and R⁶ substituents together with one or more further substituents R^{a}, R³, R⁴, R⁵ and/or R⁶.

In one embodiment, R^{I}, R^{II} and R^{III} is selected from the group consisting of hydrogen, deuterium,
Me,
ⁱPr,
^{t}Bu,
Ph, which is optionally substituted with one or more substituents
independently from each other selected from the group consisting of Me, ⁱPr, ^{t}Bu, and Ph.

In one embodiment, at least one substituent selected from R^{II} and R^{III} is hydrogen.

In one embodiment, at least one substituent selected from R^{II} and R^{III} is not hydrogen.

In some embodiments, R^{II} is hydrogen.

In some embodiments, R^{III} is not hydrogen.

In some embodiments, R^{II} is hydrogen and R^{III} is not hydrogen.

In one embodiment, R^{I} is hydrogen.

### Definitions

Herein, the term “layer” refers to a body that bears an extensively planar geometry. Embodiments of the optoelectronic devices may be composed of several layers.

A light-emitting layer (EML) in the context of embodiments of the present disclosure is a layer of an optoelectronic device, wherein light emission from said layer is observed when applying a voltage and electrical current to the device. The person skilled in the art understands that light emission from optoelectronic devices is attributed to light emission from at least one EML. Light emission from an EML may not (mainly) attributed to all materials included in said EML, to set or specific emitter materials.

An “emitter material” (also referred to as “emitter”) in the context of embodiments of the present disclosure is a material that emits light when it is included in a light-emitting layer (EML) of an optoelectronic device (vide infra), given that a voltage and electrical current are applied to said device. According to embodiments of the present disclosure, an emitter material may be an “emissive dopant” material, and a dopant material (may it be emissive or not) may be a material that is embedded in a matrix material that may be (and herein) referred to as host material. Herein, host materials are also in general referred to as H^{B} when they are included in an optoelectronic device (for example, an OLED) including at least one organic molecule according to embodiments of the present disclosure.

In the context of embodiments of the present disclosure, the term “cyclic group” may be understood in the broadest sense as any mono-, bi- or polycyclic moiety.

In the context of embodiments of the present disclosure, the term “ring” when referring to chemical structures may be understood in the broadest sense as any monocyclic moiety. Along the same lines, the term “rings” when referring to chemical structures may be understood in the broadest sense as any bi- or polycyclic moiety.

In the context of embodiments of the present disclosure, the term “ring system” may be understood in the broadest sense as any mono-, bi- or polycyclic moiety.

In the context of embodiments of the present disclosure, the term “ring atom” refers to any atom which is part of the cyclic core of a ring or a ring system, and not part of a non-cyclic substituent optionally attached to the cyclic core.

In the context of embodiments of the present disclosure, the term “carbocycle” may be understood in the broadest sense as any cyclic group in which the cyclic core structure includes only carbon atoms that may of course be substituted with hydrogen or any other substituents defined in embodiments of the present disclosure. It is understood that the term “carbocyclic” as adjective refers to cyclic groups in which the cyclic core structure includes only carbon atoms that may of course be substituted with hydrogen or any other substituents defined in embodiments of the present disclosure.

In the context of embodiments of the present disclosure, the term “heterocycle” may be understood in the broadest sense as any cyclic group in which the cyclic core structure includes not just carbon atoms, but also at least one heteroatom. It is understood that the term “heterocyclic” as adjective refers to cyclic groups in which the cyclic core structure includes not just carbon atoms, but also at least one heteroatom. The heteroatoms may, unless stated otherwise in embodiments, at each occurrence be the same or different and, for example, be individually selected from the group consisting of B, Si, N, O, S, and Se, for example, B, N, O and S, for example, N, O, S. All carbon atoms or heteroatoms included in a heterocycle in the context of embodiments of the present disclosure may of course be substituted with hydrogen or any other substituents defined in embodiments of the present disclosure.

The person skilled in the art understands that any cyclic group (e.g., any carbocycle and heterocycle) may be aliphatic or aromatic or heteroaromatic.

In the context of embodiments of the present disclosure, the term aliphatic when referring to a cyclic group (e.g., to a ring, to rings, to a ring system, to a carbocycle, to a heterocycle) means that the cyclic core structure (not counting substituents that are optionally attached to it) contains at least one ring atom that is not part of an aromatic or heteroaromatic ring or ring system. In some embodiments, the majority of ring atoms and, for example, all ring atoms within an aliphatic cyclic group are not part of an aromatic or heteroaromatic ring or ring system (such as in cyclohexane or in piperidine for example). Herein, no differentiation is made between carbocyclic and heterocyclic groups when referring to aliphatic rings or ring systems in general, whereas the term “aliphatic” may be used as adjective to describe a carbocycle or heterocycle in order to indicate whether or not a heteroatom is included in the aliphatic cyclic group.

As understood by the skilled artisan, the terms “aryl” and “aromatic” may be understood in the broadest sense as any mono-, bi- or polycyclic aromatic moieties, e.g., cyclic groups in which all ring atoms are part of an aromatic ring system, for example, part of the same aromatic ring system. However, throughout the present application, the terms “aryl” and “aromatic” are restricted to mono-, bi- or polycyclic aromatic moieties wherein all aromatic ring atoms are carbon atoms. In contrast, the terms “heteroaryl” and “heteroaromatic” herein refer to any mono-, bi- or polycyclic aromatic moieties, wherein at least one aromatic carbon ring atom is replaced by a heteroatom (e.g., not carbon). Unless stated otherwise in embodiments of the present disclosure, the at least one heteroatom within a “heteroaryl” or “heteroaromatic” may at each occurrence be the same or different and be individually selected from the group consisting of N, O, S, and Se, for example, N, O, and S. The person skilled in the art understands that the adjectives “aromatic” and “heteroaromatic” may be used to describe any cyclic group (e.g., any ring system). This is to say that an aromatic cyclic group (e.g., an aromatic ring system) is an aryl group and a heteroaromatic cyclic group (e.g., a heteroaromatic ring system) is a heteroaryl group.

Unless indicated differently in embodiments of the present disclosure, an aryl group herein, for example, contains 6 to 60 aromatic ring atoms, for example, 6 to 40 aromatic ring atoms, and, for example, 6 to 18 aromatic ring atoms. Unless indicated differently in embodiments of the present disclosure, a heteroaryl group herein, for example, contains 5 to 60 aromatic ring atoms, for example, 5 to 40 aromatic ring atoms, for example, 5 to 20 aromatic ring atoms, out of which at least one is a heteroatom, for example, selected from N, O, S, and Se, for example, from N, O, and S. If more than one heteroatom is included an a heteroaromatic group, all heteroatoms are, for example, independently of each other selected from N, O, S, and Se, for example, from N, O, and S.

In the context of embodiments of the present disclosure, for both aromatic and heteroaromatic groups (for example aryl or heteroaryl substituents), the number of aromatic ring carbon atoms may be given as subscripted number in the definition of certain substituents, for example in the form of “C₆-C₆₀-aryl”, which means that the respective aryl substituent includes 6 to 60 aromatic carbon ring atoms. The same subscripted numbers are herein also used to indicate the allowable number of carbon atoms in all other kinds of substituents, regardless of whether they are aliphatic, aromatic or heteroaromatic substituents. For example, the expression “C₁-C₄₀-alkyl” refers to an alkyl substituent including 1 to 40 carbon atoms.

Examples of aryl groups include groups derived from benzene, naphthalene, anthracene, phenanthrene, pyrene, dihydropyrene, chrysene, perylene, fluoranthene, benzanthracene, benzophenanthrene, tetracene, pentacene, benzopyrene or combinations of these groups.

Examples of heteroaryl groups include groups derived from furan, benzofuran, isobenzofuran, dibenzofuran, thiophene, benzothiophene, isobenzothiophene, dibenzothiophene; pyrrole, indole, isoindole, carbazole, indolocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazol, phenanthroxazol, isoxazole, 1,2-thiazole, 1,3-thiazole, benzothiazole, pyridazine, benzopyridazine, pyrimidine, benzopyrimidine, 1,3,5-triazine, 1,2,4-triazine, 1,2,3-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, 1,2,4,5-tetrazine, purine, pteridine, indolizine and benzothiadiazole or combinations of these groups.

As used throughout the present application, the term “arylene” refers to a divalent aryl substituent that bears two binding sites to other molecular structures, thereby serving as a linker structure. Along the same lines, the term “heteroarylene” refers to a divalent aryl substituent that bears two binding sites to other molecular structures, thereby serving as a linker structure.

In the context of embodiments of the present disclosure, the term “fused” when referring to aromatic or heteroaromatic ring systems means that the aromatic or heteroaromatic rings that are “fused” share at least one bond that is part of both ring systems. For example naphthalene (or naphthyl when referred to as substituent) or benzothiophene (or benzothiophenyl when referred to as substituent) are considered fused aromatic ring systems in the context of embodiments of the present disclosure, in which two benzene rings (for naphthalene) or a thiophene and a benzene (for benzothiophene) share one bond. It is also understood that sharing a bond in this context includes sharing the two atoms that build up the respective bond and that fused aromatic or heteroaromatic ring systems can be understood as one aromatic or heteroaromatic ring system. Additionally, it is understood, that more than one bond may be shared by the aromatic or heteroaromatic rings building up a fused aromatic or heteroaromatic ring system (e.g., in pyrene). Furthermore, it will be understood that aliphatic ring systems may also be fused and that this has the same meaning as for aromatic or heteroaromatic ring systems, with the exception of course, that fused aliphatic ring systems are not aromatic. Furthermore, it is understood that an aromatic or heteroaromatic ring system may also be fused to (in other words: share at least one bond with) an aliphatic ring system.

In the context of embodiments of the present disclosure, the term “condensed” ring system has the same meaning as “fused” ring system.

In certain embodiments of the present disclosure, adjacent substituents bonded to a ring or a ring system may together form an additional mono- or polycyclic, aliphatic, aromatic or heteroaromatic ring system which is fused to the aromatic or heteroaromatic ring or ring system to which the substituents are bonded. It is understood that the optionally so formed fused ring system will be larger (meaning it includes more ring atoms) than the aromatic or heteroaromatic ring or ring system to which the adjacent substituents are bonded. In these cases (and if such a number is provided), the “total” amount of ring atoms included in the fused ring system is to be understood as the sum of ring atoms included in the aromatic or heteroaromatic ring or ring system to which the adjacent substituents are bonded and the ring atoms of the additional ring system formed by the adjacent substituents, wherein, however, the ring atoms that are shared by fused rings are counted once and not twice. For example, a benzene ring may have two adjacent substituents that together form another benzene ring so that a naphthalene core is built. This naphthalene core then includes 10 ring atoms as two carbon atoms are shared by the two benzene rings and are thus only counted once and not twice.

In general, in the context of embodiments of the present disclosure, the terms “adjacent substituents” or “adjacent groups” refer to substituents or groups bonded to either the same or to neighboring atoms.

In the context of embodiments of the present disclosure, the term “alkyl group” may be understood in the broadest sense as any linear, branched, or cyclic alkyl substituent. Examples of alkyl groups as substituents include methyl (Me), ethyl (Et), n-propyl (ₙPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl and 1-(n-decyl)-cyclohex-1-yl.

The “s” in for example s-butyl, s-pentyl and s-hexyl refers to “secondary”; or in other words: s-butyl, s-pentyl and s-hexyl are equal to sec-butyl, sec-pentyl and sec-hexyl, respectively. The “t” in for example t-butyl, t-pentyl and t-hexyl refers to “tertiary”; or in other words: t-butyl, t-pentyl and t-hexyl are equal to tert-butyl, tert-pentyl and tert-hexyl, respectively.

As used herein, the term “alkenyl” includes linear, branched, and cyclic alkenyl substituents. The term alkenyl group comprises, as examples, the substituents ethenyl, propenyl, butenyl, pentenyl, cyclopentenyl, hexenyl, cyclohexenyl, heptenyl, cycloheptenyl, octenyl, cyclooctenyl or cyclooctadienyl.

As used herein, the term “alkynyl” includes linear, branched, and cyclic alkynyl substituents. The term alkynyl group comprises, as examples, ethynyl, propynyl, butynyl, pentynyl, hexynyl, heptynyl or octynyl.

As used herein, the term “alkoxy” includes linear, branched, and cyclic alkoxy substituents. The term alkoxy group comprises, as examples, methoxy, ethoxy, n-propoxy, i-propoxy, n-butoxy, i-butoxy, s-butoxy, t-butoxy and 2-methylbutoxy.

As used herein, the term “thioalkoxy” includes linear, branched, and cyclic thioalkoxy substituents, in which the oxygen atom O of the corresponding alkoxy groups is replaced by sulfur, S.

As used herein, the terms “halogen” (or “halo” when referred to as substituent in chemical nomenclature) may be understood in the broadest sense as any atom of an element of the 7^{th} main group (in other words: group 17) of the periodic table of elements, for example, fluorine, chlorine, bromine or iodine.

It is understood that when a molecular fragment is described as being a substituent or otherwise attached to another moiety, its name may be written as if it was a fragment (e.g., naphthyl, dibenzofuryl) or as if it was the intact group (e.g., naphthalene, dibenzofuran). As used herein, these different ways of designating a substituent or attached fragment are considered to be equivalent.

Furthermore, herein, whenever a substituent such as “C₆-C₆₀-aryl” or “C₁-C₄₀-alkyl” is referred to without the name indicating the binding site within that substituent, this is to mean that the respective substituent may bond via any atom. For example, a “C₆-C₆₀-aryl”-substituent may bond via any of the 6 to 60 aromatic carbon atoms and a “C₁-C₄₀-alkyl”-substituent may bond via any of the 1 to 40 aliphatic carbon atoms. On the other hand, a “2-cyanophenyl”-substituent can only be bonded in such a way that its CN-group is adjacent to the binding site as to allow for the chemical nomenclature to be correct.

In the context of embodiments of the present disclosure, whenever a substituent such as “butyl”, “biphenyl” or “terphenyl” is referred to without further detail, this is to mean that any isomer of the respective substituent is allowable as the substituent. In this regard, for example the term “butyl” as substituent includes n-butyl, s-butyl, t-butyl, and iso-butyl as substituents. Along the same lines, the term “biphenyl” as substituent includes ortho-biphenyl, meta-biphenyl, or para-biphenyl, wherein ortho, meta and para are defined with regard to the binding site of the biphenyl substituent to the respective chemical moiety that bears the biphenyl substituent. Similarly, the term “terphenyl” as substituent includes 3-ortho-terphenyl, 4-ortho-terphenyl, 4-meta-terphenyl, 5-meta-terphenyl, 2-para-terphenyl or 3-para-terphenyl, wherein, according to embodiments of the present disclosure, ortho, meta and para indicate the position of the two Ph-moieties within the terphenyl-group to each other and “2-”, “3-”, “4-” and “5-” denotes the binding site of the terphenyl substituent to the respective chemical moiety that bears the terphenyl substituent.

It is understood that all groups defined above and indeed all chemical moieties, regardless of whether they are cyclic or non-cyclic, aliphatic, aromatic or heteroaromatic, may be further substituted in accordance with embodiments described herein.

All hydrogen atoms (H) included in any structure referred to herein may at each occurrence independently and, be replaced by deuterium (D) without this being indicated specifically. The replacement of hydrogen may be performed by any suitable method generally used in the art. Thus, there are numerous suitable methods by which this can be achieved and several review articles describing them.

If experimental or calculated data are compared, the values have to be determined by the same methodology. For example, if an experimental AEST is determined to be below 0.4 eV by a set or specific method, a comparison is only valid using the same set or specific method including the same conditions. To give an example, the comparison of the photoluminescence quantum yield (PLQY) of different compounds is only valid if the determination of the PLQY value was performed under the same reaction conditions (measurement in a 10% PMMA film at room temperature). Similarly, calculated energy values need to be determined by the same calculation method (using the same functional and the same basis set).

### An Optoelectronic Device Including at Least One Organic Molecule According to Embodiments of the Present Disclosure

A further aspect of embodiments of the present disclosure relates to an optoelectronic device including at least one organic molecule according to embodiments of the present disclosure.

In one embodiment, the optoelectronic device including at least one organic molecule according to embodiments of the present disclosure is selected from the group consisting of:
organic light-emitting diodes (OLEDs),
light-emitting electrochemical cells,
OLED sensors, especially in gas and vapor sensors not hermetically externally shielded,
organic diodes,
organic solar cells,
organic transistors,
organic field-effect transistors,
organic lasers and
down-conversion elements.

A light-emitting electrochemical cell consists of three layers, namely a cathode, an anode, and an active layer, which may contain the organic molecule according to embodiments of the present disclosure.

In some embodiments, the optoelectronic device including at least one organic molecule according to embodiments of the present disclosure is selected from the group consisting of an organic light emitting diode (OLED), a light emitting electrochemical cell (LEC), an organic laser, and a light-emitting transistor.

In some embodiments, the optoelectronic device including at least one organic molecule according to embodiments of the present disclosure is an organic light-emitting diode (OLED).

In one embodiment, the optoelectronic device including at least one organic molecule according to embodiments of the present disclosure is an OLED that may exhibit the following layer structure:
1. Substrate
2. Anode layer A
3. Hole injection layer, HIL
4. Hole transport layer, HTL
5. Electron blocking layer, EBL
6. Light-emitting layer (also referred to as emission layer), EML
7. Hole blocking layer, HBL
8. Electron transport layer, ETL
9. Electron injection layer, EIL
10. Cathode layer C,
wherein the OLED includes each layer, except for an anode layer A, a cathode layer C, and an EML, only optionally, and wherein different layers may be merged and the OLED may include more than one layer of each layer type defined above.

Furthermore, the optoelectronic device including at least one organic molecule according to embodiments of the present disclosure may optionally include one or more protective layers protecting the device from damaging exposure to harmful species in the environment including, as examples, moisture, vapor and/or gases.

In one embodiment, the optoelectronic device including at least one organic molecule according to embodiments of the present disclosure is an OLED, that may exhibit the following (inverted) layer structure:
1. Substrate
2. Cathode layer C
3. Electron injection layer, EIL
4. Electron transport layer, ETL
5. Hole blocking layer, HBL
6. Light-emitting layer (also referred to as emission layer), EML
7. Electron blocking layer, EBL
8. Hole transport layer, HTL
9. Hole injection layer, HIL
10. Anode layer A
wherein the OLED (with an inverted layer structure) includes each layer, except for an anode layer A, a cathode layer C, and an EML, only optionally, and wherein different layers may be merged and the OLED may include more than one layer of each layer types defined above.

The organic molecules according to embodiments of the present disclosure (in accordance with the embodiments indicated above) can be employed in various layers, depending on the precise structure and on the substitution. In the case of the use, the fraction of the organic molecule according to embodiments of the present disclosure in the respective layer in an optoelectronic device, for example, in an OLED, is 0.1% to 99% by weight, for example, 1% to 80% by weight. In an alternative embodiment, the proportion of the organic molecule in the respective layer is 100% by weight.

In one embodiment, of the optoelectronic device including at least one organic molecule according to embodiments of the present disclosure is an OLED which may exhibit stacked architecture. In this architecture, contrary to other arrangements, where the OLEDs are placed side by side, the individual units are stacked on top of each other. Blended light may be generated with OLEDs exhibiting a stacked architecture, for example, white light may be generated by stacking blue, green and red OLEDs. Furthermore, the OLED exhibiting a stacked architecture may optionally include a charge generation layer (CGL), which may be located between two OLED subunits and may consist of a n-doped and p-doped layer with the n-doped layer of one CGL being located closer to the anode layer.

In one embodiment, the optoelectronic device including at least one organic molecule according to embodiments of the present disclosure is an OLED, which includes two or more emission layers between anode and cathode. For example, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

In one embodiment, the optoelectronic device including at least one organic molecule according to embodiments of the present disclosure may be an essentially white optoelectronic device, which is to say that the device emits white light. As an example, such a white light-emitting optoelectronic device may include at least one (deep) blue emitter molecule and one or more emitter molecules emitting green and/or red light. Then, there may also optionally be energy transmittance between two or more molecules as described in a later section of this text (vide infra).

In the case of the optoelectronic device including at least one organic molecule according to embodiments of the present disclosure, the at least one organic molecule according to embodiments of the present disclosure may be included in a light-emitting layer (EML) of the optoelectronic device, for example, in an EML of an OLED. However, the organic molecules according to embodiments of the present disclosure may for example also be employed in an electron transport layer (ETL) and/or in an electron blocking layer (EBL) or exciton-blocking layer and/or in a hole transport layer (HTL) and/or in a hole blocking layer (HBL). In the case of the use, the fraction of the organic molecule according to embodiments of the present disclosure in the respective layer in an optoelectronic device, for example, in an OLED, is 0.1% to 99% by weight, for example, 0.5% to 80% by weight, for example, 0.5% to 10% by weight. In an alternative embodiment, the proportion of the organic molecule in the respective layer is 100% by weight.

The selection criteria for suitable materials for the individual layers of optoelectronic devices, for example OLEDs, may be any suitable ones generally used in the art. The state of the art describes plenty of materials to be used in the individual layers and also teaches which materials are suitable to be used alongside each other. It is understood that any materials used in the state of the art may also be used in optoelectronic devices including the organic molecule according to embodiments of the present disclosure. In the following, examples of materials for the individual layers will be given. It is understood that this does not imply that all types of layers listed below must be present in an optoelectronic device including at least one organic molecule according to embodiments of the present disclosure. Additionally, it is understood that an optoelectronic device including at least one organic molecule according to embodiments of the present disclosure may include more than one of each of the layers listed in the following, for example two or more light-emitting layers (EMLs). It is also understood that two or more layers of the same type (e.g., two or more EMLs or two or more HTLs) do not necessarily include the same materials or even the same materials in the same ratios. Furthermore, it is understood that an optoelectronic device including at least one organic molecule according to embodiments of the present disclosure does not have to include all the layer types listed in the following, wherein an anode layer, a cathode layer, and a light-emitting layer will usually be present in all cases.

The substrate may be formed by any material or composition of materials. Most frequently, glass slides are used as substrates. Alternatively, thin metal layers (e.g., copper, gold, silver or aluminum films) or plastic films or slides may be used. This may allow a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is usually transparent. In some embodiments, the anode layer A includes a large content or even consists of transparent conductive oxides (TCOs). Such an anode layer A may, for example, include indium tin oxide, aluminum zinc oxide, fluorine doped tin oxide, indium zinc oxide, PbO, SnO, zirconium oxide, molybdenum oxide, vanadium oxide, wolfram oxide, graphite, doped Si, doped Ge, doped GaAs, doped polyaniline, doped polypyrrol and/or doped polythiophene.

In some embodiments, an anode layer A (essentially) consists of indium tin oxide (ITO) (e.g., (InO₃)_{0.9}(SnO₂)_{0.1}). The roughness of an anode layer A caused by the transparent conductive oxides (TCOs) may be compensated by using a hole injection layer (HIL). Further, a HIL may facilitate the injection of quasi charge carriers (e.g., holes) in that the transport of the quasi charge carriers from the TCO to the hole transport layer (HTL) is facilitated. A hole injection layer (HIL) may include poly-3,4-ethylendioxy thiophene (PEDOT), polystyrene sulfonate (PSS), MoO₂, V₂O₅, CuPC or Cul, for example, a mixture of PEDOT and PSS. A hole injection layer (HIL) may also prevent or reduce the diffusion of metals from an anode layer A into a hole transport layer (HTL). A HIL may for example include PEDOT:PSS (poly-3,4-ethylendioxy thiophene: polystyrene sulfonate), PEDOT (poly-3,4-ethylendioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N, N′-bis-(1-naphthalenyl)-N, N′-bis-phenyl-(1,1′-biphenyl)-4,4′-diamine), NPNPB (N, N′-diphenyl-N, N′-di-[4-(N, N-diphenyl-amino)phenyl]benzidine), MeO-TPD (N, N, N′, N′-tetrakis(4-methoxyphenyl)benzidine), HAT-CN (1,4,5,8,9,11-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to an anode layer A or a hole injection layer (HIL), a hole transport layer (HTL) may be located. Herein, any hole transport material may be used. As an example, electron-rich heteroaromatic compounds such as triarylamines and/or carbazoles may be used as hole transport compound. A HTL may decrease the energy barrier between an anode layer A and a light-emitting layer EML. A hole transport layer (HTL) may also be an electron blocking layer (EBL). In some embodiments, hole transport compounds bear comparably high energy levels of their lowermost excited triplet states T1. As an example, a hole transport layer (HTL) may include a star-shaped heterocyclic compound such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD (2,2′,7,7′-tetrakis(n,n-diphenylamino)-9,9′-spirobifluorene), DNTPD (N1, N1′-(biphenyl-4,4′-diyl)bis(N1-phenyl-N4, N4-di-m-tolylbenzene-1,4-diamine), NPB (N, N′-bis-(1-naphthalenyl)-N, N′-bis-phenyl-(1,1′-biphenyl)-4,4′-diamine)), NPNPB (N,N′-diphenyl-N, N′-di-[4-(N, N-diphenyl-amino)phenyl]benzidine), MeO-TPD (N, N, N′, N′-tetrakis(4-methoxyphenyl)benzidine), HAT-CN (1,4,5,8,9,11-hexaazatriphenylen-hexacarbonitrile) and/or TrisPcz (9,9′-diphenyl-6-(9-phenyl-9H-carbazol-3-yl)-9H, 9′H-3,3′-bicarbazole). In addition, a HTL may include a p-doped layer, which may be composed of an inorganic or organic dopant in an organic hole-transporting matrix. Transition metal oxides such as vanadium oxide, molybdenum oxide or tungsten oxide may be used as inorganic dopant. Tetrafluorotetracyanoquinodimethane (F4-TCNQ), copper-pentafluorobenzoate (Cu(I)pFBz) or transition metal complexes may be used as organic dopant.

An EBL may for example include mCP (1,3-bis(carbazol-9-yl)benzene), TCTA (tris(4-carbazoyl-9-ylphenyl)amine), 2-TNATA (4,4′,4″-tris[2-naphthyl(phenyl)amino]triphenylamine), mCBP (3,3-di(9H-carbazol-9-yl)biphenyl), tris-Pcz (9-Phenyl-3,6-bis(9-phenyl-9Hcarbazol-3-yl)-9H-carbazole), CzSi (9-(4-tert-Butylphenyl)-3,6-bis(triphenylsilyl)-9H-carbazole), and/or DCB (N,N′-dicarbazolyl-1,4-dimethylbenzene).

Adjacent to a hole transport layer (HTL) or (if present) an electron blocking layer (EBL), for example, a light-emitting layer (EML) may be located. A light-emitting layer (EML) includes at least one light-emitting molecule (e.g., emitter material). In some embodiments, an EML additionally includes one or more host materials (also referred to as matrix materials). As an example, the host material may be selected from CBP (4,4′-Bis-(N-carbazolyl)-biphenyl), mCP (1,3-bis(carbazol-9-yl)benzene), mCBP (3,3-di(9H-carbazol-9-yl)biphenyl), Sif87 (dibenzo[b,d]thiophen-2-yltriphenylsilane), CzSi (9-(4-tert-Butylphenyl)-3,6-bis(triphenylsilyl)-9H-carbazole), Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). According to embodiments of the present disclosure, a host material may be selected to exhibit first (e.g., lowermost) excited triplet state (T1) and first (e.g., lowermost) excited singlet (S1) energy levels, which are energetically higher than the first (e.g., lowermost) excited triplet state (T1) and first (e.g., lowermost) excited singlet state (S1) energy levels of the at least one light-emitting molecule that is embedded in the respective host material(s).

As stated previously, in the context of embodiments of the present disclosure, at least one EML of the optoelectronic device includes at least one molecule according to embodiments of the present disclosure. Example compositions of an EML of an optoelectronic device including at least one organic molecule according to embodiments of the present disclosure are described in more detail in a section of this text below (vide infra).

Adjacent to a light-emitting layer (EML), an electron transport layer (ETL) may be located. Herein, any electron transport material may be used. As an example, compounds bearing electron-deficient groups, such as for example benzimidazoles, pyridines, triazoles, triazines, oxadiazoles (e.g., 1,3,4-oxadiazole), phosphinoxides and sulfones, may be used. An electron transport material may also be a star-shaped heterocyclic compound such as 1,3,5-tri(1-phenyl-1H-benzo[d]imidazol-2-yl)phenyl (TPBi). An ETL may for example include Nbphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BpyTP2 (2,7-di(2,2′-bipyridin-5-yl)triphenyl), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, an ETL may be doped with materials such as Liq ((8-hydroxyquinolinato)lithium). An electron transport layer (ETL) may also block holes or a hole blocking layer (HBL) is introduced, for example, between an EML and an ETL.

A hole blocking layer (HBL) may for example include BCP (2,9-dimethyl-4,7-diphenyl-1,10-phenanthroline=bathocuproine), 4,6-diphenyl-2-(3-(triphenylsilyl)phenyl)-1,3,5-triazine, 9,9′-(5-(6-([1,1′-biphenyl]-3-yl)-2-phenylpyrimidin-4-yl)-1,3-phenylene)bis(9H-carbazole), BAlq (bis(8-hydroxy-2-methylquinoline)-(4-phenylphenoxy)aluminum), Nbphen (2,9-bis(naphthalen-2-yl)-4,7-diphenyl-1,10-phenanthroline), Alq3 (aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/ 1,3,5-tris(carbazol)-9-yl) benzene).

A cathode layer C may be located adjacent to the electron transport layer (ETL). For example, the cathode layer C may include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may consist of (essentially) non-transparent metals such as Mg, Ca or Al. Alternatively or additionally, the cathode layer C may also include graphite and/or carbon nanotubes (CNTs). Alternatively, the cathode layer C may also include or consist of nanoscalic silver wires.

An OLED including at least one organic molecule according to embodiments of the present disclosure may further, optionally include a protection layer between an electron transport layer (ETL) and a cathode layer C (which may be designated as electron injection layer (EIL)). This layer may include lithium fluoride, cesium fluoride, silver, Liq ((8-hydroxyquinolinato)lithium), Li₂O, BaF₂, MgO and/or NaF.

Optionally, an electron transport layer (ETL) and/or a hole blocking layer (HBL) may also include one or more host materials.

As used herein, if not defined more specifically in the particular context, the designation of the colors of emitted and/or absorbed light is as follows:
violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to light-emitting molecules (in other words: emitter materials), such colors refer to the emission maximum of the main emission peak. Therefore, as an example, a deep blue emitter has an emission maximum in the range of from >420 to 480 nm, a sky-blue emitter has an emission maximum in the range of from >480 to 500 nm, a green emitter has an emission maximum in a range of from >500 to 560 nm, and a red emitter has an emission maximum in a range of from >620 to 800 nm.

A deep blue emitter may, for example, have an emission maximum of below 475 nm, for example, below 470 nm, for example, below 465 nm or even below 460 nm. It may be above 420 nm, for example, above 430 nm, for example, above 440 nm or even above 450 nm. In some embodiments, the organic molecules according to embodiments of the present disclosure exhibit emission maxima between 420 and 500 nm, for example, between 430 and 490 nm, for example, between 440 and 480 nm, and, for example, between 450 and 470 nm, for example, measured at room temperature (e.g., (approximately) 20° C.) from a spin-coated film with 1-5%, for example, 2% by weight of the organic molecule according to embodiments of the present disclosure in poly(methyl methacrylate), PMMA, mCBP or alternatively in an organic solvent, for example, DCM or toluene, with 0.001 mg/mL of organic molecule according to embodiments of the present disclosure.

A further embodiment relates to an OLED including at least one organic molecule according to embodiments of the present disclosure and emitting light with CIEx and CIEy color coordinates close to the CIEx (=0.131) and CIEy (=0.046) color coordinates of the primary color blue (CIEx=0.131 and CIEy=0.046) as defined by the ITU-R Recommendation BT.2020 (Rec. 2020) and thus is suited for the use in Ultra High Definition (UHD) displays, e.g., UHD-TVs. Accordingly, a further aspect of embodiments of the present disclosure relates to an OLED including at least one organic molecule according to embodiments of the present disclosure, whose emission exhibits a CIEx color coordinate of between 0.02 and 0.30, for example, between 0.03 and 0.25, for example, between 0.05 and 0.20 or, for example, between 0.08 and 0.18 or even between 0.10 and 0.15 and/or a CIEy color coordinate of between 0.00 and 0.45, for example, between 0.01 and 0.30, for example, between 0.02 and 0.20 or, for example, between 0.03 and 0.15 or even between 0.04 and 0.10.

A further embodiment relates to an OLED including at least one organic molecule according to embodiments of the present disclosure and exhibiting an external quantum efficiency at 1000 cd/m² of more than 8%, for example, of more than 10%, for example, of more than 13%, for example, of more than 15% or even more than 20% and/or exhibits an emission maximum 420 and 500 nm, for example, between 430 and 490 nm, for example, between 440 and 480 nm, and, for example, between 450 and 470 nm or still and/or exhibits an LT80 value at 500 cd/m² of more than 100 h, for example, more than 200 h, for example, more than 400 h, for example, more than 750 h or even more than 1000 h.

A green emitter material may have an emission maximum between 500 and 560 nm, for example, between 510 and 550 nm, and, for example, between 520 and 540 nm.

Some embodiments relate to an OLED including at least one organic molecule according to embodiments of the present disclosure and emitting light at a distinct color point. In some embodiments, the OLED emits light with a narrow emission band (a small full width at half maximum (FWHM)). In some embodiments, the OLED including at least one organic molecule according to embodiments of the present disclosure emits light with an FWHM of the main emission peak of less than 0.30 eV, for example, less than 25 eV, for example, less than 0.20 eV, for example, less than 0.1 eV, or even less than 0.17 eV.

In accordance with embodiments of the present disclosure, the optoelectronic devices including at least one organic molecule according to embodiments of the present disclosure can for example be employed in displays, as light sources in lighting applications and as light sources in medical and/or cosmetic applications (for example light therapy).

Combination of the Organic Molecules According to Embodiments of the Present Disclosure with Further Materials

Any suitable layer of embodiments of the optoelectronic device (herein, for example, an OLED), and, for example, the light-emitting layer (EML), may be composed of a single material or a combination of different materials.

For example, the person skilled in the art understands that an EML may be composed of a single material that is capable of emitting light when a voltage (and electrical current) is applied to said device. However, the skilled artisan also understands that it may be beneficial to combine different materials in an EML of an optoelectronic device (herein, for example, an OLED), for example, one or more host material(s) (in other words: matrix material(s); herein designated host material(s) H^{B} when included in an optoelectronic device that includes at least one organic molecule according to embodiments of the present disclosure) and one or more dopant materials out of which at least one is emissive (e.g., an emitter material) when applying a voltage and electrical current to the device.

In some embodiments of the use of an organic molecule according to embodiments of the present disclosure in an optoelectronic device, said optoelectronic device includes at least one organic molecule according to embodiments of the present disclosure in an EML or in a layer that is directly adjacent to an EML or in more than one of these layers.

In some embodiments of the use of an organic molecule according to embodiments of the present disclosure in an optoelectronic device, said optoelectronic device is an OLED and includes at least one organic molecule according to embodiments of the present disclosure in an EML or in a layer that is directly adjacent to an EML or in more than one of these layers.

In some embodiments of the use of an organic molecule according to embodiments of the present disclosure in an optoelectronic device, said optoelectronic device is an OLED and includes at least one organic molecule according to embodiments of the present disclosure in an EML.

In one embodiment relating to the optoelectronic device, for example, the OLED, including at least one organic molecule according to embodiments of the present disclosure, the at least one, for example, each, organic molecule according to embodiments of the present disclosure is used as emitter material in a light-emitting layer EML, which is to say that it emits light when a voltage (and electrical current) is applied to said device.

According to embodiments of the present disclosure, light emission from emitter materials (e.g., emissive dopants), for example in organic light-emitting diodes (OLEDs), may include fluorescence from excited singlet states (for example, the lowermost excited singlet state S1) and phosphorescence from excited triplet states (for example, the lowermost excited triplet state T1).

A fluorescence emitter F is capable of emitting light at room temperature (e.g., (approximately) 20° C.)upon electronic excitation (for example in an optoelectronic device), wherein the emissive excited state is a singlet state. Fluorescence emitters usually display prompt (e.g., direct) fluorescence on a timescale of nanoseconds, when the initial electronic excitation (for example by electron hole recombination) affords an excited singlet state of the emitter.

In the context of embodiments of the present disclosure, a delayed fluorescence material is a material that is capable of reaching an excited singlet state (for example, the lowermost excited singlet state S1) by means of reverse intersystem crossing (RISC; in other words: up intersystem crossing or inverse intersystem crossing) from an excited triplet state (for example, from the lowermost excited triplet state T1) and that is furthermore capable of emitting light when returning from the so-reached excited singlet state (for example, S1) to its electronic ground state. The fluorescence emission observed after RISC from an excited triplet state (for example, T1) to the emissive excited singlet state (for example, S1) occurs on a timescale (for example, in the range of microseconds) that is slower than the timescale on which direct (e.g., prompt) fluorescence occurs (for example, in the range of nanoseconds) and is thus referred to as delayed fluorescence (DF). When RISC from an excited triplet state (for example, from T1) to an excited singlet state (for example, to S1), occurs through thermal activation, and if the so populated excited singlet state emits light (delayed fluorescence emission), the process is referred to as thermally activated delayed fluorescence (TADF). Accordingly, a TADF material is a material that is capable of emitting thermally activated delayed fluorescence (TADF) as explained above. According to some embodiments, when the energy difference ΔE_{ST} between the lowermost excited singlet state energy level E(S1^{E}) and the lowermost excited triplet state energy level E(T1^{E}) of a fluorescence emitter F is reduced, population of the lowermost excited singlet state from the lowermost excited triplet state by means of RISC may occur with high efficiency. Thus, according to embodiments of the present disclosure, a TADF material may have a small ΔE_{ST} value (vide infra). According to embodiments of the present disclosure, a TADF material may not just be a material that is on its own capable of RISC from an excited triplet state to an excited singlet state with subsequent emission of TADF as laid out above. According to some embodiments, a TADF material may in fact also be an exciplex that is formed from two kinds of materials, for example, from two host materials H^{B}, for example, from a p-host material H^{P} and an n-host material H^{N} (vide infra).

The occurrence of (thermally activated) delayed fluorescence may for example be analyzed based on the decay curve obtained from time-resolved (e.g., transient) photoluminescence (PL) measurements. For this purpose, a spin-coated film of the respective emitter (e.g., the assumed TADF material) in poly(methyl methacrylate) (PMMA) with 1-10% by weight, for example, 10% by weight of the respective emitter may be used as sample. The analysis may for example be performed using an FS5 fluorescence spectrometer from Edinburgh instruments. The sample PMMA film may be placed in a cuvette and kept under nitrogen atmosphere during the measurement. Data acquisition may be performed using the well-established technique of time correlated single photon counting (TCSPC, vide infra). To gather the full decay dynamics over several orders of magnitude in time and signal intensity, measurements in four time windows (200 ns, 1 μs, and 20 μs, and a longer measurement spanning >80 μs) may be carried out and combined (vide infra).

TADF materials, for example, fulfill the following two conditions regarding the aforementioned full decay dynamics:
(i) the decay dynamics exhibit two time regimes, one in the nanosecond (ns) range and the other in the microsecond (μs) range; and
(ii) the shapes of the emission spectra in both time regimes coincide;
wherein, the fraction of light emitted in the first decay regime is taken as prompt fluorescence and the fraction emitted in the second decay regime is taken as delayed fluorescence.

The ratio of delayed and prompt fluorescence may be expressed in form of a so-called n-value that may be calculated by the integration of respective photoluminescence decays in time according to the following equation:

$$\frac{\int {I}_{DF} ( t ) dt}{\int {I}_{PF} ( t ) dt} = n$$

In the context of embodiments of the present disclosure, a TADF material, for example, exhibits an n-value (ratio of delayed to prompt fluorescence) larger than 0.05 (n>0.05), for example, larger than 0.1 (n>0.1), for example, larger than 0.15 (n >0.15), for example, larger than 0.2 (n>0.20), or even larger than 0.25 (n>0.25).

In some embodiments, the organic molecules according to embodiments of the present disclosure exhibit an n-value (ratio of delayed to prompt fluorescence) larger than 0.05 (n>0.05).

In the context of embodiments of the present disclosure, a TADF material E^{B} is characterized by exhibiting a ΔE_{ST} value, which corresponds to the energy difference between the lowermost excited singlet state energy level E(S1^{E}) and the lowermost excited triplet state energy level E(T1E), of less than 0.4 eV, for example, of less than 0.3 eV, for example, of less than 0.2 eV, for example, of less than 0.1 eV, or even of less than 0.05 eV. The means of determining the ΔE_{ST} value of TADF materials E^{B} are laid out in a later subchapter of this text.

One approach for the design of TADF materials in general is to covalently attach one or more (electron) donor moieties on which the HOMO is distributed and one or more (electron) acceptor moieties on which the LUMO is distributed to the same bridge, herein referred to as linker group. A TADF material E^{B} may for example also include two or three linker groups which are bonded to the same acceptor moiety and additional donor and acceptor moieties may be bonded to each of these two or three linker groups.

One or more donor moieties and one or more acceptor moieties may also be bonded directly to each other (without the presence of a linker group).

Example donor moieties are derivatives of diphenyl amine, indole, carbazole, acridine, phenoxazine, and related structures. In some embodiments, aliphatic, aromatic or heteroaromatic ring systems may be fused to the aforementioned donor motifs to arrive at for example indolocarbazoles.

Benzene-, biphenyl-, and to some extend also terphenyl-derivatives are suitable linker groups.

Nitrile groups are suitable acceptor moieties in TADF materials and examples thereof include:
(i) carbazolyl dicyanobenzene compounds
   such as 2CzPN (4,5-di(9H-carbazol-9-yl)phthalonitrile), DCzIPN (4,6-di(9H-carbazol-9-yl)isophthalonitrile), 4CzPN (3,4,5,6-tetra(9H-carbazol-9-yl)phthalonitrile), 4CzIPN (2,4,5,6-Tetra(9H-carbazol-9-yl)isophthalonitrile), 4CzTPN (2,4,5,6-tetra(9H-carbazol-9-yl)terephthalonitrile), and derivatives thereof;
(ii) carbazolyl cyanopyridine compounds
   such as 4CzCNPy (2,3,5,6-tetra(9H-carbazol-9-yl)-4-cyanopyridine) and derivatives thereof;
(iii) carbazolyl cyanobiphenyl compounds
   such as CNBPCz (4,4′,5,5′-tetra(9H-carbazol-9-yl)-[1,1′-biphenyl]-2,2′-dicarbonitrile), CzBPCN (4,4′,6,6′-tetra(9H-carbazol-9-yl)-[1,1′-biphenyl]-3,3′-dicarbonitrile), DDCzIPN (3,3′,5,5′-tetra(9H-carbazol-9-yl)-[1,1′-biphenyl]-2,2′,6,6′-tetracarbonitrile) and derivatives thereof;
wherein in these materials, one or more of the nitrile groups may be replaced my fluorine (F) or trifluoromethyl (CF₃) as acceptor moieties.

Nitrogen-heterocycles such as triazine-, pyrimidine-, triazole-, oxadiazole-, thiadiazole-, heptazine-, 1,4-diazatriphenylene-, benzothiazole-, benzoxazole-, quinoxaline-, and diazafluorene-derivatives are also suitable acceptor moieties used for the construction of TADF molecules. Examples of TADF molecules including for example a triazine acceptor include PIC-TRZ (7,7′-(6-([1,1′-biphenyl]-4-yl)-1,3,5-triazine-2,4-diyl)bis(5-phenyl-5,7-dihydroindolo[2,3-b]carbazole)), mBFCzTrz (5-(3-(4,6-diphenyl-1,3,5-triazin-2-yl)phenyl)-5H-benzofuro[3,2-c]carbazole), and DCzTrz (9,9′-(5-(4,6-diphenyl-1,3,5-triazin-2-yl)-1,3-phenylene)bis(9H-carbazole)).

Another group of TADF materials includes diaryl ketones such as benzophenone or (heteroaryl)aryl ketones such as 4-benzoylpyridine, 9,10-anthraquinone, 9H-xanthen-9-one, and derivatives thereof as acceptor moieties to which the donor moieties (usually carbazolyl substituents) are bonded. Examples of such TADF molecules include BPBCz (bis(4-(9′-phenyl-9H,9′H-[3,3′-bicarbazol]-9-yl)phenyl)methanone), mDCBP ((3,5-di(9H-carbazol-9-yl)phenyl)(pyridin-4-yl)methanone), AQ-DTBu-Cz (2,6-bis(4-(3,6-di-tert-butyl-9H-carbazol-9-yl)phenyl)anthracene-9,10-dione), and MCz-XT (3-(1,3,6,8-tetramethyl-9H-carbazol-9-yl)-9H-xanthen-9-one), respectively.

Sulfoxides, for example, diphenyl sulfoxides, are also suitable to be used as acceptor moieties for the construction of TADF materials and examples include 4-PC-DPS (9-phenyl-3-(4-(phenylsulfonyl)phenyl)-9H-carbazole), DitBu-DPS (9,9′-(sulfonylbis(4,1-phenylene))bis(9H-carbazole)), and TXO-PhCz (2-(9-phenyl-9H-carbazol-3-yl)-9H-thioxanthen-9-one 10,10-dioxide).

It is understood that a fluorescence emitter F may also display TADF as defined herein and even be a TADF material E^{B} as defined herein. In consequence, a small FWHM emitter S^{B} as defined herein may or may not also be a TADF material E^{B} as defined herein.

Phosphorescence, e.g., light emission from excited triplet states (for example, from the lowermost excited triplet state T1) is a spin-forbidden process. According to some embodiments, phosphorescence may be facilitated (enhanced) by exploiting the (intramolecular) spin-orbit interaction (so called (internal) heavy atom effect). A phosphorescence material P^{B} in the context of embodiments of the present disclosure is a phosphorescence emitter capable of emitting phosphorescence at room temperature (e.g., at approximately 20° C.).

Herein, in some embodiments, a phosphorescence material P^{B} includes at least one atom of an element having a standard atomic weight larger than the standard atomic weight of calcium (Ca). For example, a phosphorescence material P^{B} in the context of embodiments of the present disclosure includes a transition metal atom, for example, a transition metal atom of an element having a standard atomic weight larger than the standard atomic weight of zinc (Zn). The transition metal atom, for example, included in the phosphorescence material P^{B} may be present in any oxidation state (and may also be present as ion of the respective element).

According to embodiments of the present disclosure, phosphorescence materials P^{B} used in organic electroluminescent devices may be complexes of Ir, Pd, Pt, Au, Os, Eu, Ru, Re, Ag and Cu, in the context of embodiments of the present disclosure, for example, of Ir, Pt, and Pd, for example, of Ir and Pt. Any suitable phosphorescence materials generally used in the art may be used as phosphorescence materials P^{B} in optoelectronic devices of embodiments of the present disclosure and may be synthesized according to any suitable method generally used in the art. Furthermore, any suitable design principles of phosphorescent complexes for use as phosphorescence materials in optoelectronic devices generally used in the art may be used in embodiments of the present disclosure and the emission of the complexes may be tuned by any suitable structural variations generally used in the art.

Any suitable phosphorescence material generally used in the art may be used as phosphorescence materials P^{B} to be used in optoelectronic devices of embodiments of the present disclosure and may be synthesized by any suitable method generally used in the art. According to embodiments of the present disclosure, any suitable design principles of phosphorescent complexes for use as phosphorescence materials P^{B} in optoelectronic devices generally used in the art may be used and the emission of the complexes may be tuned by any suitable structural variations generally used in the art.

Examples of phosphorescence materials P^{B} that may be used alongside the organic molecules according to embodiments of the present disclosure (for example in form of a composition or in an EML of an optoelectronic device, vide infra) are disclosed in the state of the art. For example, the following metal complexes are phosphorescence materials P^{B} that may be used alongside the organic molecules according to embodiments of the present disclosure:

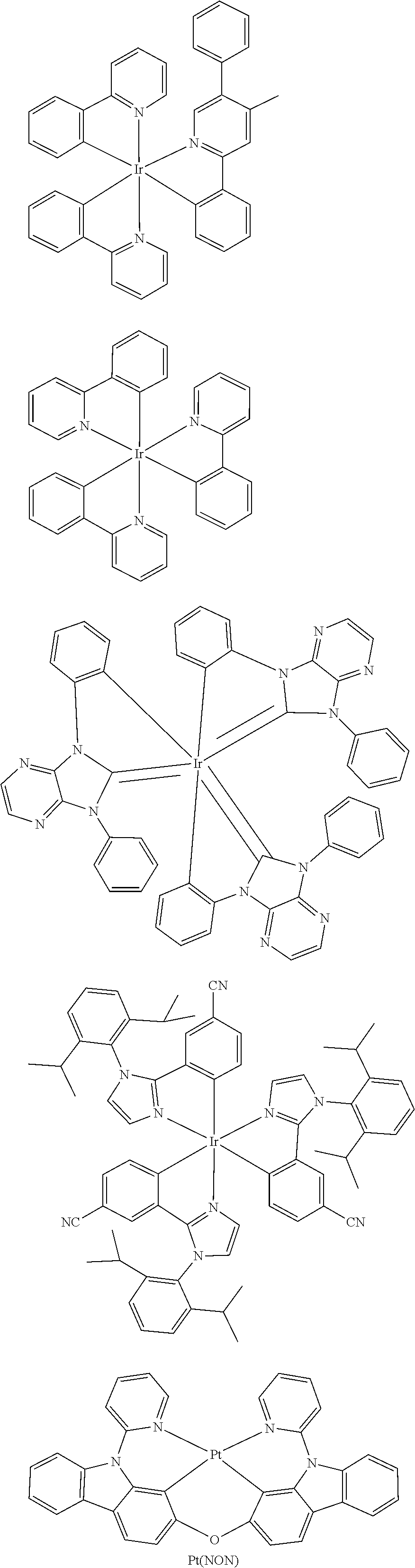

A small full width at half maximum (FWHM) emitter S^{B} in the context of embodiments of the present disclosure is any emitter (e.g., emitter material) that has an emission spectrum, which exhibits an FWHM of less than or equal to 0.35 eV (≤ 0.35 eV), for example, of less than or equal to 0.30 eV (≤ 0.30 eV), for example, of less than or equal to 0.25 eV (≤ 0.25 eV). Unless stated otherwise, this is judged based on an emission spectrum of the respective emitter at room temperature (e.g., (approximately) 20° C.), for example, measured with 1 to 5% by weight, for example, with 2% by weight, of the emitter in poly(methyl methacrylate) PMMA or mCBP. Alternatively, emission spectra of small FWHM emitters S^{B} may be measured in a solution, for example, with 0.001-0.2 mg/ml of the emitter S^{B} in dichloromethane or toluene at room temperature (e.g., (approximately) 20° C.).

A small FWHM emitter S^{B} may be a fluorescence emitter F, a phosphorescence emitter (for example a phosphorescence material P^{B}) and/or a TADF emitter (for example a TADF material E^{B}). For TADF materials E^{B} and for phosphorescence materials P^{B} as laid out above, the emission spectrum is recorded at room temperature (e.g., approximately 20° C.) from a spin-coated film of the respective material in poly(methyl methacrylate) PMMA, with 10% by weight of the respective molecule of embodiments of the present disclosure, E^{B} or P^{B}.

According to embodiments of the present disclosure, the full width at half maximum (FWHM) of an emitter (for example a small FWHM emitter S^{B}) may be readily determined from the respective emission spectrum (fluorescence spectrum for fluorescence emitters and phosphorescence spectrum for phosphorescence emitters). All reported FWHM values may refer to the main emission peak (e.g., the peak with the highest intensity). The method of determining the FWHM (herein, for example, reported in electron volts, eV) may be any suitable one generally used in the art. Given for example that the main emission peak of an emission spectrum reaches its half maximum emission (e.g., 50% of the maximum emission intensity) at the two wavelengths λ₁ and λ₂, both obtained in nanometers (nm) from the emission spectrum, the FWHM in electron volts (eV) may be (and herein) determined using the following equation:

$$FWHM [ eV ] = \vert \frac{1239.84 [ eV \cdot nm ]}{{λ}_{2} [ nm ]} - \frac{1239.84 [ eV \cdot nm ]}{{λ}_{1} [ nm ]} \vert$$

In the context of embodiments of the present disclosure, a small FWHM emitter S^{B} is an organic emitter, which, in the context of embodiments of the present disclosure, means that it does not contain any transition metals. For example, a small FWHM emitter S^{B} in the context of embodiments of the present disclosure predominantly consists of the elements hydrogen (H), carbon (C), nitrogen (N), and boron (B), but may for example also include oxygen (O), silicon (Si), fluorine (F), and bromine (Br).

Furthermore, a small FWHM emitter S^{B} in the context of embodiments of the present disclosure is a fluorescence emitter F that may or may not additionally exhibit TADF.

For example, a small FWHM emitter S^{B} in the context of embodiments of the present disclosure, for example, fulfills at least one of the following requirements:
(i) it is a boron (B)-containing emitter, which means that at least one atom within the respective small FWHM emitter S^{B} is boron (B);
(ii) it includes a polycyclic aromatic or heteroaromatic core structure, wherein at least two aromatic rings are fused together (e.g., anthracene, pyrene or aza-derivatives thereof).

In some embodiments, a host material H^{B} of an EML may transport electrons or positive charges through said EML and may also transfer excitation energy to the at least one emitter material doped in the host material(s) H^{B}. According to embodiments of the present disclosure, a host material H^{B} included in an EML of an optoelectronic device (e.g., an OLED) may not significantly be involved in light emission from said device upon applying a voltage and electrical current. The person skilled in the art is also familiar with the fact that any host material H^{B} may be a p-host H^{P} exhibiting high hole mobility, an n-host H^{N} exhibiting high electron mobility, or a bipolar host material HBP exhibiting both, high hole mobility and high electron mobility.

In some embodiments, an EML may also include a so-called mixed-host system with at least one p-host H^{P} and one n-host H^{N}. In some embodiments, the EML may include exactly one emitter material according to embodiments of the present disclosure and a mixed-host system including T2T (2,4,6-tris(biphenyl-3-yl)-1,3,5-triazine) as n-host H^{N} and a host selected from CBP, mCP, mCBP, 4,6-diphenyl-2-(3-(triphenylsilyl)phenyl)-1,3,5-triazine, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as p-host H^{P}.

An EML may include a so-called mixed-host system with at least one p-host H^{P} and one n-host H^{N}; wherein the n-host H^{N} includes groups derived from pyridine, pyrimidine, benzopyrimidine, 1,3,5-triazine, 1,2,4-triazine, and 1,2,3-triazine, while the p-host H^{P} includes groups derived from indole, isoindole, and, for example, carbazole.

Any suitable materials generally used in the art as host materials may be used as host materials in organic electroluminescent devices of embodiments of the present disclosure. It is understood that any suitable host materials that are used in the state of the art may be suitable host materials H^{B} in the context of embodiments of the present disclosure.

Examples of materials H^{B} that are p-host materials H^{P} in the context of embodiments of the present disclosure are listed below:

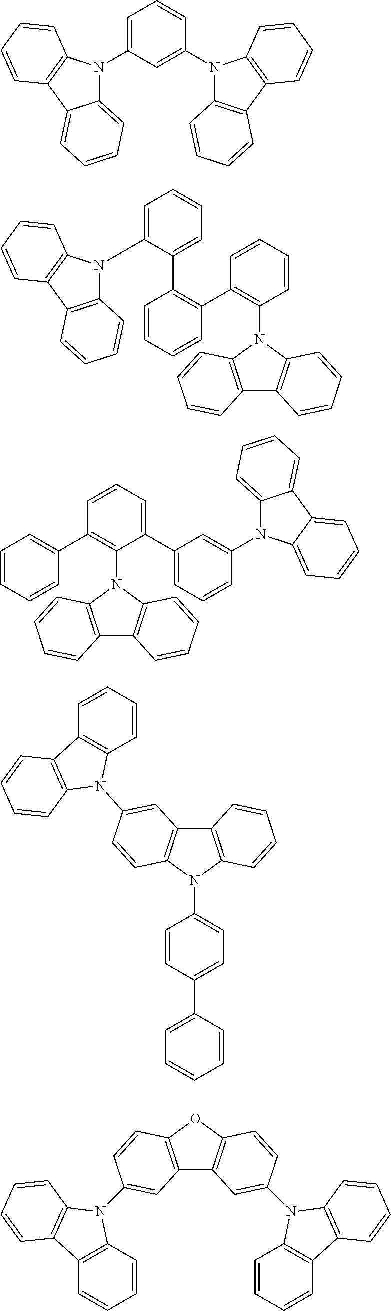

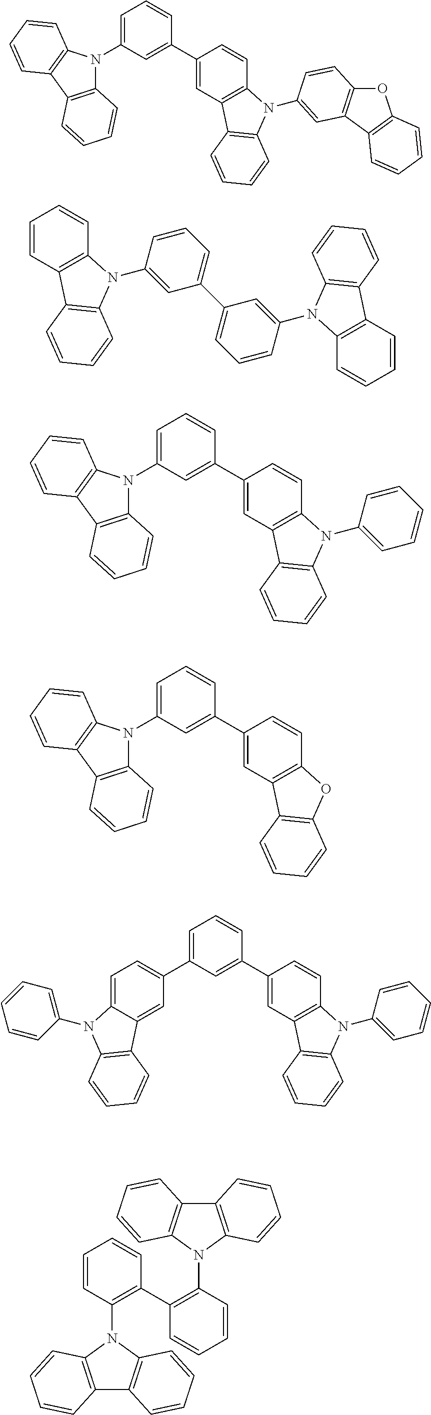 [SMILES: c1cc(-c2ccc3c(c2)c2ccccc2n3-c2ccc3oc4ccccc4c3c2)cc(-n2c3ccccc3c3ccccc32)c1 ; c1cc(-c2cccc(-n3c4ccccc4c4ccccc43)c2)cc(-n2c3ccccc3c3ccccc32)c1 ; c1ccc(-n2c3ccccc3c3cc(-c4cccc(-n5c6ccccc6c6ccccc65)c4)ccc32)cc1 ; c1cc(-c2ccc3oc4ccccc4c3c2)cc(-n2c3ccccc3c3ccccc32)c1 ; c1ccc(-n2c3ccccc3c3cc(-c4cccc(-c5ccc6c(c5)c5ccccc5n6-c5ccccc5)c4)ccc32)cc1 ; c1ccc(-n2c3ccccc3c3ccccc32)c(-c2ccccc2-n2c3ccccc3c3ccccc32)c1]

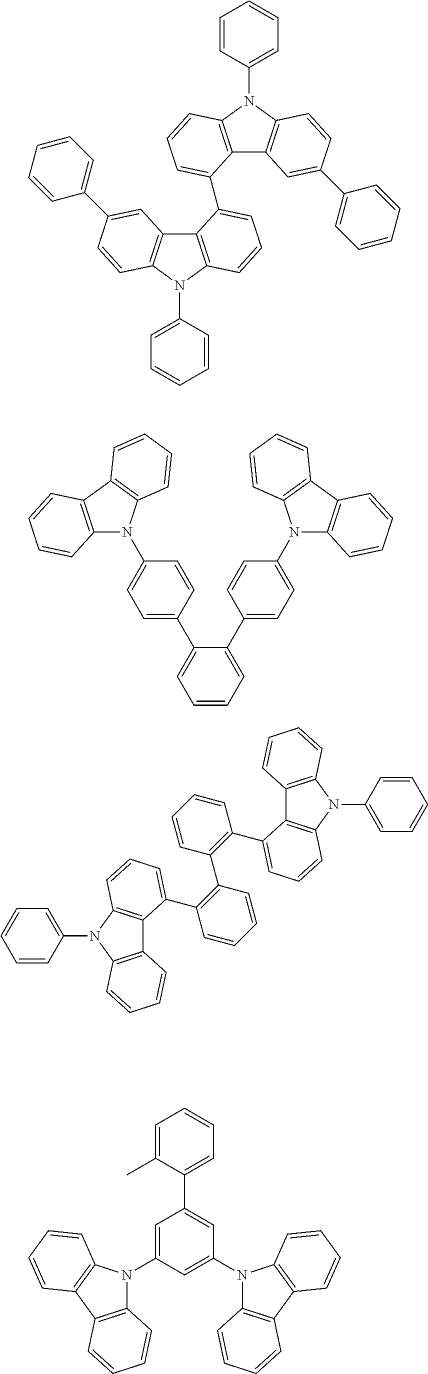 [SMILES: c1ccc(-c2ccc3c(c2)c2c(-c4cccc5c4c4cc(-c6ccccc6)ccc4n5-c4ccccc4)cccc2n3-c2ccccc2)cc1 ; c1ccc(-c2ccc(-n3c4ccccc4c4ccccc43)cc2)c(-c2ccc(-n3c4ccccc4c4ccccc43)cc2)c1 ; c1ccc(-n2c3ccccc3c3c(-c4ccccc4-c4ccccc4-c4cccc5c4c4ccccc4n5-c4ccccc4)cccc32)cc1 ; Cc1ccccc1-c1cc(-n2c3ccccc3c3ccccc32)cc(-n2c3ccccc3c3ccccc32)c1]

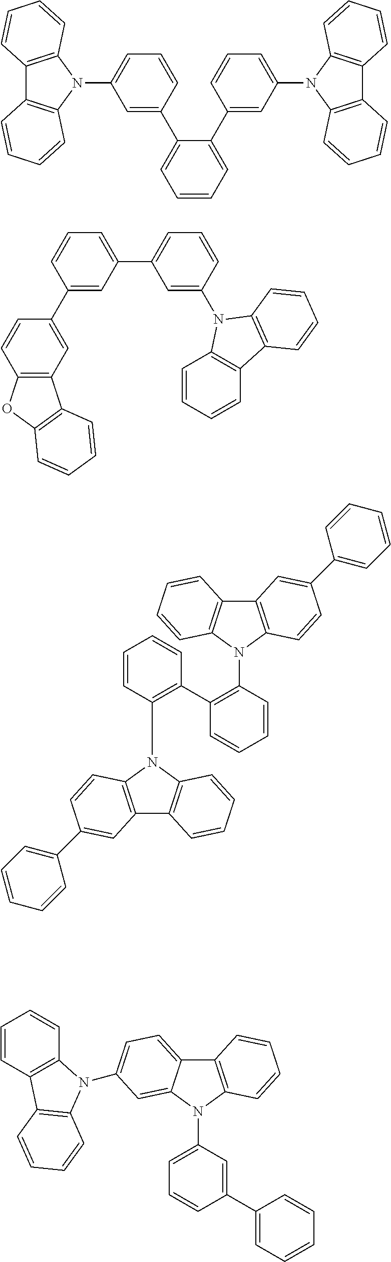

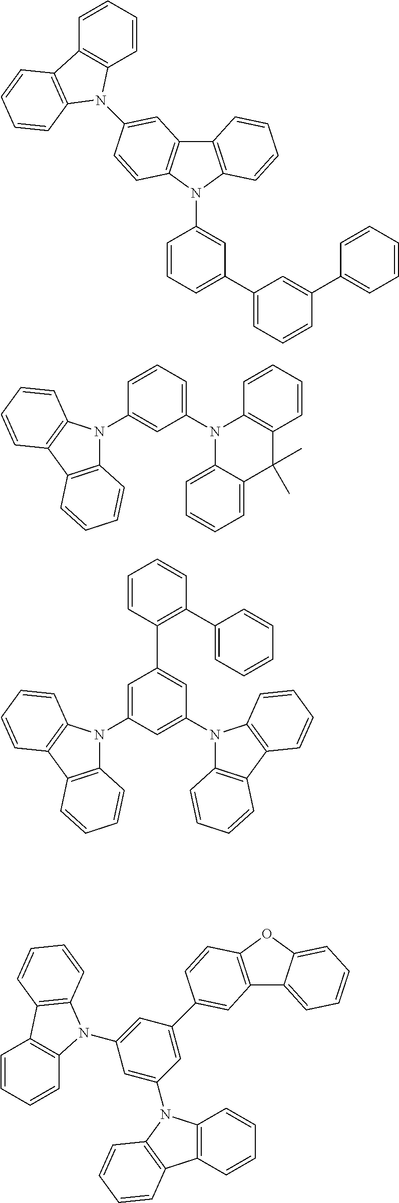

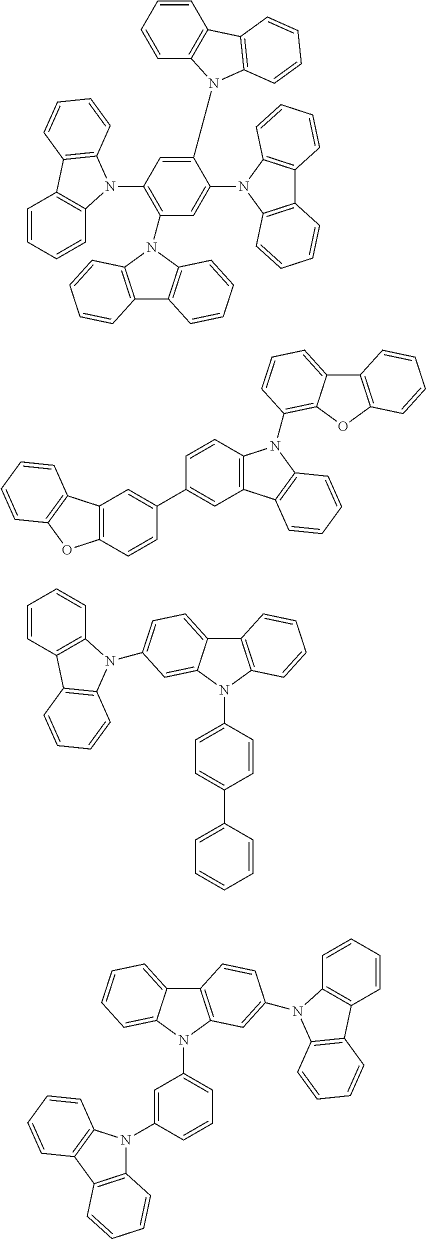

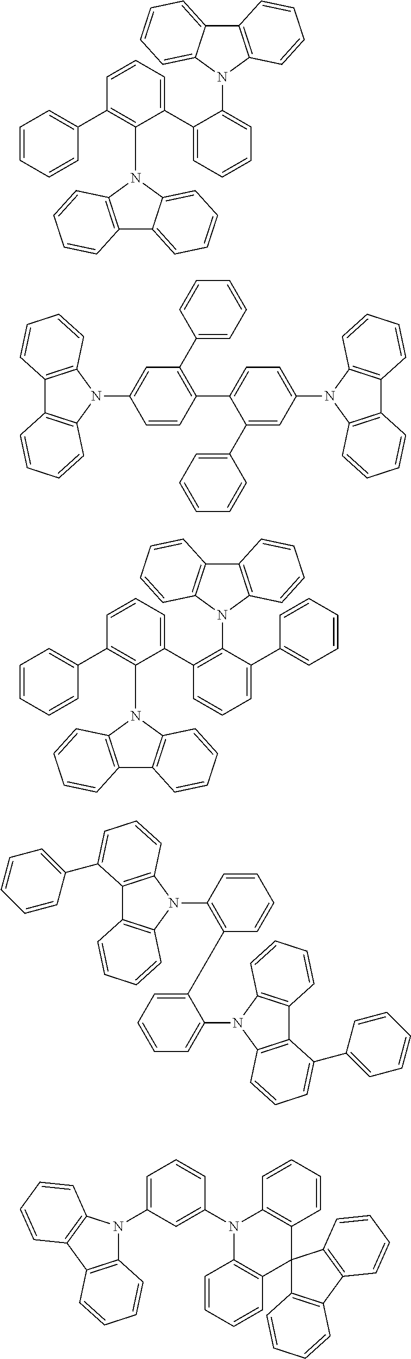

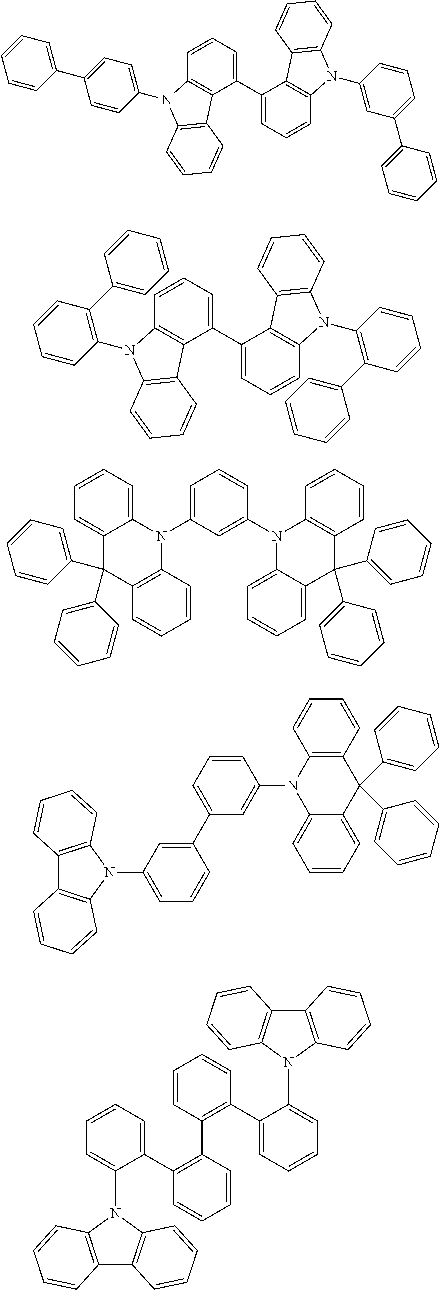

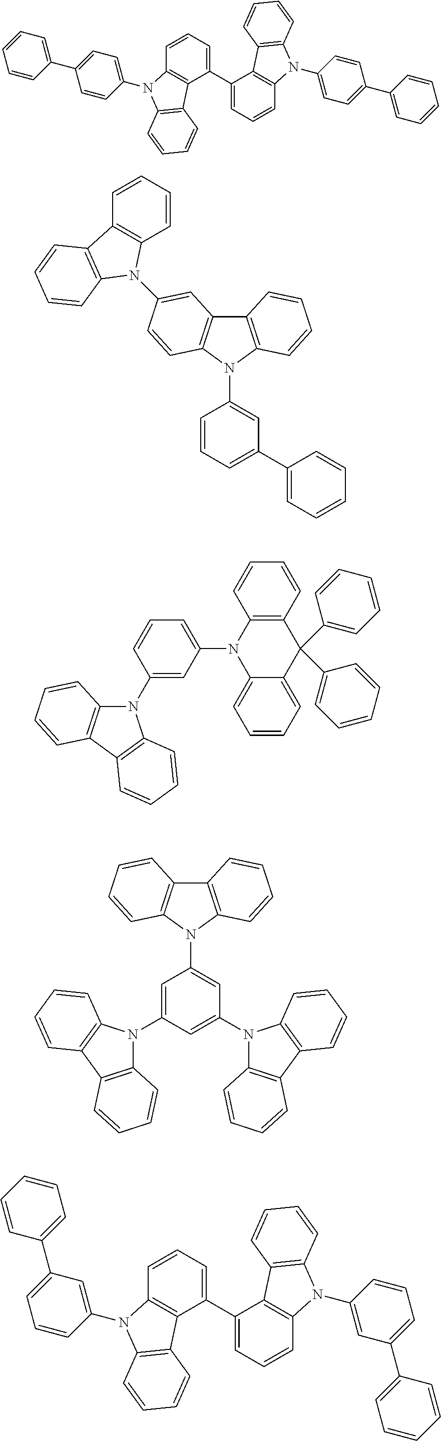

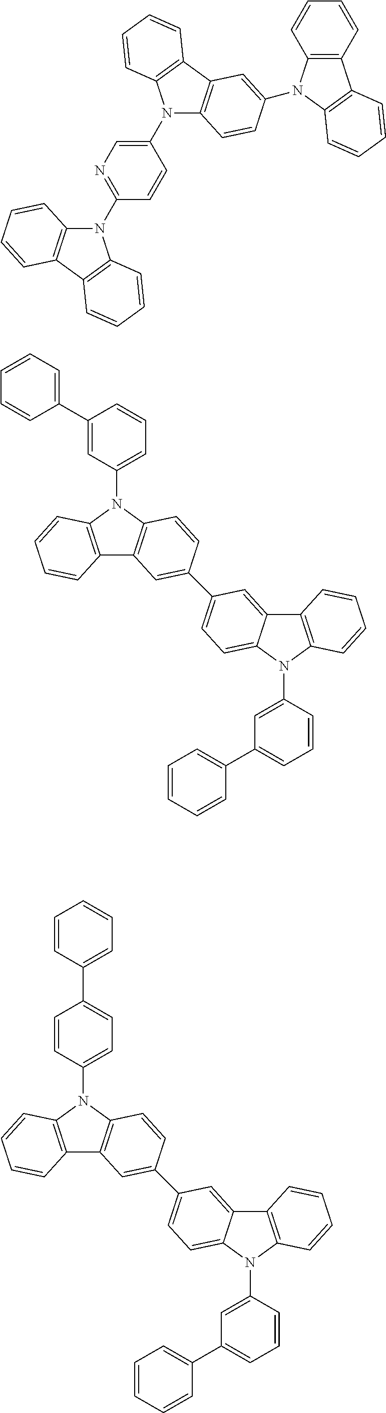 [SMILES: c1ccc2c(c1)c1ccccc1n2-c1ccc2c(c1)c1ccccc1n2-c1ccc(-n2c3ccccc3c3ccccc32)nc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

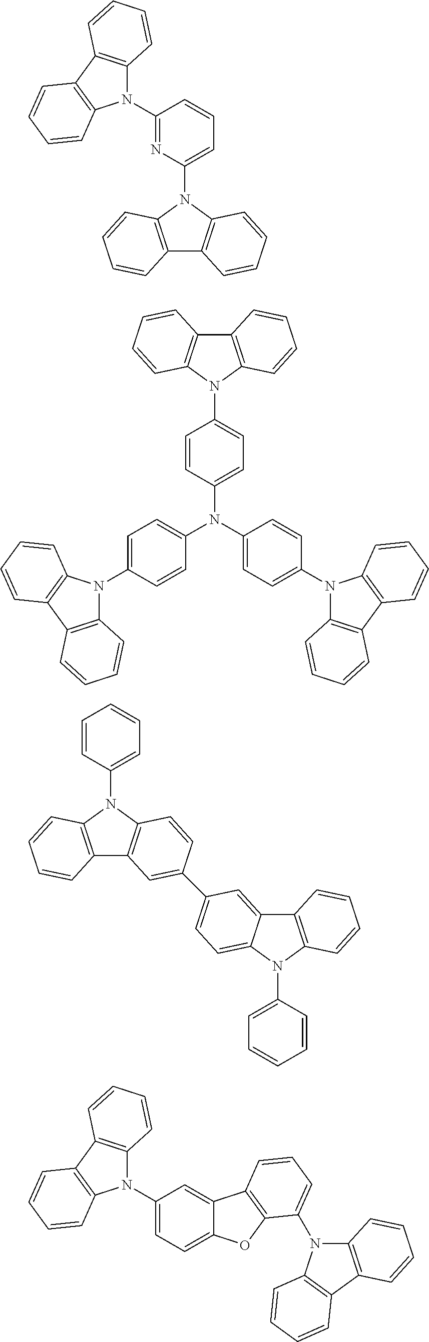

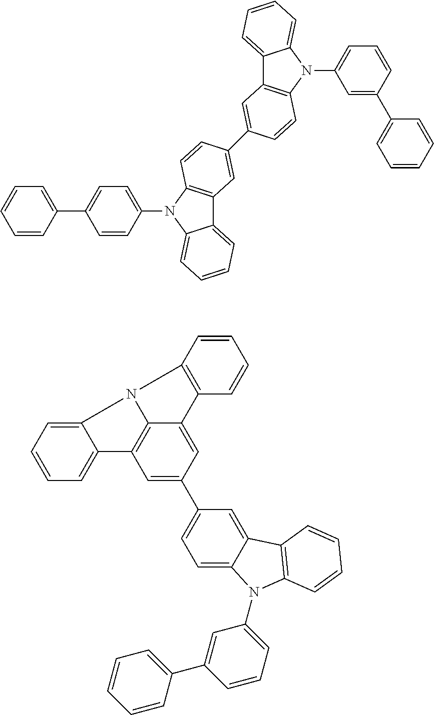 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-n3c4ccccc4c4cc(-c5cc6c7ccccc7n7c8ccccc8c(c5)c67)ccc43)c2)cc1]

Examples of materials H^{B} that are n-host materials H^{N} in the context of embodiments of the present disclosure are listed below:

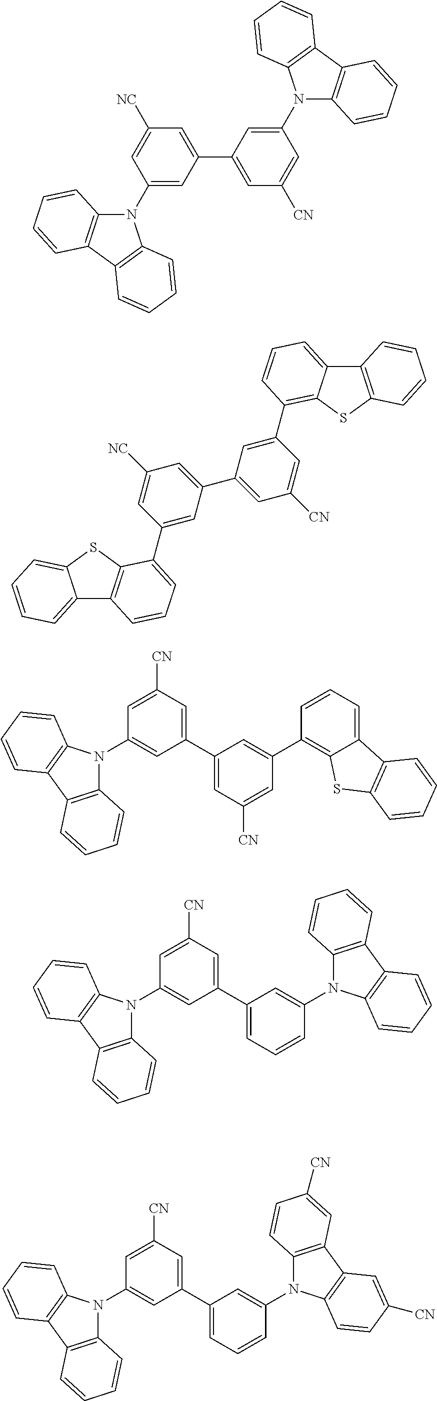

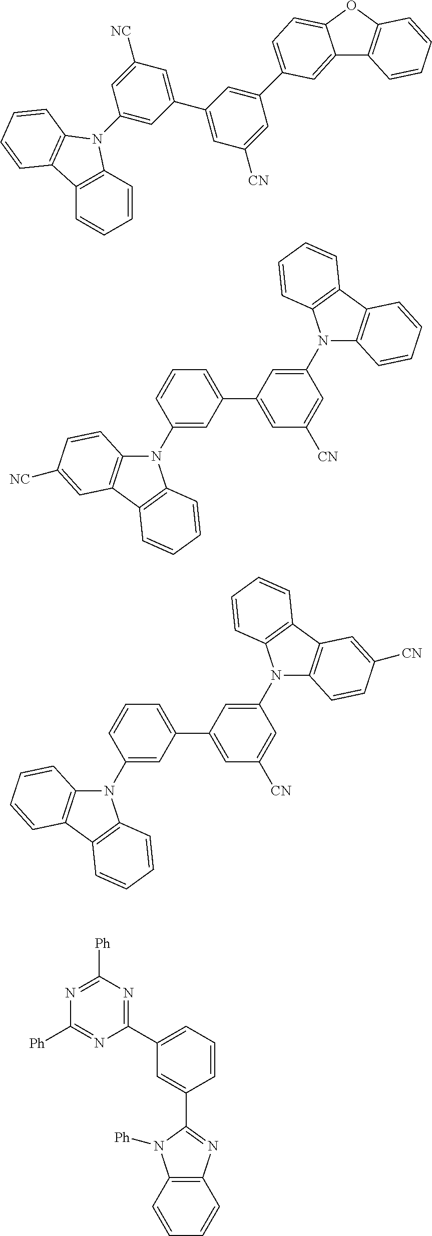 [SMILES: N#Cc1cc(-c2cc(C#N)cc(-n3c4ccccc4c4ccccc43)c2)cc(-c2ccc3oc4ccccc4c3c2)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; c1ccc(-c2nc(-c3ccccc3)nc(-c3cccc(-c4nc5ccccc5n4-c4ccccc4)c3)n2)cc1]

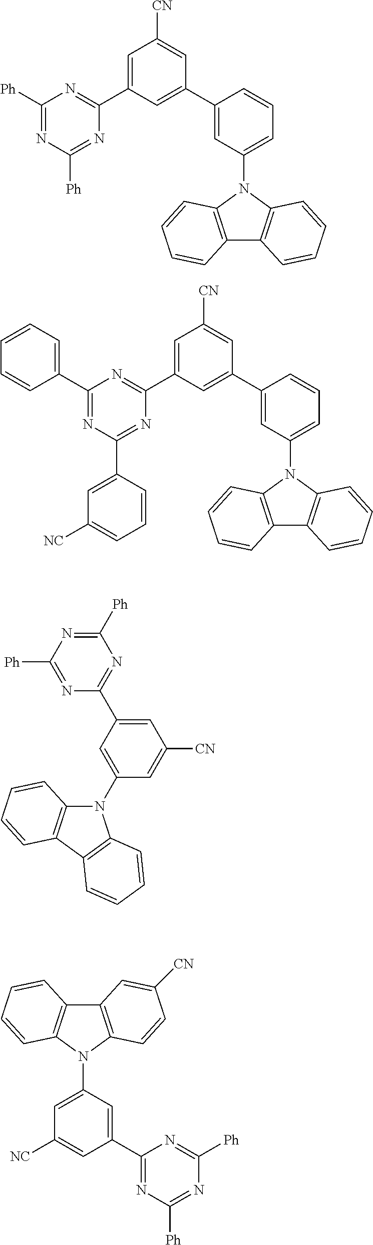

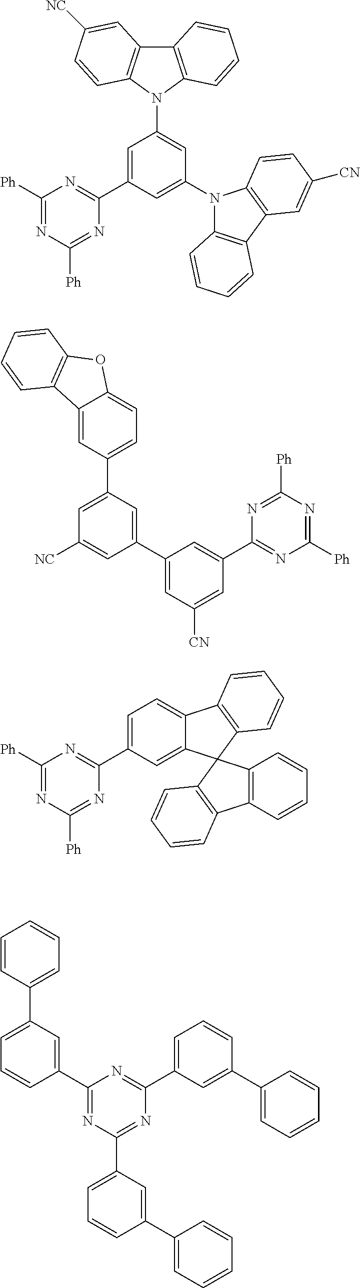 [SMILES: N#Cc1ccc2c(c1)c1ccccc1n2-c1cc(-c2nc(-c3ccccc3)nc(-c3ccccc3)n2)cc(-n2c3ccccc3c3cc(C#N)ccc32)c1 ; N#Cc1cc(-c2cc(C#N)cc(-c3nc(-c4ccccc4)nc(-c4ccccc4)n3)c2)cc(-c2ccc3oc4ccccc4c3c2)c1 ; c1ccc(-c2nc(-c3ccccc3)nc(-c3ccc4c(c3)C3(c5ccccc5-c5ccccc53)c3ccccc3-4)n2)cc1 ; c1ccc(-c2cccc(-c3nc(-c4cccc(-c5ccccc5)c4)nc(-c4cccc(-c5ccccc5)c4)n3)c2)cc1]

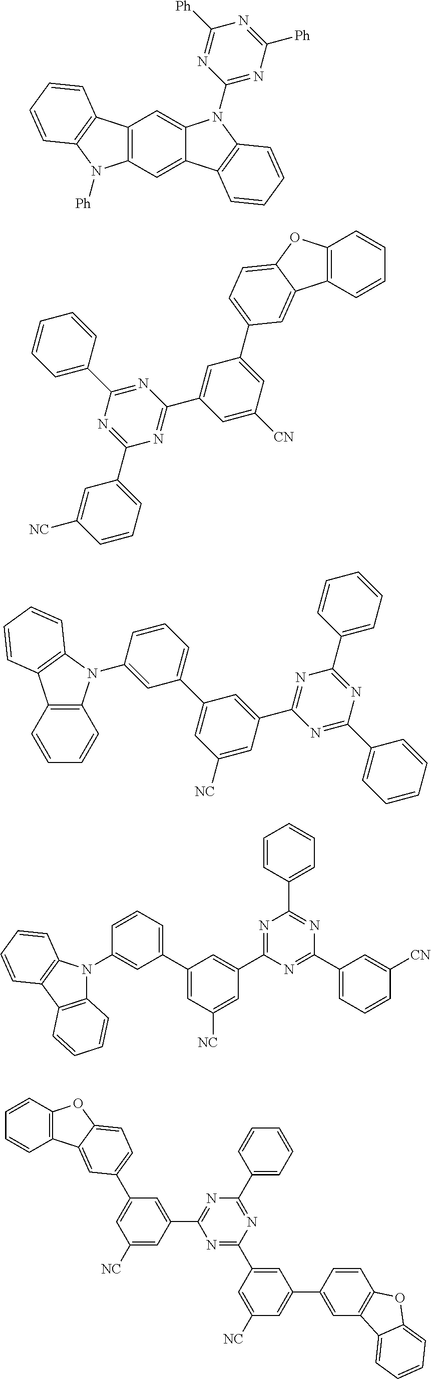

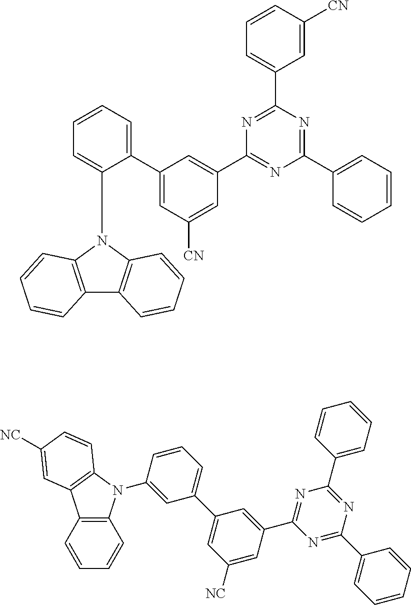 [SMILES: N#Cc1cccc(-c2nc(-c3ccccc3)nc(-c3cc(C#N)cc(-c4ccccc4-n4c5ccccc5c5ccccc54)c3)n2)c1 ; N#Cc1cc(-c2cccc(-n3c4ccccc4c4cc(C#N)ccc43)c2)cc(-c2nc(-c3ccccc3)nc(-c3ccccc3)n2)c1]

The person skilled in the art understands that any materials that are included in the same layer, for example, in the same EML, but also materials that are in adjacent layers and get in close proximity at the interface between these adjacent layers, may together form an exciplex. According to embodiments of the present disclosure, any suitable method generally used in the art may be used to choose pairs of materials, for example, pairs of a p-host H^{P} and an n-host H^{N}, which form an exciplex and the selection criteria for the two components of said pair of materials may be any suitable ones generally used in the art, including HOMO- and/or LUMO-energy level requirements. This is to say that, in case exciplex formation may be aspired, the highest occupied molecular orbital (HOMO) of the one component, e.g., the p-host material H^{P}, may be at least 0.20 eV higher in energy than the HOMO of the other component, e.g., the n-host material H^{N}, and the lowest unoccupied molecular orbital (LUMO) of the one component, e.g., the p-host material H^{P}, may be at least 0.20 eV higher in energy than the LUMO of the other component, e.g., the n-host material H^{N}. According to embodiments of the present disclosure, if present in an EML of an optoelectronic device, for example, an OLED, an exciplex may have the function of an emitter material and emit light when a voltage and electrical current are applied to said device. According to embodiments of the present disclosure, an exciplex may also be non-emissive and may for example transfer excitation energy to an emitter material, if included in an EML of an optoelectronic device.

In some embodiments, triplet-triplet annihilation (TTA) materials can be used as host materials H^{B}. The TTA material enables triplet-triplet annihilation. Triplet-triplet annihilation may, for example, result in a photon up-conversion. Accordingly, two, three or even more photons may facilitate photon up-conversion from the lowermost excited triplet state (T1^{TTA}) to the first excited singlet state S1^{TTA} of the TTA material H^{TTA}. In some embodiments, two photons facilitate photon up-conversion from T1^{TTA} to S1^{TTA}. Triplet-triplet annihilation may thus be a process that through a number of energy transfer steps, may combine two (or optionally more than two) low frequency photons into one photon of higher frequency.

Optionally, the TTA material may include an absorbing moiety, the sensitizer moiety, and an emitting moiety (or annihilator moiety). In this context, an emitter moiety may, for example, be a polycyclic aromatic moiety such as, benzene, biphenyl, triphenyl, triphenylene, naphthalene, anthracene, phenalene, phenanthrene, fluorene, pyrene, chrysene, perylene, azulene. In some embodiments, the polycyclic aromatic moiety includes an anthracene moiety or a derivative thereof. A sensitizer moiety and an emitting moiety may be located in two different chemical compounds (e.g., separated chemical entities) or may be both moieties embraced by one chemical compound.

According to embodiments of the present disclosure, a triplet-triplet annihilation (TTA) material converts energy from first excited triplet states T1^{N} to first excited singlet states S1^{N} by triplet-triplet annihilation.

According to embodiments of the present disclosure, a TTA material is characterized in that it exhibits triplet-triplet annihilation from the lowermost excited triplet state (T1^{N}) resulting in a triplet-triplet annihilated first excited singlet state S1^{N}, having an energy of up to two times the energy of T1^{N}.

In one embodiment of the present disclosure, a TTA material is characterized in that it exhibits triplet-triplet annihilation from T1^{N} resulting in S1^{N}, having an energy of 1.01 to 2 fold, 1.1 to 1.9 fold, 1.2 to 1.5 fold, 1.4 to 1.6 fold, or 1.5 to 2 fold times the energy of T1N.

As used herein, the terms “TTA material” and “TTA compound” may be understood interchangeably.

Example “TTA material” can be found in the state of the art related to blue fluorescent OLEDs, as described by Kondakov (Philosophical Transactions of the Royal Society A: Mathematical, Physical and Engineering Sciences, 2015, 373:20140321). Such blue fluorescent OLEDs employ aromatic hydrocarbons such as anthracene derivatives as the main component (host) in the EML.

In some embodiments, the TTA material enables sensitized triplet-triplet annihilation. Optionally, the TTA material may include one or more polycyclic aromatic structures. In some embodiments, the TTA material includes at least one polycyclic aromatic structure and at least one further aromatic residue.

In some embodiments, the TTA material bears larger singlet-triplet energy splitting, e.g., an energy difference between its first excited singlet state S1^{N} and its lowermost excited triplet state T1^{N} of at least 1.1 fold, at least 1.2 fold, at least 1.3 fold, at least 1.5 fold and, for example, not more than 2 fold.

In some embodiments of embodiments of the present disclosure, the TTA material H^{TTA} is an anthracene derivative.

In one embodiment, the TTA material H^{TTA} is an anthracene derivative of the following Formula 4

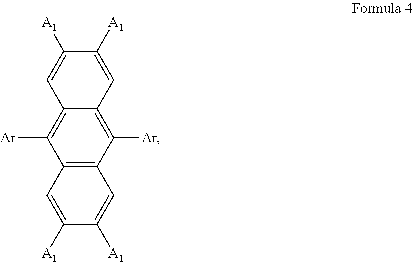

wherein each Ar is independently from each other selected from the group consisting of C₆-C₆₀-aryl, which is optionally substituted with one or more residues selected from the group consisting of C₆-C₆₀-aryl, C₃-C₅₇-heteroaryl, halogen, and C₁-C₄₀-(hetero)alkyl;
and C₃-C₅₇-heteroaryl, which is optionally substituted with one or more residues selected from the group consisting of C₆-C₆₀-aryl, C₃-C₅₇-heteroaryl, halogen, and C₁-C₄₀-(hetero)alkyl; and
each A₁ is independently from each other selected from the group consisting of consisting of
hydrogen;
deuterium;
C₆-C₆₀-aryl, which is optionally substituted with one or more residues selected from the group consisting of C₆-C₆₀-aryl, C₃-C₅₇-heteroaryl, halogen, and C₁-C₄₀-(hetero)alkyl; C₃-C₅₇-heteroaryl, which is optionally substituted with one or more residues selected from the group consisting of C₆-C₆₀-aryl, C₃-C₅₇-heteroaryl, halogen, and C₁-C₄₀-(hetero)alkyl; and
C₁-C₄₀-(hetero)alkyl, which is optionally substituted with one or more residues selected from the group consisting of C₆-C₆₀-aryl, C₃-C₅₇-heteroaryl, halogen, and C₁-C₄₀-(hetero)alkyl.

In one embodiment, the TTA material H^{TTA} is an anthracene derivative of the following Formula 4, wherein each Ar is independently from each other selected from the group consisting of C₆-C₂₀-aryl, which is optionally substituted with one or more residues selected from the group consisting of C₆-C₂₀-aryl, C₃-C₂₀-heteroaryl, halogen, and C₁-C₁₀-(hetero)alkyl;
and C₃-C₂₀-heteroaryl, which is optionally substituted with one or more residues selected from the group consisting of C₆-C₂₀-aryl, C₃-C₂₀-heteroaryl, halogen, and C₁-C₁₀-(hetero)alkyl; and
each A₁ is independently from each other selected from the group consisting of consisting of
hydrogen,
deuterium,
C₆-C₂₀-aryl, which is optionally substituted with one or more residues selected from the group consisting of C₆-C₂₀-aryl, C₃-C₂₀-heteroaryl, halogen, and C₁-C₁₀-(hetero)alkyl,
C₃-C₂₀-heteroaryl, which is optionally substituted with one or more residues selected from the group consisting of C₆-C₂₀-aryl, C₃-C₂₀-heteroaryl, halogen, and C₁-C₁₀-(hetero)alkyl; and
C₁-C₁₀-(hetero)alkyl, which is optionally substituted with one or more residues selected from the group consisting of C₆-C₆₀-aryl, C₃-C₅₇-heteroaryl, halogen, and C₁-C₄₀-(hetero)alkyl.

In one embodiment, H^{TTA} is an anthracene derivative of the following Formula 4, wherein at least one of A₁ is hydrogen. In one embodiment, H^{TTA} is an anthracene derivative of the following Formula (4), wherein at least two of A₁ are hydrogen. In one embodiment, H^{TTA} is an anthracene derivative of the following Formula (4), wherein at least three of A₁ are hydrogen. In one embodiment, H^{TTA} is an anthracene derivative of the following Formula (4), wherein all of A₁ are each hydrogen.

In one embodiment, H^{TTA} is an anthracene derivative of the following Formula (4), wherein one of Ar is a residue selected from the group consisting of phenyl, naphthyl, phenanthryl, pyrenyl, triphenylenyl, dibenzoanthracenyl, fluorenyl, benzofluorenyl, anthracenyl, phenanthrenyl, benzonaphthofuranyl, benzonaphthothiophenyl, dibenzofuranyl, dibenzothiophenyl,
which may be each optionally substituted with one or more residues selected from the group consisting of C₆-C₆₀-aryl, C₃-C₅₇-heteroaryl, halogen, and C₁-C₄₀-(hetero)alkyl.

In one embodiment, H^{TTA} is an anthracene derivate of the following Formula (4), wherein both Ar are residues each independently from each other selected from the group consisting of phenyl, naphthyl, phenanthryl, pyrenyl, triphenylenyl, dibenzoanthracenyl, fluorenyl, benzofluorenyl, anthracenyl, phenanthrenyl, benzonaphthofuranyl, benzonaphthothiophenyl, dibenzofuranyl, dibenzothiophenyl,
which may be each optionally substituted with one or more residues selected from the group consisting of C₆-C₆₀-aryl, C₃-C₅₇-heteroaryl, halogen, and C₁-C₄₀-(hetero)alkyl.

In one embodiment, the TTA material H^{TTA} is an anthracene derivative selected from the following:

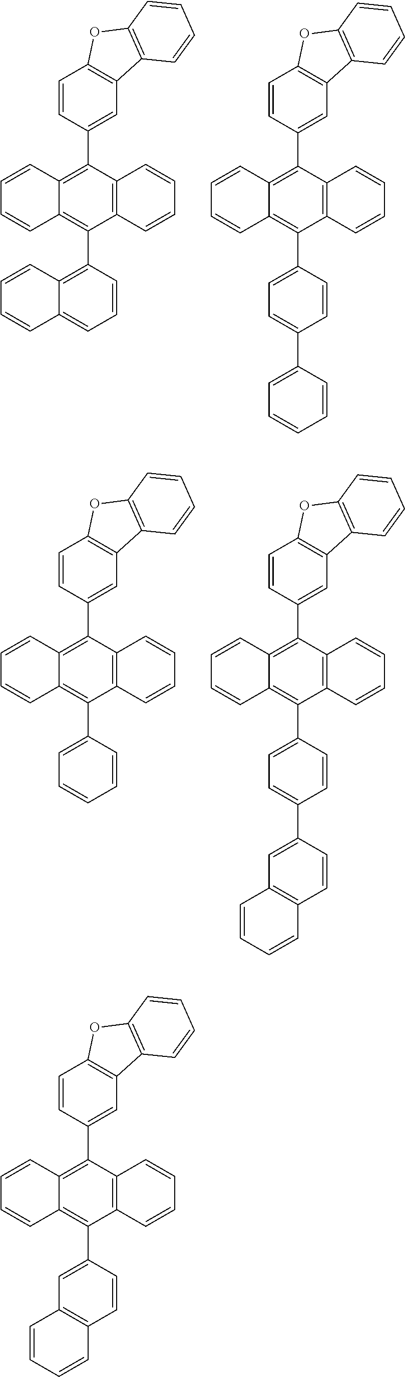

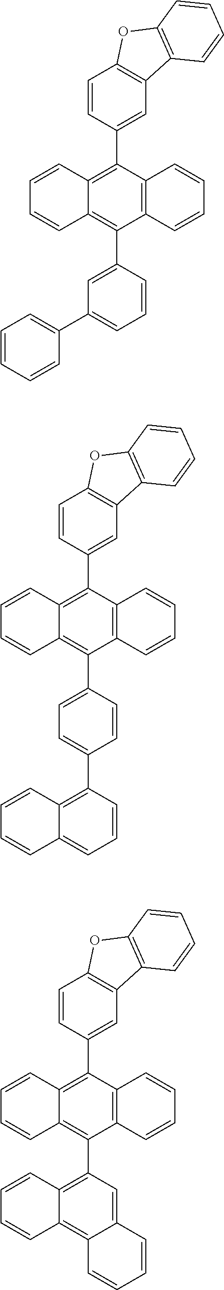 [SMILES: c1ccc(-c2cccc(-c3c4ccccc4c(-c4ccc5oc6ccccc6c5c4)c4ccccc34)c2)cc1 ; c1ccc2c(-c3ccc(-c4c5ccccc5c(-c5ccc6oc7ccccc7c6c5)c5ccccc45)cc3)cccc2c1 ; c1ccc2c(c1)cc(-c1c3ccccc3c(-c3ccc4oc5ccccc5c4c3)c3ccccc13)c1ccccc12]

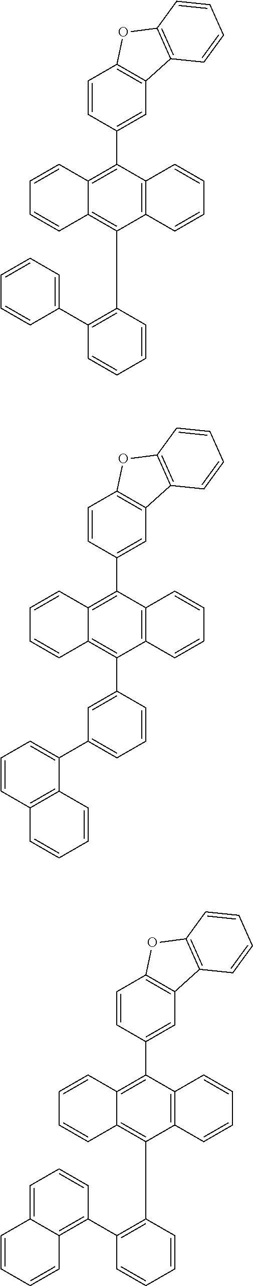 [SMILES: c1ccc(-c2ccccc2-c2c3ccccc3c(-c3ccc4oc5ccccc5c4c3)c3ccccc23)cc1 ; c1cc(-c2cccc3ccccc23)cc(-c2c3ccccc3c(-c3ccc4oc5ccccc5c4c3)c3ccccc23)c1 ; c1ccc(-c2c3ccccc3c(-c3ccc4oc5ccccc5c4c3)c3ccccc23)c(-c2cccc3ccccc23)c1]

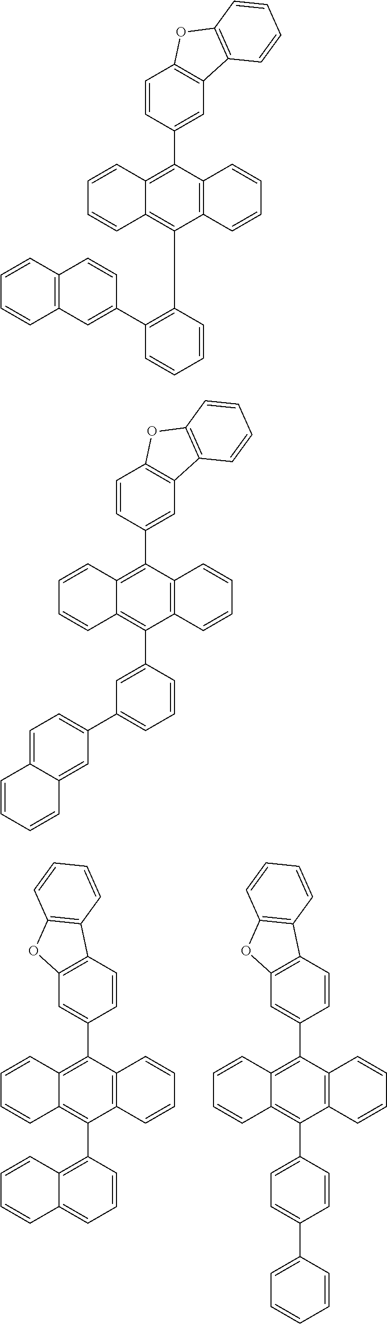

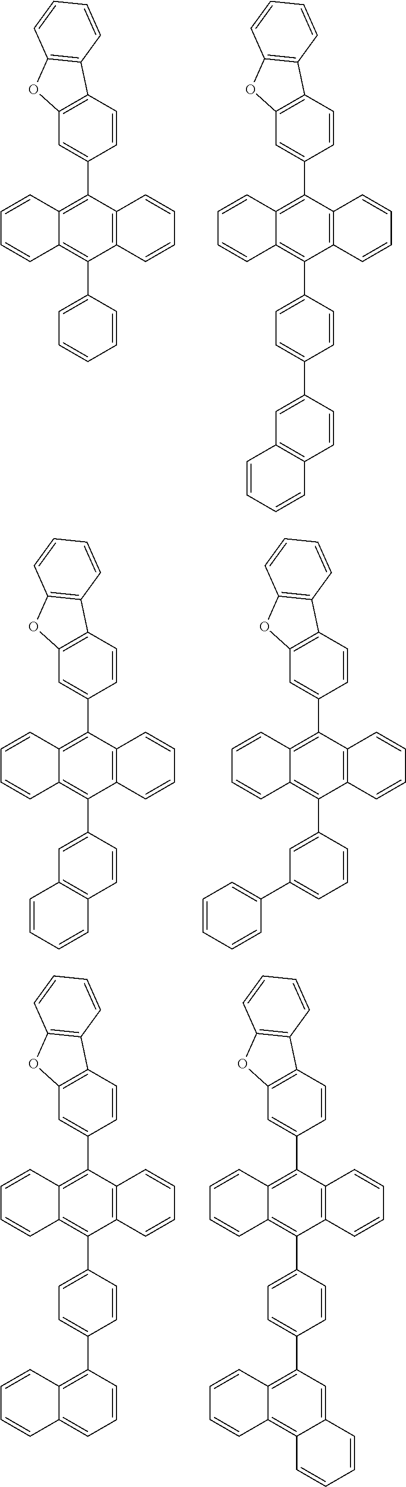

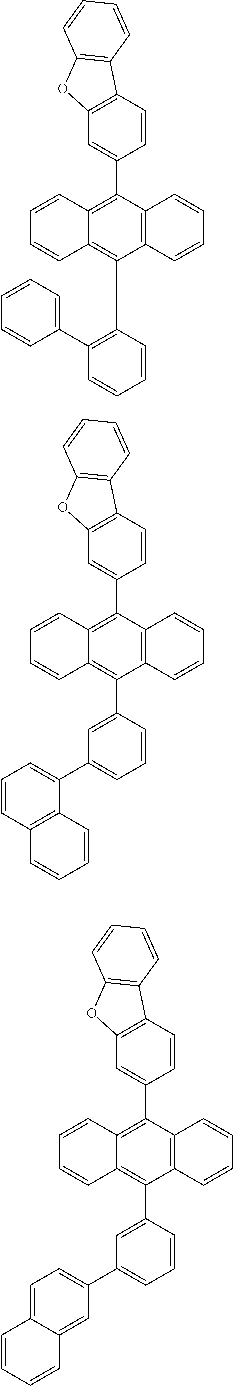

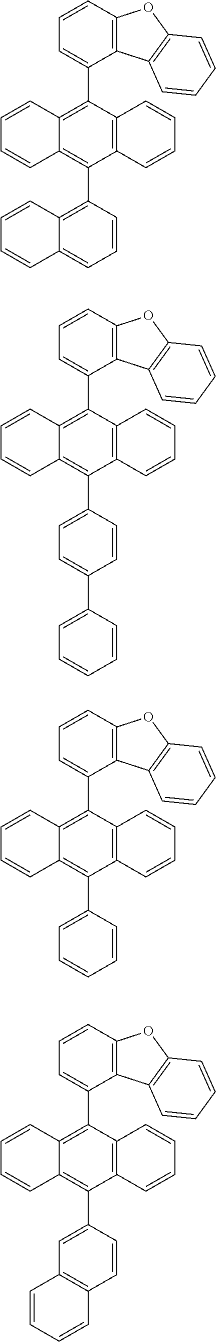

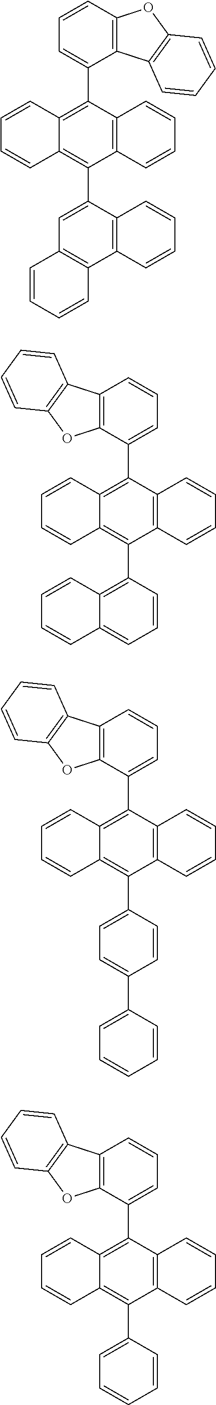

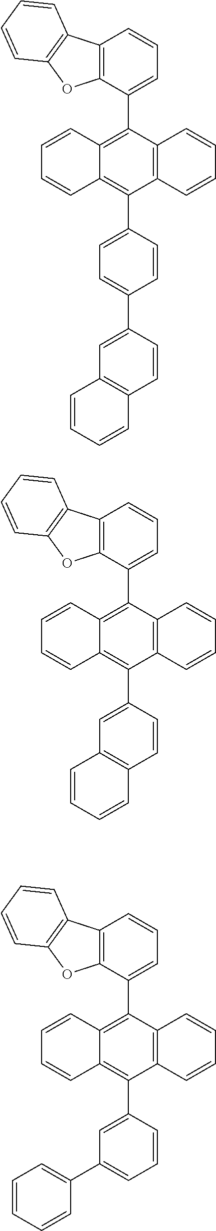 [SMILES: c1ccc2cc(-c3ccc(-c4c5ccccc5c(-c5cccc6c5oc5ccccc56)c5ccccc45)cc3)ccc2c1 ; c1ccc2cc(-c3c4ccccc4c(-c4cccc5c4oc4ccccc45)c4ccccc34)ccc2c1 ; c1ccc(-c2cccc(-c3c4ccccc4c(-c4cccc5c4oc4ccccc45)c4ccccc34)c2)cc1]

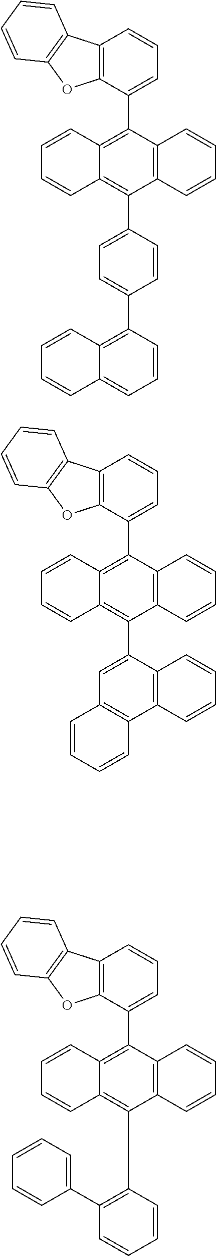

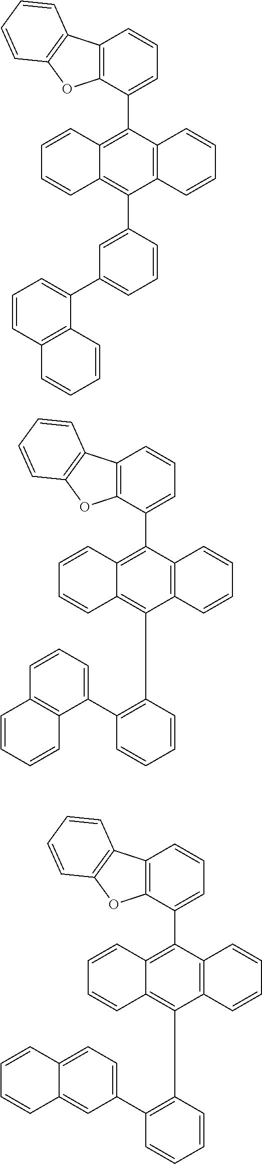

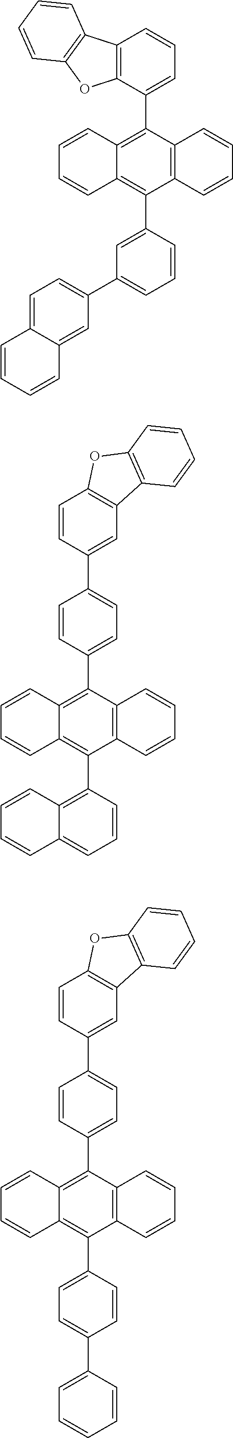 [SMILES: c1cc(-c2ccc3ccccc3c2)cc(-c2c3ccccc3c(-c3cccc4c3oc3ccccc34)c3ccccc23)c1 ; c1ccc2c(-c3c4ccccc4c(-c4ccc(-c5ccc6oc7ccccc7c6c5)cc4)c4ccccc34)cccc2c1 ; c1ccc(-c2ccc(-c3c4ccccc4c(-c4ccc(-c5ccc6oc7ccccc7c6c5)cc4)c4ccccc34)cc2)cc1]

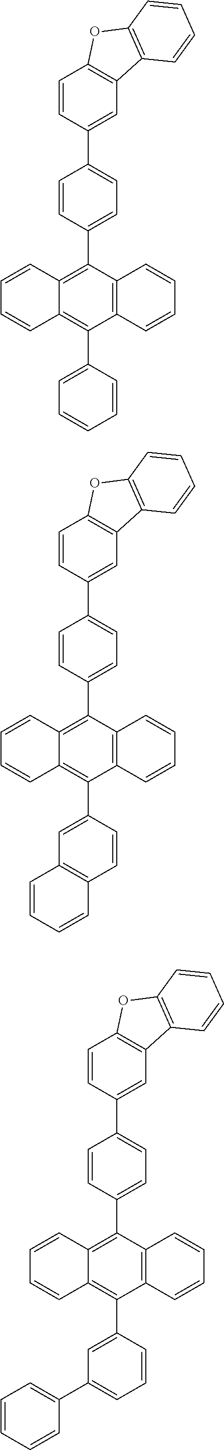 [SMILES: c1ccc(-c2c3ccccc3c(-c3ccc(-c4ccc5oc6ccccc6c5c4)cc3)c3ccccc23)cc1 ; c1ccc2cc(-c3c4ccccc4c(-c4ccc(-c5ccc6oc7ccccc7c6c5)cc4)c4ccccc34)ccc2c1 ; c1ccc(-c2cccc(-c3c4ccccc4c(-c4ccc(-c5ccc6oc7ccccc7c6c5)cc4)c4ccccc34)c2)cc1]

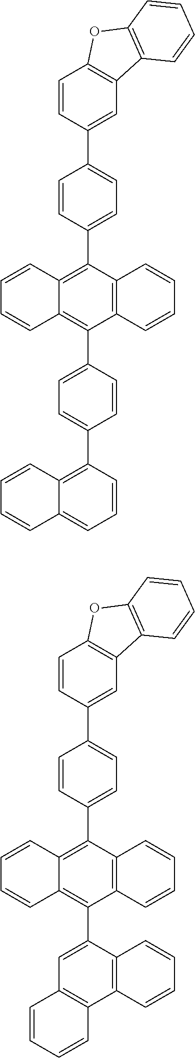 [SMILES: c1ccc2c(-c3ccc(-c4c5ccccc5c(-c5ccc(-c6ccc7oc8ccccc8c7c6)cc5)c5ccccc45)cc3)cccc2c1 ; c1ccc2c(c1)cc(-c1c3ccccc3c(-c3ccc(-c4ccc5oc6ccccc6c5c4)cc3)c3ccccc13)c1ccccc12]

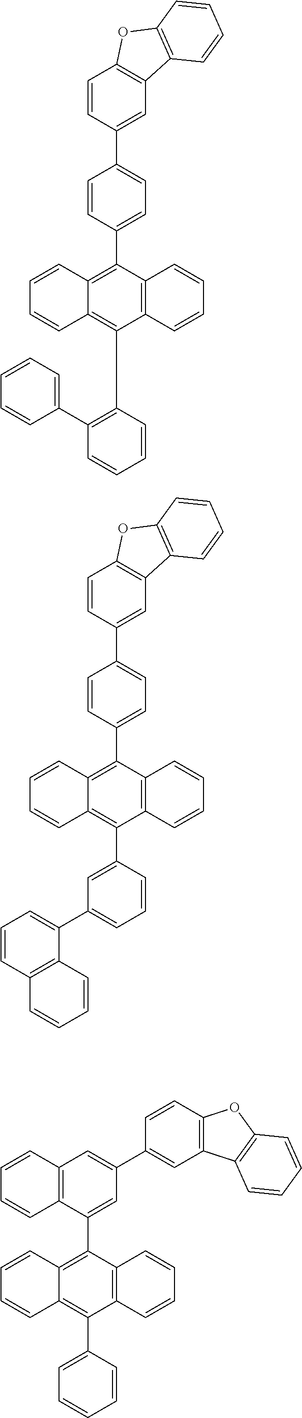 [SMILES: c1ccc(-c2ccccc2-c2c3ccccc3c(-c3ccc(-c4ccc5oc6ccccc6c5c4)cc3)c3ccccc23)cc1 ; c1cc(-c2cccc3ccccc23)cc(-c2c3ccccc3c(-c3ccc(-c4ccc5oc6ccccc6c5c4)cc3)c3ccccc23)c1 ; c1ccc(-c2c3ccccc3c(-c3cc(-c4ccc5oc6ccccc6c5c4)cc4ccccc34)c3ccccc23)cc1]

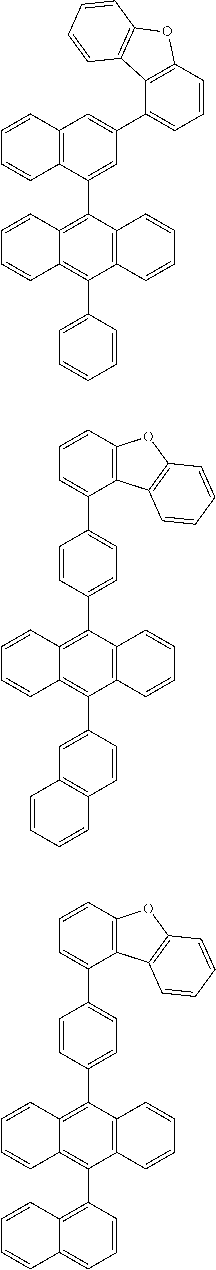 [SMILES: c1ccc(-c2c3ccccc3c(-c3cc(-c4cccc5oc6ccccc6c45)cc4ccccc34)c3ccccc23)cc1 ; c1ccc2cc(-c3c4ccccc4c(-c4ccc(-c5cccc6oc7ccccc7c56)cc4)c4ccccc34)ccc2c1 ; c1ccc2c(-c3c4ccccc4c(-c4ccc(-c5cccc6oc7ccccc7c56)cc4)c4ccccc34)cccc2c1]

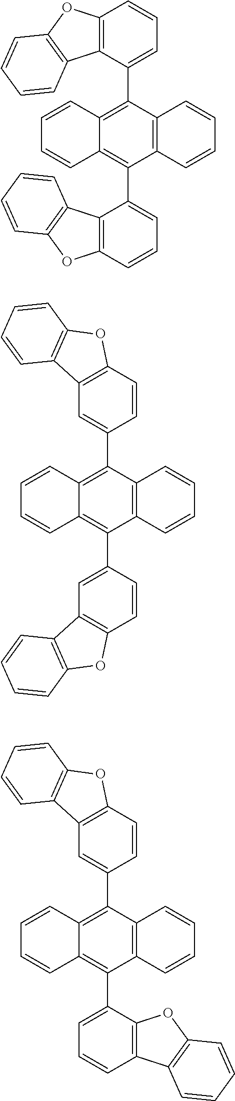

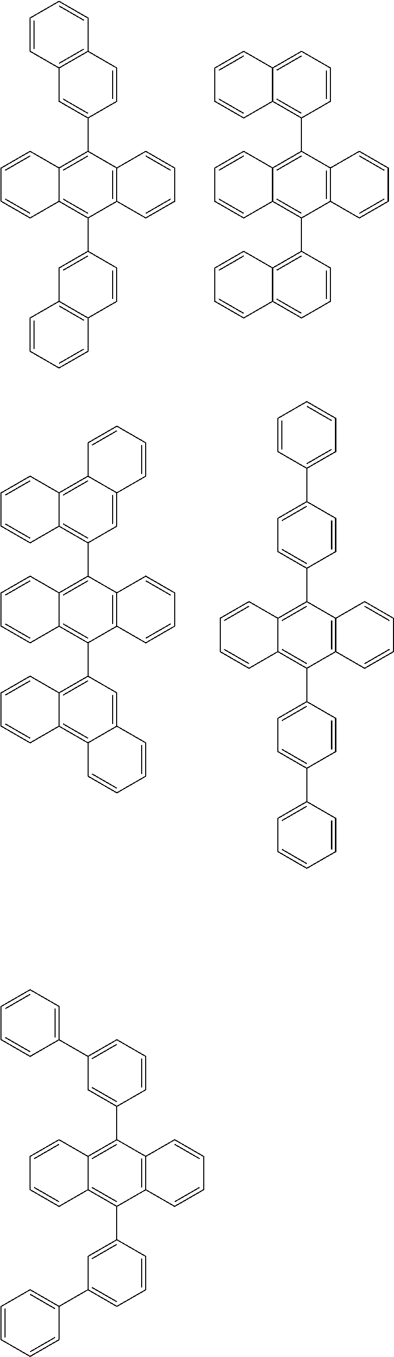

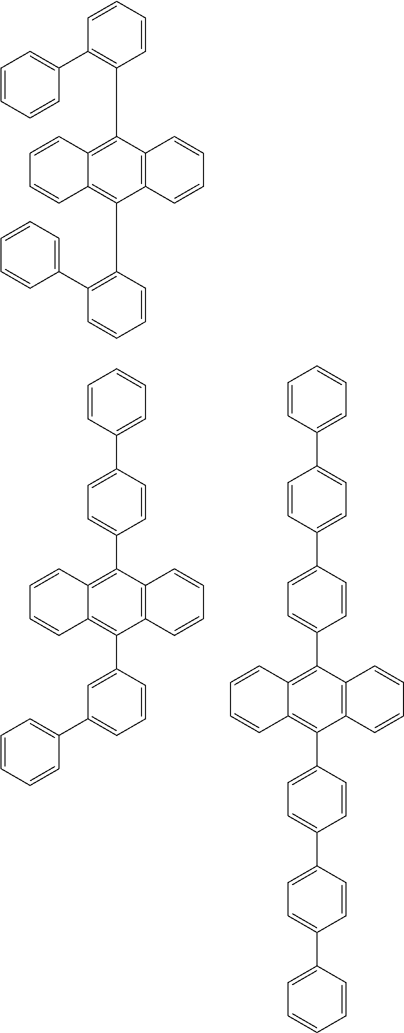

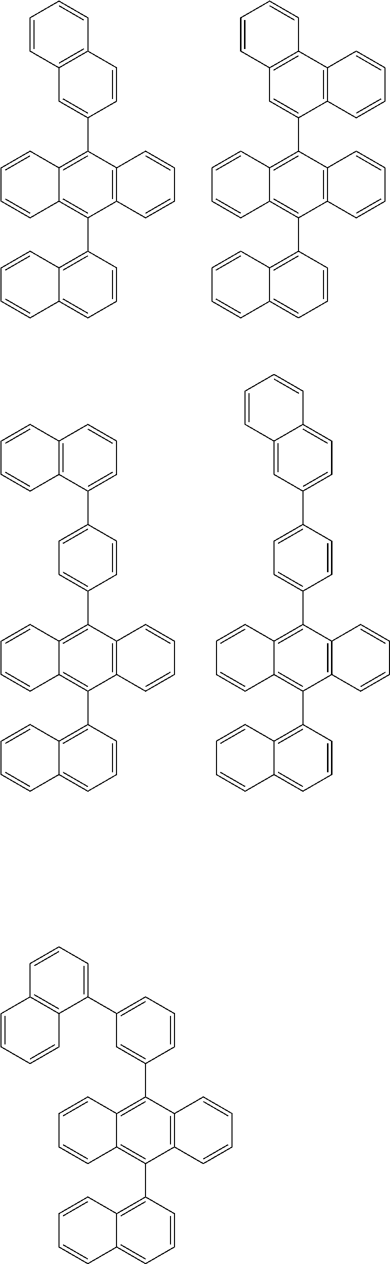

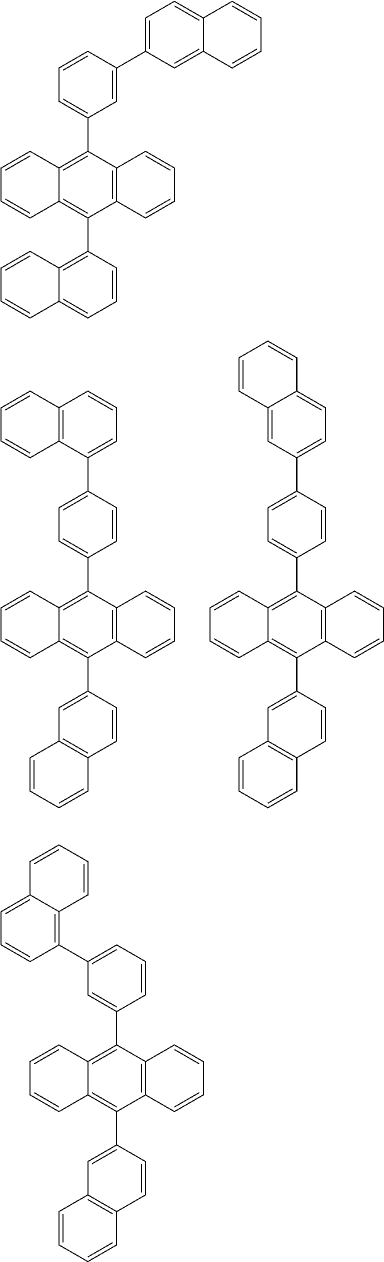

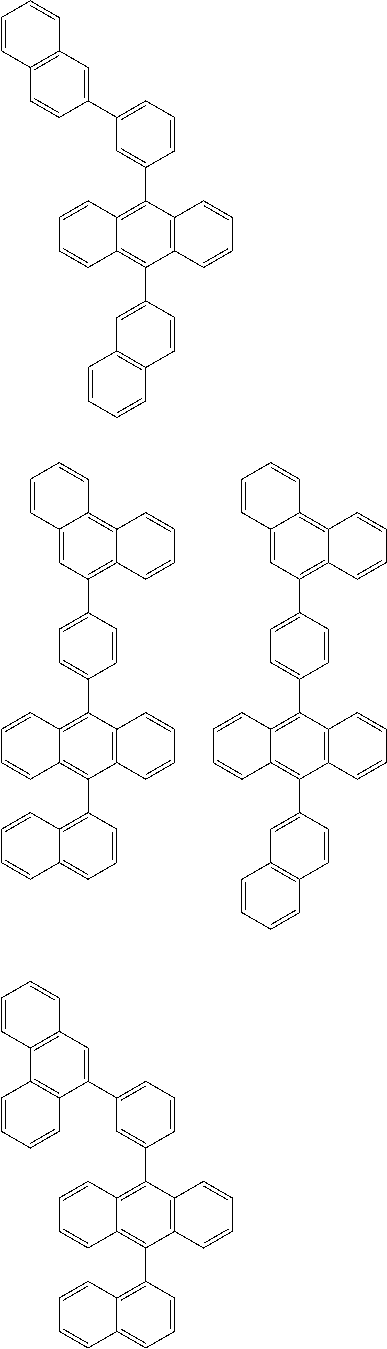

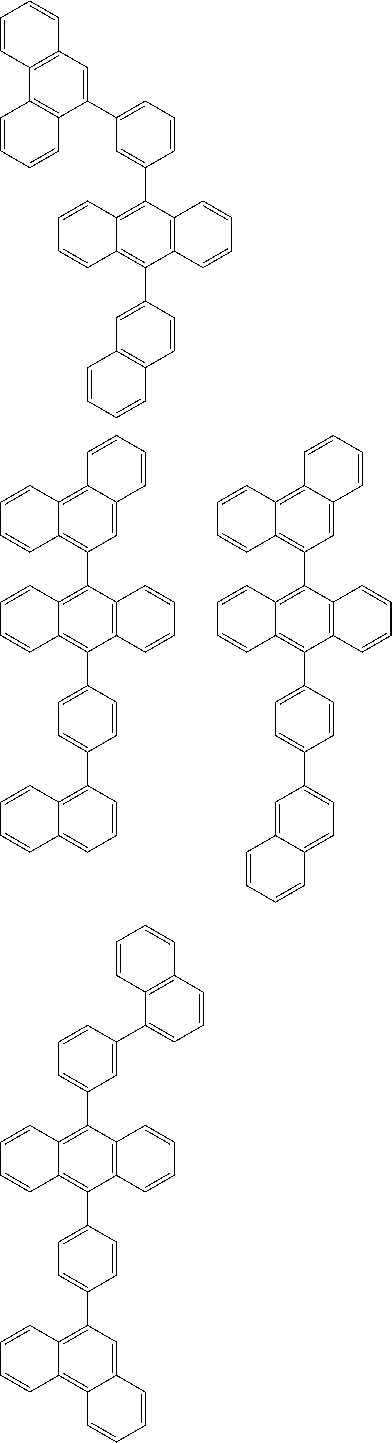

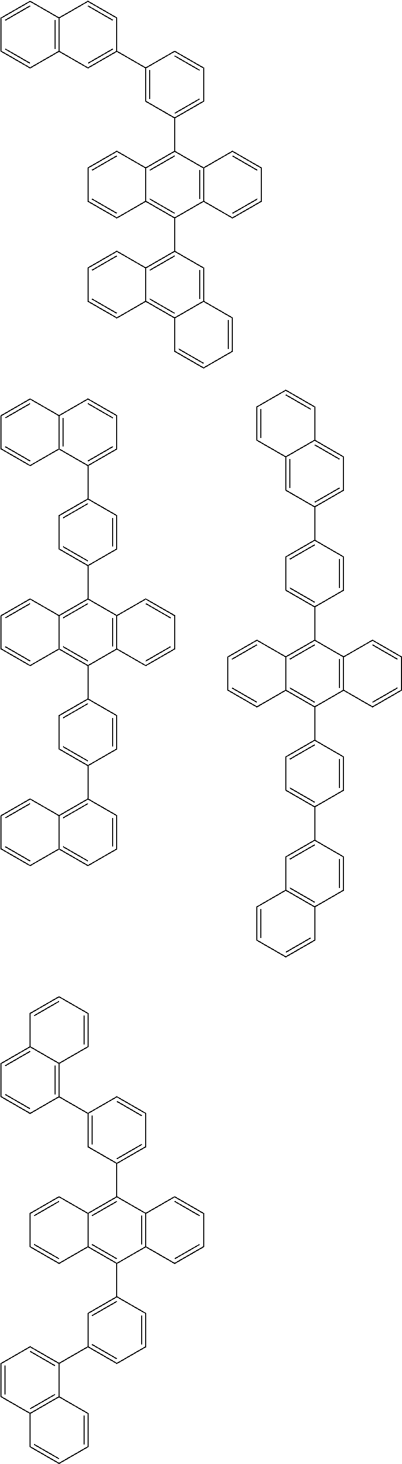

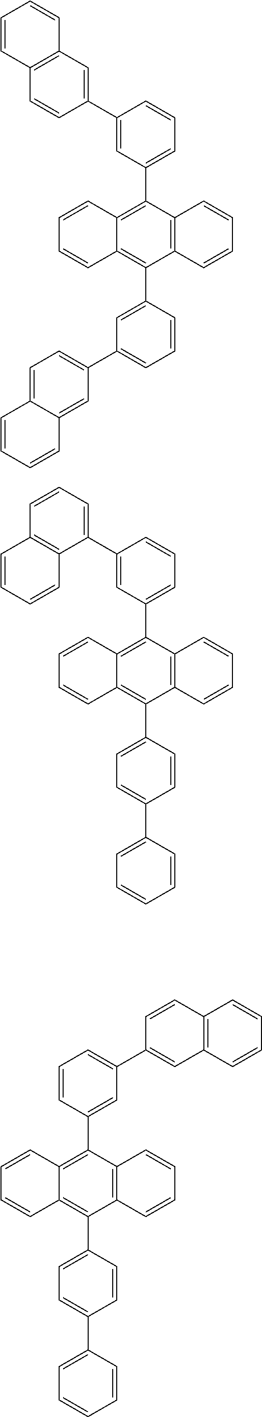

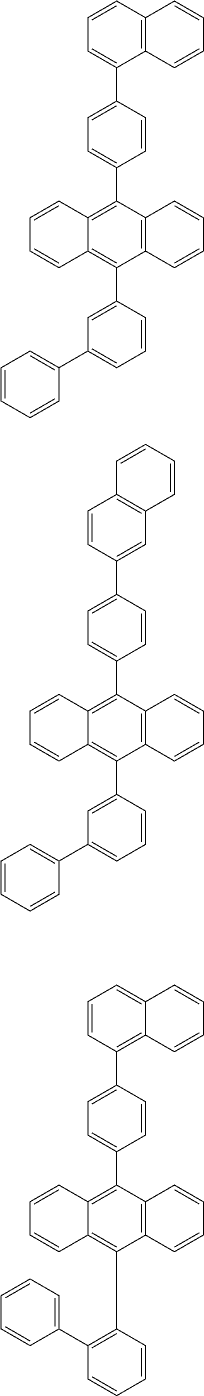

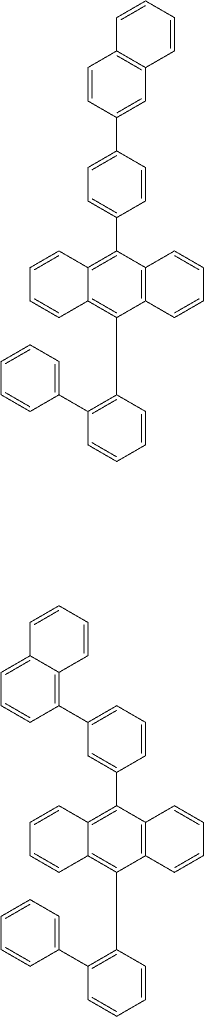

### Compositions Including at Least One Organic Molecule According to Embodiments of the Present Disclosure

One aspect of embodiments of the present disclosure relates to a composition including at least one organic molecule according to embodiments of the present disclosure. One aspect of embodiments of the present disclosure relates to the use of this composition in optoelectronic devices, for example, OLEDs, for example, in an EML of said devices.

In the following, when describing the aforementioned composition, reference is in some cases made to the content of certain materials in the respective compositions in form of percentages. It is to be noted that, unless stated otherwise for embodiments, all percentages refer to weight percentages, which has the same meaning as percent by weight or % by weight ((weight/weight), (w/w), wt. %). It is understood that, when for example stating that the content of one or more organic molecules according to embodiments of the present disclosure in a set or specific composition is, as an example, 30%, this is to mean that the total weight of the one or more organic molecules according to embodiments of the present disclosure (e.g., of all of these molecules combined) is 30% by weight, e.g., accounts for 30% of the total weight of the respective composition. It is understood that, whenever a composition is described by providing the content of its components in % by weight, the total content of all components adds up to 100% by weight (e.g., the total weight of the composition).

When in the following describing the embodiments of the present disclosure relating to a composition including at least one organic molecule according to embodiments of the present disclosure, reference will be made to energy transfer processes that may take place between components within these compositions when using said compositions in an optoelectronic device, for example, in an EML of an optoelectronic device, for example, in an EML of an OLED. The person skilled in the art understands that such excitation energy transfer processes may enhance the emission efficiency when using the composition in an EML of an optoelectronic device.

When describing compositions including at least one organic molecule according to embodiments of the present disclosures, it will also be pointed out that certain materials “differ” from other materials. This is to mean the materials that “differ” from each other do not have the same chemical structure.

In one embodiment, the composition includes or consists of:
(a) one or more organic molecules according to embodiments of the present disclosure, and
(b) one or more host materials H^{B}, which differ from the organic molecules of (a), and
I optionally, one or more solvents.
In one embodiment, the composition includes or consists of:
(a) one or more organic molecules according to embodiments of the present disclosure, and
(b) one or more host materials H^{B}, which differ from the organic molecules of (a),
wherein the fraction of the host materials H^{B} in % by weight in the composition is higher than the fraction of the organic molecules according to embodiments of the present disclosure in % by weight, for example, the fraction of the host materials H^{B} in % by weight in the composition is more than two times higher than the fraction of the organic molecules according to embodiments of the present disclosure in % by weight.

In one embodiment, the composition includes or consists of:
(a) 0.1-30% by weight, for example, 0.8-15% by weight, for example, 1.5-5% by weight, of organic molecules according to embodiments of the present disclosure, and

TTA materials as host materials H^{B} according to following Formula (4):

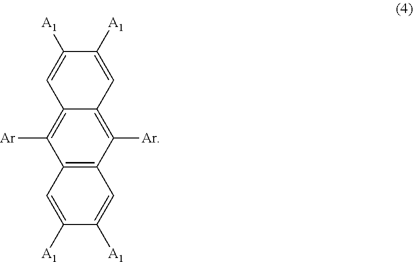

In one embodiment, the composition includes or consists of:
(a) organic molecules according to embodiments of the present disclosure, and
(b) host material H^{B}, which differ from the organic molecules of (a),
I TADF material E^{B} and/or phosphorescence material P^{B}.

In one embodiment, the composition includes or consists of:
(a) 0.1-20% by weight, for example, 0.5-12% by weight, for example, 1-5% by weight of organic molecules according to embodiments of the present disclosure, and
(b) 0-98.8% by weight, for example, 35-94% by weight, for example,—0—88% by weight of one or more host materials H^{B}, which differ from the organic molecules according to embodiments of the present disclosure, and(c) 0.1-20% by weight, for example, 0.5-10% by weight, for example, 1-3% by weight, of one or more phosphorescence materials P^{B}, which differ from the organic molecules of (a), and
(d) 1-99.8% by weight, for example, 5-50% by weight, for example, 10-30% by weight, of one or more TADF materials E^{B}, which differ from the organic molecules of (a), I
(e) 0-98.8% by weight, for example, 0-59% by weight, for example, 0-28% by weight of one or more solvents.

In a further aspect, embodiments of the present disclosure relates to an optoelectronic device including an organic molecule or a composition of the type described here, for example, in the form of a device selected from the group consisting of organic light-emitting diode (OLED), light-emitting electrochemical cell, OLED sensor, for example, gas and vapour sensors not hermetically externally shielded, organic diode, organic solar cell, organic transistor, organic field-effect transistor, organic laser and down-conversion element.

In some embodiments, the optoelectronic device is a device selected from the group consisting of an organic light emitting diode (OLED), a light emitting electrochemical cell (LEC), and a light-emitting transistor.

In one embodiment of the optoelectronic device of the present disclosure, the organic molecule according to embodiments of the present disclosure E is used as emission material in a light-emitting layer EML.

In one embodiment of the optoelectronic device of the present disclosure, the light-emitting layer EML consists of the composition according to embodiments of the present disclosure described here.

When the optoelectronic device is an OLED, it may, for example, have the following layer structure:
1. substrate
2. anode layer A
3. hole injection layer, HIL
4. hole transport layer, HTL
5. electron blocking layer, EBL
6. emitting layer, EML
7. hole blocking layer, HBL
8. electron transport layer, ETL
9. electron injection layer, EIL
10. cathode layer,

wherein the OLED includes each layer selected from the group of HIL, HTL, EBL, HBL, ETL, and EIL only optionally, different layers may be merged and the OLED may include more than one layer of each layer type defined above.

Furthermore, the optoelectronic device may, in one embodiment, include one or more protective layers protecting the device from damaging exposure to harmful species in the environment including, for example, moisture, vapor and/or gases.

In one embodiment of the present disclosure, the optoelectronic device is an OLED, with the following inverted layer structure:
1. substrate
2. cathode Layer
3. electron injection layer, EIL
4. electron transport layer, ETL
5. hole blocking layer, HBL
6. emitting layer, B
7. electron blocking layer, EBL
8. hole transport layer, HTL
9. hole injection layer, HIL
10. anode layer A
wherein the OLED includes each layer selected from the group of HIL, HTL, EBL, HBL, ETL, and EIL only optionally, different layers may be merged and the OLED may include more than one layer of each layer types defined above.

In one embodiment of the present disclosure, the optoelectronic device is an OLED, which may have a stacked architecture. In this architecture, contrary to other arrangements in which the OLEDs are placed side by side, the individual units are stacked on top of each other. Blended light may be generated with OLEDs exhibiting a stacked architecture, for example, white light may be generated by stacking blue, green and red OLEDs. Furthermore, the OLED exhibiting a stacked architecture may include a charge generation layer (CGL), which may be located between two OLED subunits and may consist of a n-doped and p-doped layer with the n-doped layer of one CGL located closer to the anode layer.

In one embodiment of the present disclosure, the optoelectronic device is an OLED, which includes two or more emission layers between anode and cathode. In some embodiments, this so-called tandem OLED includes three emission layers, wherein one emission layer emits red light, one emission layer emits green light and one emission layer emits blue light, and optionally may include further layers such as charge generation layers, blocking or transporting layers between the individual emission layers. In a further embodiment, the emission layers are adjacently stacked. In a further embodiment, the tandem OLED includes a charge generation layer between each two emission layers. In addition, adjacent emission layers or emission layers separated by a charge generation layer may be merged.

The substrate may be formed by any material or composition of materials. Most frequently, glass slides are used as substrates. Alternatively, thin metal layers (e.g., copper, gold, silver or aluminum films) or plastic films or slides may be used. This may allow for a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is transparent. In some embodiments, the anode layer A includes a large content or even consists of transparent conductive oxides (TCOs). Such anode layer A may, for example, include indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrol and/or doped polythiophene.

The anode layer A (essentially) may consist of indium tin oxide (ITO) (e.g., (InO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (e.g., holes) in that the transport of the quasi charge carriers from the TCO to the hole transport layer (HTL) is facilitated. The hole injection layer (HIL) may include poly-3,4-ethylendioxy thiophene (PEDOT), polystyrene sulfonate (PSS), MoO₂, V₂O₅, CuPC or Cul, for example, a mixture of PEDOT and PSS. The hole injection layer (HIL) may also prevent or reduce the diffusion of metals from the anode layer A into the hole transport layer (HTL). The HIL may, for example, include PEDOT:PSS (poly-3,4-ethylendioxy thiophene: polystyrene sulfonate), PEDOT (poly-3,4-ethylendioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine), NPB (N, N′-nis-(1-naphthalenyl)-N, N′-bis-phenyl-(1,1′-biphenyl)-4,4′-diamine), NPNPB (N, N′-diphenyl-N,N′-di-[4-(N, N-diphenyl-amino)phenyl]benzidine), MeO-TPD (N, N, N′, N′-tetrakis(4-methoxyphenyl)benzidine), HAT-CN (1,4,5,8,9,11-hexaazatriphenylen-hexacarbonitrile) and/or Spiro-NPD (N,N′-diphenyl-N, N′-bis-(1-naphthyl)-9,9′-spirobifluorene-2,7-diamine).

Adjacent to the anode layer A or the hole injection layer (HIL), a hole transport layer (HTL) may be located. Herein, any hole transport compound may be used. For example, electron-rich heteroaromatic compounds such as triarylamines and/or carbazoles may be used as hole transport compound. The HTL may decrease the energy barrier between the anode layer A and the light-emitting layer EML. The hole transport layer (HTL) may also be an electron blocking layer (EBL). In some embodiments, hole transport compounds bear comparably high energy levels of their triplet states T1. For example, the hole transport layer (HTL) may include a star-shaped heterocycle such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N,N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H, 9′H-3,3′-bicarbazole). In addition, the HTL may include a p-doped layer, which may be composed of an inorganic or organic dopant in an organic hole-transporting matrix. Transition metal oxides such as vanadium oxide, molybdenum oxide or tungsten oxide may, for example, be used as inorganic dopant. Tetrafluorotetracyanoquinodimethane (F4-TCNQ), copper-pentafluorobenzoate (Cu(I)pFBz) or transition metal complexes may, for example, be used as organic dopant.

The EBL may, for example, include mCP (1,3-bis(carbazol-9-yl)benzene), TCTA, 2-TNATA, mCBP (3,3-di(9H-carbazol-9-yl)biphenyl), tris-Pcz, CzSi (9-(4-tert-butylphenyl)-3,6-bis(triphenylsilyl)-9H-carbazole), and/or DCB (N, N′-dicarbazolyl-1,4-dimethylbenzene).

Adjacent to the hole transport layer (HTL), the light-emitting layer EML may be located. The light-emitting layer EML includes at least one light emitting molecule. In some embodiments, the EML includes at least one light emitting molecule according to embodiments of the present disclosure E. In one embodiment, the light-emitting layer includes only the organic molecules according to embodiments of the present disclosure. In some embodiments, the EML additionally includes one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 (dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material H may be selected to exhibit first triplet (T1) and first singlet (S1) energy levels, which are energetically higher than the first triplet (T1) and first singlet (S1) energy levels of the organic molecule.

In one embodiment of the present disclosure, the EML includes a so-called mixed-host system with at least one hole-dominant host and one electron-dominant host. In some embodiments, the EML includes exactly one light emitting organic molecule according to embodiments of the present disclosure and a mixed-host system including T2T as electron-dominant host and a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as hole-dominant host. In a further embodiment the EML includes 50-80% by weight, for example, 60-75% by weight of a host selected from CBP, mCP, mCBP, 9-[3-(dibenzofuran-2-yl)phenyl]-9H-carbazole, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, for example, 15-30% by weight of T2T and 5-40% by weight, for example, 10-30% by weight of light emitting molecule according to embodiments of the present disclosure.

Adjacent to the light-emitting layer EML, an electron transport layer (ETL) may be located. Herein, any electron transporter may be used. As an electron transporter, electron-poor compounds such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may include Nbphen (2,9-bis(naphthalen-2-yl)-4,7-diphenyl-1,10-phenanthroline), Alq3 (Aluminum-tris(8-hydroxyquinoline)), TSPO1 (diphenyl-4-triphenylsilylphenyl-phosphinoxide), BpyTP2 (2,7-di(2,2′-bipyridin-5-yl)triphenyl), Sif87 (dibenzo[b,d]thiophen-2-yltriphenylsilane), Sif88 (dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block holes or a holeblocking layer (HBL) is introduced.

The HBL may, for example, include BCP (2,9-dimethyl-4,7-diphenyl-1,10-phenanthroline=Bathocuproine), BAlq (bis(8-hydroxy-2-methylquinoline)-(4-phenylphenoxy)aluminum), Nbphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/ 1,3,5-tris(carbazol)-9-yl) benzene).

Adjacent to the electron transport layer (ETL), a cathode layer C may be located. The cathode layer C may, for example, include or may consist of a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also consist of (essentially) intransparent metals such as Mg, Ca or Al. Alternatively or additionally, the cathode layer C may also include graphite and/or carbon nanotubes (CNTs). Alternatively, the cathode layer C may also consist of nanoscalic silver wires.

An OLED may further, optionally, include a protection layer between the electron transport layer (ETL) and the cathode layer C (which may be designated as electron injection layer (EIL)). This layer may include lithium fluoride, cesium fluoride, silver, Liq (8-hydroxyquinolinolatolithium), Li₂O, BaF₂, MgO and/or NaF.

Optionally, the electron transport layer (ETL) and/or a hole blocking layer (HBL) may also include one or more host compounds H.

In order to modify the emission spectrum and/or the absorption spectrum of the light-emitting layer EML further, the light-emitting layer EML may further include one or more further emitter molecules F. Such an emitter molecule F may be any suitable emitter molecule generally used in the art. In some embodiments such an emitter molecule F is a molecule with a structure differing from the structure of the molecules according to embodiments of the present disclosure E. The emitter molecule F may optionally be a TADF emitter. Alternatively, the emitter molecule F may optionally be a fluorescent and/or phosphorescent emitter molecule which is able to shift the emission spectrum and/or the absorption spectrum of the light-emitting layer EML. As an example, the triplet and/or singlet excitons may be transferred from the organic emitter molecule according to embodiments of the present disclosure to the emitter molecule F before relaxing to the ground state S0 by emitting light that may be red-shifted in comparison to the light emitted by an organic molecule. Optionally, the emitter molecule F may also provoke two-photon effects (e.g., the absorption of two photons of half the energy of the absorption maximum).

Optionally, an optoelectronic device (e.g., an OLED) may, for example, be an essentially white optoelectronic device. For example, such a white optoelectronic device may include at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows: violet: wavelength range of >380-420 nm;
deep blue: wavelength range of >420-480 nm;
sky blue: wavelength range of >480-500 nm;
green: wavelength range of >500-560 nm;
yellow: wavelength range of >560-580 nm;
orange: wavelength range of >580-620 nm;
red: wavelength range of >620-800 nm.

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, a red emitter has an emission maximum in a range of from >620 to 800 nm.

A deep blue emitter may, for example, have an emission maximum of below 480 nm, for example, below 470 nm, for example, below 465 nm or even below 460 nm. It may be above 420 nm, for example, above 430 nm, for example, above 440 nm or even above 450 nm.

A green emitter has an emission maximum of below 560 nm, for example, below 550 nm, for example, below 545 nm or even below 540 nm. It may be above 500 nm, for example, above 510 nm, for example, above 515 nm or even above 520 nm.

Accordingly, a further aspect of embodiments of the present disclosure relates to an OLED, which exhibits an external quantum efficiency at 1000 cd/m² of more than 8%, for example, of more than 10%, for example, of more than 13%, for example, of more than 15% or even more than 20% and/or exhibits an emission maximum between 420 nm and 500 nm, for example, between 430 nm and 490 nm, for example, between 440 nm and 480 nm, for example, between 450 nm and 470 nm and/or exhibits a LT80 value at 500 cd/m² of more than 100 h, for example, more than 200 h, for example, more than 400 h, for example, more than 750 h or even more than 1000 h. Accordingly, a further aspect of embodiments of the present disclosure relates to an OLED, whose emission exhibits a CIEy color coordinate of less than 0.45, for example, less than 0.30, for example, less than 0.20 or, for example, less than 0.15 or even less than 0.10.

A further aspect of embodiments of the present disclosure relates to an OLED, which emits light at a distinct color point. According to embodiments of the present disclosure, the OLED emits light with a narrow emission band (small full width at half maximum (FWHM)). In one aspect, the OLED according to embodiments of the present disclosure emits light with a FWHM of the main emission peak of less than 0.25 eV, for example, less than 0.20 eV, for example, less than 0.17 eV, for example, less than 0.15 eV or even less than 0.13 eV.

A further aspect of embodiments of the present disclosure relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g., UHD-TVs. Accordingly, a further aspect of embodiments of the present disclosure relates to an OLED, whose emission exhibits a CIEx color coordinate of between 0.02 and 0.30, for example, between 0.03 and 0.25, for example, between 0.05 and 0.20 or, for example, between 0.08 and 0.18 or even between 0.10 and 0.15 and/or a CIEy color coordinate of between 0.00 and 0.45, for example, between 0.01 and 0.30, for example, between 0.02 and 0.20 or, for example, between 0.03 and 0.15 or even between 0.04 and 0.10.

In a further embodiment of the present disclosure, the composition has a photoluminescence quantum yield (PLQY) of more than 20%, for example, more than 30%, for example, more than 35%, for example, more than 40%, for example, more than 45%, for example, more than 50%, for example, more than 55%, for example, more than 60% or even more than 70% at room temperature.

In a further aspect, embodiments of the present disclosure relate to a method for producing an optoelectronic component. In this case an organic molecule of embodiments of the present disclosure is used.

In a further aspect, embodiments of the present disclosure relate to a method for generating light at a wavelength range from 440 nm to 560 nm, for example, from 440 nm to 470 nm or from 510 nm to 550 nm including the steps of:
(i) providing an organic electroluminescent device including an organic molecule of embodiments of the present disclosure and
(ii) applying an electrical current to said organic electroluminescent device.

The optoelectronic device, for example, the OLED according to embodiments of the present disclosure can be fabricated by any means of vapor deposition and/or liquid processing. Accordingly, at least one layer is
prepared by means of a sublimation process,
prepared by means of an organic vapor phase deposition process,
prepared by means of a carrier gas sublimation process,
solution processed or printed.

The methods used to fabricate the optoelectronic device, for example, the OLED according to embodiments of the present disclosure may be any suitable ones generally used in the art. The different layers are individually and successively deposited on a suitable substrate by means of subsequent deposition processes. The individual layers may be deposited using the same or differing deposition methods.

Vapor deposition processes, for example, include thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process, for example, include spin coating, dip coating and jet printing. Liquid processing may optionally be carried out in an inert atmosphere (e.g., in a nitrogen atmosphere) and the solvent may be completely or partially removed by any suitable method generally used in the art.

In another aspect, embodiments of the present disclosure also refer to an organic light-emitting molecule including or consisting of a structure of Formula 100

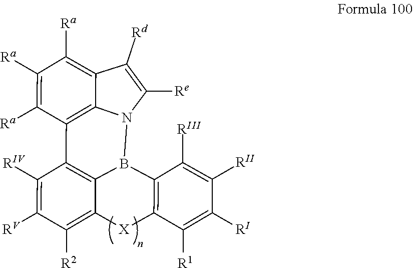

wherein n=0 or 1;
X is at each occurrence independently selected from the group consisting of a direct bond, CR³R⁴, C═CR³R⁴, C═O, C═NR³, NR³, O, SiR³R⁴, S, S(O) and S(O)₂;
R¹, R², R³, R⁴, R^{I}, R^{II}, R^{III}, R^{IV} and R^{V} is selected from the group consisting of:
hydrogen, deuterium, N(R⁵)₂, OR⁵, Si(R⁵)₃, B(OR⁵)₂, B(R⁵)₂, OSO₂R⁵, CF₃, CN, F, Br, I,
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵;
R^{d} and R^{e} is independently selected from the group consisting of: hydrogen, deuterium, CF₃, CN, F, Br, I,
C₁-C₄₀-alkyl,
which is optionally substituted with one or more substituents R^{a} and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R^{a}; and
C₂-C₅₇-heteroaryl,
which is optionally substituted with one or more substituents R^{a};
R^{a} are at each occurrence independently selected from the group consisting of: hydrogen, deuterium, N(R⁵)₂, OR⁵, Si(R⁵)₃, B(OR⁵)₂, B(R⁵)₂, OSO₂R⁵, CF₃, CN, F, Br, I,
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵;
R⁵ is at each occurrence independently from another selected from the group consisting of: hydrogen, deuterium, N(R⁶)₂, OR⁶, Si(R⁶)₃, B(OR⁶)₂, B(R⁶)₂, OSO₂R⁶, CF₃, CN, F, Br, I,
C₁-C₄₀-alkyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-alkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶; C₂-C₄₀-alkenyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkynyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₆-C₆₀-aryl,
which is optionally substituted with one or more substituents R⁶; and
C₂-C₅₇-heteroaryl,
which is optionally substituted with one or more substituents R⁶;
R⁶ is at each occurrence independently from another selected from the group consisting of: hydrogen, deuterium, OPh, CF₃, CN, F,
C₁-C₅-alkyl,
wherein one or more hydrogen atoms are optionally, independently from each other substituted by deuterium, CN, CF₃, or F;
C₁-C₅-alkoxy,
wherein one or more hydrogen atoms are optionally, independently from each other substituted by deuterium, CN, CF₃, or F;
C₁-C₅-thioalkoxy,
wherein one or more hydrogen atoms are optionally, independently from each other substituted by deuterium, CN, CF₃, or F;
C₂-C₅-alkenyl,
wherein one or more hydrogen atoms are optionally, independently from each other substituted by deuterium, CN, CF₃, or F;
C₂-C₅-alkynyl,
wherein one or more hydrogen atoms are optionally, independently from each other substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₈-C₁₈-aryl)₂;
N(C₂-C₁₇-heteroaryl)₂, and
N(C₂-C₁₇-heteroaryl)(C₆-C₁₈-aryl);
wherein the substituents R^{a}, R^{d}, R^{e}, R⁵, independently from each other, optionally form a mono- or polycyclic, aliphatic, aromatic, heteroaromatic and/or benzo-fused ring system with one or more substituents R^{a}, R^{d}, R^{e}, R⁵; and
wherein the substituents R¹, R², R³, R⁴, R⁵, R^{I}, R^{II}, R^{III}, R^{IV}, R^{V} independently from each other, optionally form a mono- or polycyclic, aliphatic, aromatic, heteroaromatic and/or benzo-fused ring system with one or more substituents R¹, R², R³, R⁴, R⁵, R^{I}, R^{II}, R^{III}, R^{IV}, R^{V}.

### EXAMPLES

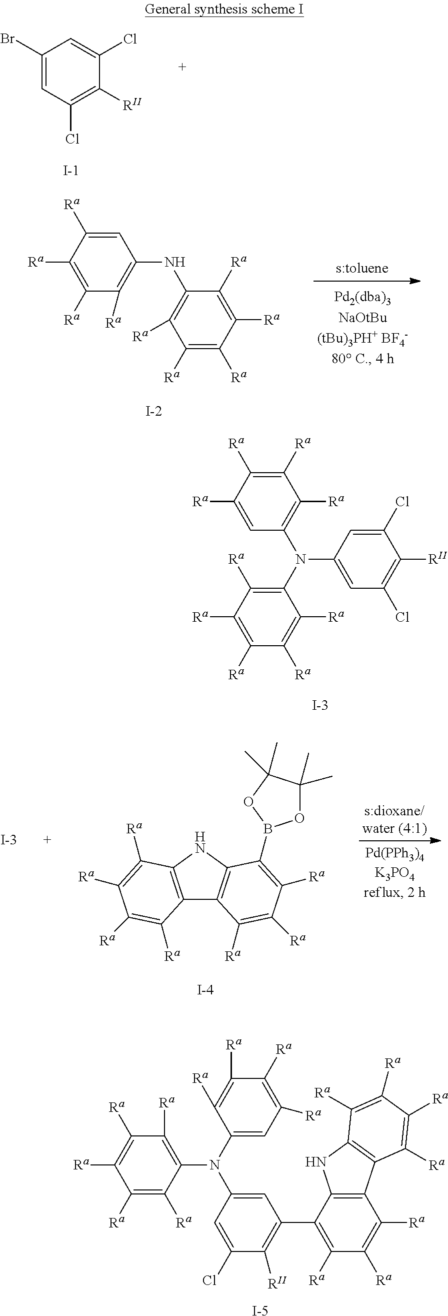

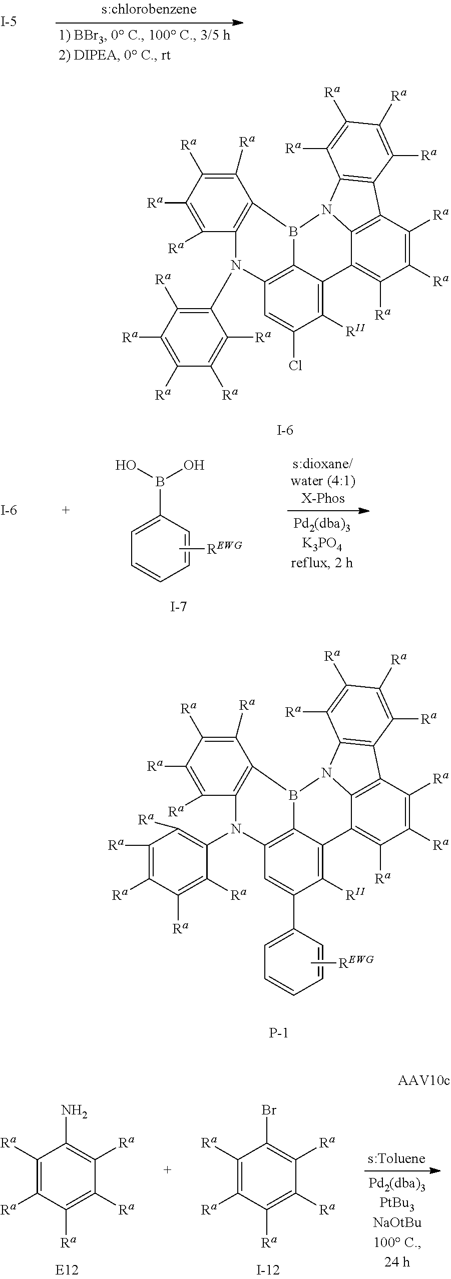

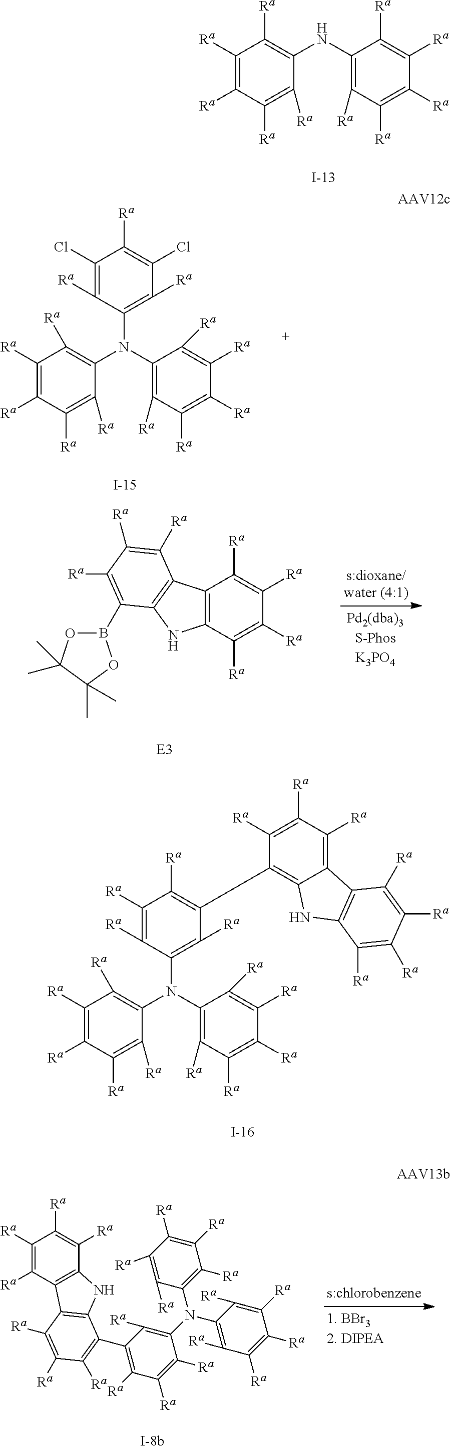

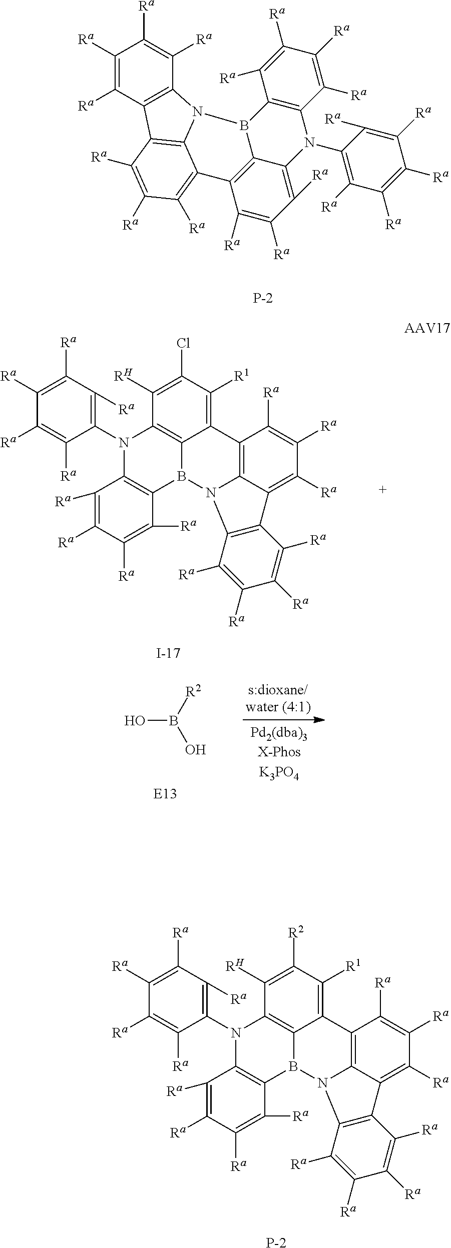

### General Procedure for Synthesis:

AAV1: A suspension of I-1 (1.0 equivalents), I-2 (1.0 equivalents), Tris(dibenzylideneacetone)dipalladium(0) (0.01 equivalents; Pd₂(dba)₃; CAS-No. 51364-51-3), Tri-tert-butylphosphonium tetrafluoroborate (0.04 equivalents; (tBu)₃PH⁺BF₄⁻; CAS-No. 131274-22-1) and Sodium tert-butoxide (NaO^{t}Bu; CAS-No. 865-48-5, 3.0 equivalents) was stirred at 80° C. for 4 h. After cooling down the mixture was extracted between water and ethyl acetate and the combined organic phases were dried over MgSO₄ and filtered and concentrated.

AAV2: A suspension of I-3 (1.0 equivalent), I-4 (1.0 equivalent), Tris(dibenzylideneacetone)dipalladium(0) (0.01 equivalents; Pd₂(dba)₃; CAS-No. 51364-51-3), X-Phos (0.04 equivalents; CAS-No. 564483-18-7) and K₃PO₄ (CAS-No. 7778-53-2, 1.5 equivalents) in a degassed mixture of dioxane and water (4:1 by vol.) was stirred under reflux for 2 h. After cooling down to rt an aqueous workup was performed, followed by purification of the crude product through recrystallization or column chromatography. The desired compound I-5 was obtained as a solid.

AAV3: At 0° C. a solution of I-5 (1.0 equivalent) in dry chlorobenzene (35 mL per 1 mmol I-5) was added boron tribromide (99%, CAS-No. 10294-33-4, 4.0 equivalents). The mixture was allowed to warm to rt, followed by heating at 70° C. for 3.5 h. The mixture was allowed to cool down to rt. Subsequently, the mixture was extracted between water and ethyl acetate and the combined organic layers were dried over MgSO₄, filtered and concentrated. After purification through recrystallization or column chromatography, the compound I-6 was obtained as a solid.

AAV4: 1-6 (1.0 equivalent), I-7 (1.5 equivalent), tetrakis(triphenylphosphine)palladium(0) (CAS-No. 14221-01-3, 0.04 equivalents) and K₃PO₄ (CAS-No. 7778-53-2, 2.5 equivalents) are combined in a degassed mixture of dioxane and water (5:1 by vol.) is stirred under reflux for 16 h. After cooling down to rt an aqueous workup was performed, followed by purification of the crude product through recrystallization or column chromatography. The desired target compound P-1 was obtained as a solid.

AAV10c: A suspension of E12 (1.0 equivalents), I-12 (1.1 equivalent), tris(dibenzylideneacetone)-dipalladium(0) (CAS-no. 51364-51-3, 0.06 equivalents), tri-tert-butylphosphine (CAS-no. 13716-12-6, 0.12 equivalents) and sodium tert-butoxide (CAS-no. 865-48-5, 5.0 equivalents) in degassed toluene and was stirred at 100° C. for 24 h. After cooling down to room temperature (rt) an aqueous workup was performed, followed by purification of the crude product through recrystallization or column chromatography. The desired compound I-13 was obtained as a solid.

AAV10d: A suspension of E13 (1.0 equivalents), I-14 (1.0 equivalent), tris(dibenzylideneacetone)-dipalladium(0) (CAS-no. 51364-51-3, 0.01 equivalents), tri-tert-butylphosphine (CAS-no. 13716-12-6, 0.04 equivalents) and sodium tert-butoxide (CAS-no. 865-48-5, 3.0 equivalents) in degassed toluene and was stirred at 80° C. for 18 h. After cooling down to room temperature (rt) an aqueous workup was performed, followed by purification of the crude product through recrystallization or column chromatography. The desired compound I-15 was obtained as a solid.

AAV12c: 1-15 (1.2 equivalent), E3 (1.0 equivalents), tris(dibenzylideneacetone)dipalladium(0) (CAS-No. 51364-51-3, 0.01 equivalents), S-PHOS (CAS-No. 657408-07-6, 0.04 equivalents) and K₃PO₄ (CAS-No. 7778-53-2, 2.0 equivalents) are reacted in a mixture of dioxane and water (4:1 by vol.) under reflux for 4 h. After cooling down to rt, the reaction mixture is extracted between ethyl acetate and water. The combined organic layers are dried over MgSO₄, filtered and concentrated under reduced pressure. After purification through recrystallization or column chromatography, compound I-16 is obtained as a solid.

AAV13b: At 0° C. a solution of 1-8b (1.0 equivalent) in dry chlorobenzene (20 mL per 1 mmol I-8b) is added boron tribromide (99%, CAS-No. 10294-33-4, 4.0 equivalents). The mixture was allowed to warm to rt, followed by heating at 50° C. for 24 h. The mixture was allowed to cool down to rt. Subsequently, the mixture was extracted between water and ethyl acetate and the combined organic layers were dried over MgSO₄, filtered and concentrated. After purification through recrystallization or column chromatography, the target compound P-2 was obtained as a solid.

AAV17: 1-17 (1.0 equivalent), E13 (1.5 equivalents), tris(dibenzylideneacetone)dipalladium(0) (CAS-No. 51364-51-3, 0.02 equivalents), X-PHOS (CAS-No. 564483-18-7, 0.08 equivalents) and K₃PO₄ (CAS-No. 7778-53-2, 1.5 equivalents) are reacted in a mixture of dioxane and water (4:1 by vol.) under reflux for 4 h. After cooling down to rt, the reaction mixture is extracted between ethyl acetate and water. The combined organic layers are dried over MgSO₄, filtered and concentrated under reduced pressure. After purification through recrystallization or column chromatography, compound P-2 is obtained as a solid.

### Cyclic Voltammetry

Cyclic voltammograms are measured from solutions having concentration of 10⁻³ mol/L of the organic molecules in dichloromethane or a suitable solvent and a suitable supporting electrolyte (e.g., 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

### Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets (and a m4-grid for numerical integration are used. The Turbomole program package is used for all calculations.

### Photophysical Measurements

Sample pretreatment: Spin-coating

Apparatus: Spin150, SPS euro.

The sample concentration is 10 mg/ml, dissolved in a suitable solvent.

Program: 1) 3 s at 400 U/min; 20 s at 1000 U/min at 1000 Upm/s. 3) 10 s at 4000 U/min at 1000 Upm/s. After coating, the films are tried at 70° C. for 1 min.

### Photoluminescence Spectroscopy and Time-Correlated Single-Photon Counting (TCSPC)

Steady-state emission spectroscopy is measured by a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra are corrected using standard correction fits.

Excited state lifetimes are determined employing the same system using the TCSPC method with FM-2013 equipment and a Horiba Yvon TCSPC hub.
Excitation sources:
NanoLED 370 (wavelength: 371 nm, puls duration: 1.1 ns)
NanoLED 290 (wavelength: 294 nm, puls duration: <1 ns)
SpectraLED 310 (wavelength: 314 nm)
SpectraLED 355 (wavelength: 355 nm).

Data analysis (exponential fit) is done using the software suite DataStation and DAS6 analysis software. The fit is specified using the chi-squared-test.

### Photoluminescence Quantum Yield Measurements

For photoluminescence quantum yield (PLQY) measurements an Absolute PL Quantum Yield Measurement C9920-03G system (Hamamatsu Photonics) is used. Quantum yields and CIE coordinates are determined using the software U6039-05 version 3.6.0.

Emission maxima are given in nm, quantum yields ¢ in % and CIE coordinates as x,y values.

PLQY is determined using the following protocol:
1. Quality assurance: Anthracene in ethanol (set concentration) is used as reference
2. Excitation wavelength: the absorption maximum of the organic molecule is determined and the molecule is excited using this wavelength
3. Measurement
Quantum yields are measured, for sample, of solutions or films under nitrogen atmosphere. The yield is calculated using the equation:

$${Φ}_{PL} = \frac{{n}_{photon} , emited}{{n}_{photon} , absorbed} = \frac{\int \frac{λ}{hc} [ {Int}_{emitted}^{sample} ( λ ) - {Int}_{absorbed}^{sample} ( λ ) ] d λ}{\int \frac{λ}{hc} [ {Int}_{emitted}^{reference} ( λ ) - {Int}_{absorbed}^{reference} ( λ ) ] d λ}$$

wherein nₚₕₒₜₒₙ denotes the photon count and Int. the intensity.

### Production and Characterization of Optoelectronic Devices

Optoelectronic devices, such as OLED devices including organic molecules according to embodiments of the present disclosure can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The not fully optimized OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g., applying increased current densities). For example, LT80 values at 500 cd/m² are determined using the following equation:

$$LT 80 ( 500 \frac{{cd}^{2}}{{m}^{2}} ) = LT 80 ( {L}_{0} ) {( \frac{{L}_{0}}{500 \frac{{cd}^{2}}{{m}^{2}}} )}^{1.6}$$

wherein L₀ denotes the initial luminance at the applied current density.

The values correspond to the average of several pixels (for example, two to eight), the standard deviation between these pixels is given.

### HPLC-MS

HPLC-MS analysis is performed on an HPLC by Agilent (1100 series) with MS-detector (Thermo LTQ XL).

As am example, an HPLC method is as follows: a reverse phase column 4.6 mm×150 mm, particle size 3.5 μm from Agilent (ZORBAX Eclipse Plus 95 Å C18, 4.6×150 mm, 3.5 μm HPLC column) is used in the HPLC. The HPLC-MS measurements are performed at room temperature (rt) following gradients:

| Flow rate [ml/min] | Time [min] | A[%] | B[%] | C[%] |
|---|---|---|---|---|
| 2.5 | 0 | 40 | 50 | 10 |
| 2.5 | 5 | 40 | 50 | 10 |
| 2.5 | 25 | 10 | 20 | 70 |
| 2.5 | 35 | 10 | 20 | 70 |
| 2.5 | 35.01 | 40 | 50 | 10 |
| 2.5 | 40.01 | 40 | 50 | 10 |
| 2.5 | 41.01 | 40 | 50 | 10 |

using the following solvent mixtures:

| | | |
|---|---|---|
| Solvent A: | H2O (90%) | MeCN (10%) |
| Solvent B: | H2O (10%) | MeCN (90%) |
| Solvent C: | THF (50%) | MeCN (50%) |

An injection volume of 5 μL from a solution with a concentration of 0.5 mg/ml of the analyte is taken for the measurements.

Ionization of the probe is performed using an APCI (atmospheric pressure chemical ionization) source either in positive (APCI+) or negative (APCI−) ionization mode.

### Example 1

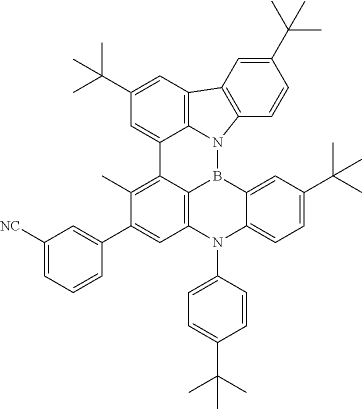 [SMILES: Cc1c(-c2cccc(C#N)c2)cc2c3c1-c1cc(C(C)(C)C)cc4c5cc(C(C)(C)C)ccc5n(c14)B3c1cc(C(C)(C)C)ccc1N2c1ccc(C(C)(C)C)cc1]

Example 1 was synthesized according to
AAV1 (78% yield), where I-1 and I-2 were represented by 5-bromo-1,3-dichloro-2-methylbenzene (CAS-no. 204930-37-0) and bis(4-tert-butylphenyl)amine (CAS-no. 4627-22-9), respectively;
AAV2 (56% yield), where I-4 was represented by 3,6-Bis(1,1-dimethylethyl)-1-(4,4,5,5-tetramethyl-1,3,2-dioxaborolan-2-yl)-9H-carbazole (CAS-no. 1510810-80-6);
AAV3 (76% yield),
and AAV4 (45% yield) where I-7 was represented by 3-cyanophenylboronic acid (CAS-no. 150255-96-2).

MS (LC-MS, APCI ion source): 758 m/z at rt: 7.997 min.

The emission maximum of example 1 (0.001 mg/mL in toluene) is at 450 nm, the CIEx coordinate is 0.14 and the CIEy coordinate is 0.07.

### Example 2

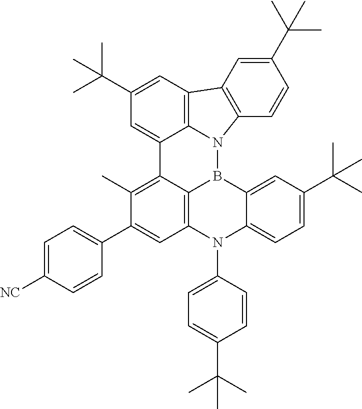 [SMILES: Cc1c(-c2ccc(C#N)cc2)cc2c3c1-c1cc(C(C)(C)C)cc4c5cc(C(C)(C)C)ccc5n(c14)B3c1cc(C(C)(C)C)ccc1N2c1ccc(C(C)(C)C)cc1]

Example 2 was synthesized according to
AAV1 (78% yield), where I-1 and I-2 were represented by 5-bromo-1,3-dichloro-2-methylbenzene (CAS-no. 204930-37-0) and bis(4-tert-butylphenyl)amine (CAS-no. 4627-22-9), respectively;
AAV2 (56% yield), where I-4 was represented by 3,6-Bis(1,1-dimethylethyl)-1-(4,4,5,5-tetramethyl-1,3,2-dioxaborolan-2-yl)-9H-carbazole (CAS-no. 1510810-80-6);
AAV3 (76% yield),
and AAV4 (48% yield) where I-7 was represented by 4-Cyanophenylboronic acid (CAS-no. 126747-14-6).

MS (LC-MS, APCI ion source): 758 m/z at rt: 7.997 min.

The emission maximum of example 2 (0.001 mg/mL in toluene) is at 457 nm, the CIEx coordinate is 0.14 and the CIEy coordinate is 0.10.

### Example 3

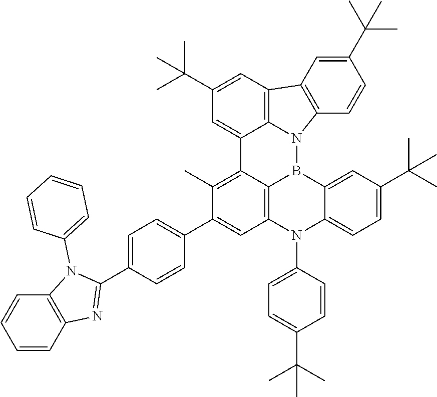 [SMILES: Cc1c(-c2ccc(-c3nc4ccccc4n3-c3ccccc3)cc2)cc2c3c1-c1cc(C(C)(C)C)cc4c5cc(C(C)(C)C)ccc5n(c14)B3c1cc(C(C)(C)C)ccc1N2c1ccc(C(C)(C)C)cc1]

Example 3 was synthesized according to
AAV1 (78% yield), where I-1 and I-2 were represented by 5-bromo-1,3-dichloro-2-methylbenzene (CAS-no. 204930-37-0) and bis(4-tert-butylphenyl)amine (CAS-no. 4627-22-9), respectively;
AAV2 (56% yield), where I-4 was represented by 3,6-bis(1,1-dimethylethyl)-1-(4,4,5,5-tetramethyl-1,3,2-dioxaborolan-2-yl)-9H-carbazole (CAS-no. 1510810-80-6);
AAV3 (76% yield),
and AAV4 (48% yield) where I-7 was represented by (4-(1-phenyl-1H-benzo[d]imidazol-2-yl)phenyl)boronic acid (CAS-no. 952514-79-3).

MS (LC-MS, APPI ion source): 926 m/z at rt: 8.00 min.

The emission maximum of example 3 (0.001 mg/mL in toluene) is at 452 nm, the CIEx coordinate is 0.14 and the CIEy coordinate is 0.08. The photoluminescence quantum yield (PLQY) is 85%.

### Example 4

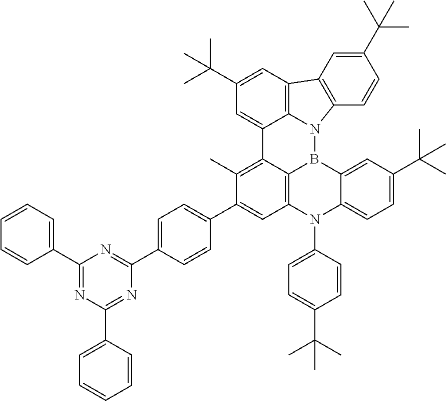 [SMILES: Cc1c(-c2ccc(-c3nc(-c4ccccc4)nc(-c4ccccc4)n3)cc2)cc2c3c1-c1cc(C(C)(C)C)cc4c5cc(C(C)(C)C)ccc5n(c14)B3c1cc(C(C)(C)C)ccc1N2c1ccc(C(C)(C)C)cc1]

Example 4 was synthesized according to
AAV1 (78% yield), where I-1 and I-2 were represented by 5-bromo-1,3-dichloro-2-methylbenzene (CAS-no. 204930-37-0) and bis(4-tert-butylphenyl)amine (CAS-no. 4627-22-9), respectively;
AAV2 (56% yield), where I-4 was represented by 3,6-bis(1,1-dimethylethyl)-1-(4,4,5,5-tetramethyl-1,3,2-dioxaborolan-2-yl)-9H-carbazole (CAS-no. 1510810-80-6);
AAV3 (76% yield),
and AAV4 (34% yield) where I-7 was represented by 2,4-diphenyl-6-[4-(4,4,5,5-tetramethyl-1,3,2-dioxaborolan-2-yl)phenyl]-1,3,5-triazine (CAS-no. 1219956-23-6).

MS (LC-MS, APPI ion source): 965 m/z at rt: 9.6 min.

The emission maximum of example 4 (0.001 mg/mL in toluene) is at 499 nm, the CIEx coordinate is 0.24 and the CIEy coordinate is 0.43.

### Example 5

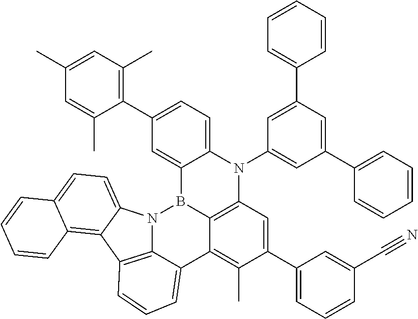 [SMILES: Cc1cc(C)c(-c2ccc3c(c2)B2c4c(cc(-c5cccc(C#N)c5)c(C)c4-c4cccc5c6c7ccccc7ccc6n2c45)N3c2cc(-c3ccccc3)cc(-c3ccccc3)c2)c(C)c1]

Example 5 was synthesized according to
AAV10c (47% yield), where I-12 and E12 were represented by 1-bromo-3,5-diphenylbenzene (CAS: 103068-20-8) and 2′,4′,6′-trimethyl-[1,1′-biphenyl]-4-amine, respectively;
AAV10d (48% yield), where I-14 and E13 were represented by 5-bromo-1,3-dichloro-2-methylbenzene (CAS: 204930-37-0) and N-(2′,4′,6′-trimethyl-[1,1′-biphenyl]-4-yl)-[1, 1′:3′, 1″-terphenyl]-5′-amine, respectively;
AAV12c (32% yield), where I-15 and E3 were represented by N-(3,5-dichloro-4-methylphenyl)-N-(2′,4′,6′-trimethyl-[1,1′-biphenyl]-4-yl)-[1,1′:3′, 1″-terphenyl]-5′-amine and 8-(4,4,5,5-tetramethyl-1,3,2-dioxaborolan-2-yl)-7H-benzo[c]carbazole, respectively;
AAV13b (65% yield), where I-8b was represented by N-(3-(7H-benzo[c]carbazol-8-yl)-5-chloro-4-methylphenyl)-N-(2′,4′, 6′-trimethyl-[1,1′-biphenyl]-4-yl)-[1,1′:3′,1″-terphenyl]-5′-amine;
AAV17 (52% yield), where I-17 and E13 were represented by 5-([1,1′:3′,1″-terphenyl]-5′-yl)-7-chloro-2-mesityl-8-methyl-5H-5,17b-diaza-17c-borabenzo[gh]benzo[6,7]indeno[1,2,3-no]tetraphene and 3-Cyanophenylboronic acid (CAS: 150255-96-2), respectively.

MS (LC-MS, APPI ion source): 855 m/z at rt: 7.41 min.

The emission maximum of example 5 (0.001 mg/mL in toluene) is at 452 nm with a full-width at half maximum (FWHM) of 32 nm, the CIEx coordinate is 0.14 and the CIEy coordinate is 0.08 and the PLQY is 82%.

### Example OLED Device D1

Stack material

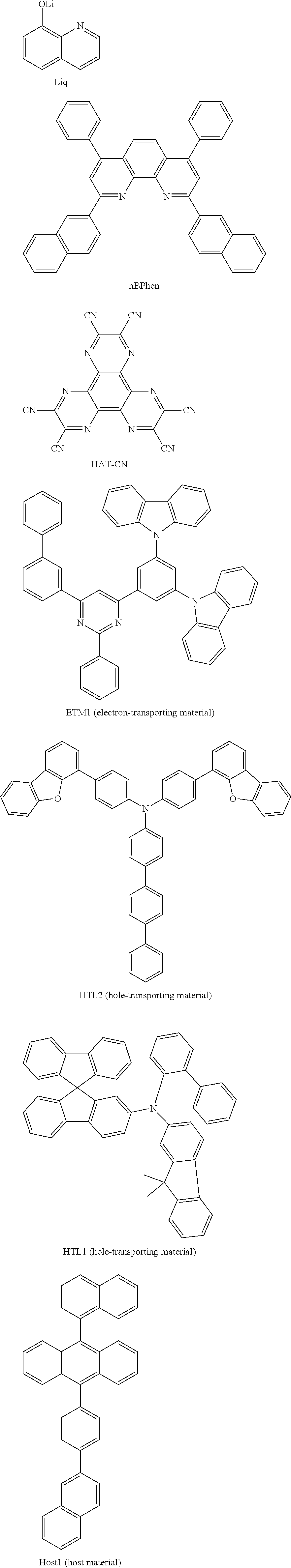

Example 1 was tested in the OLED D1, which was fabricated with the following layer structure:

| Layer # | Thickness | | D1 |
|---|---|---|---|
| 9 | 100 | nm | Al |
| 8 | 2 | nm | Liq |
| 7 | 11 | nm | nBPhen |
| 6 | 20 | nm | ETM1 |
| 5 | 20 | nm | Host1 (98%):Example 1 (2%) |
| 4 | 10 | nm | HTL2 |
| 3 | 50 | nm | HTL1 |
| 2 | 7 | nm | HAT-CN |
| 1 | 50 | nm | ITO |
| Substrate | | | Glass |

OLED D1 yielded an external quantum efficiency (EQE) at 1000 cd/m² of 8.4%. The emission maximum is at 456 nm with a FWHM of 34 nm at 3.9 V. The corresponding CIEx value is 0.138 and the CIEy value is 0.082.

### Additional Examples of Organic Molecules/Oligomers of Embodiments of the Present Disclosure

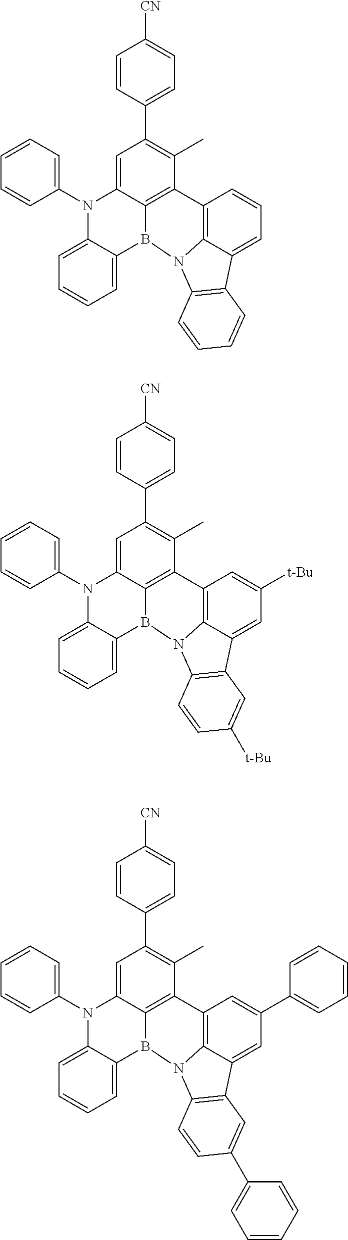 [SMILES: Cc1c(-c2ccc(C#N)cc2)cc2c3c1-c1cccc4c5ccccc5n(c14)B3c1ccccc1N2c1ccccc1 ; Cc1c(-c2ccc(C#N)cc2)cc2c3c1-c1cc(C(C)(C)C)cc4c5cc(C(C)(C)C)ccc5n(c14)B3c1ccccc1N2c1ccccc1 ; Cc1c(-c2ccc(C#N)cc2)cc2c3c1-c1cc(-c4ccccc4)cc4c5cc(-c6ccccc6)ccc5n(c14)B3c1ccccc1N2c1ccccc1]

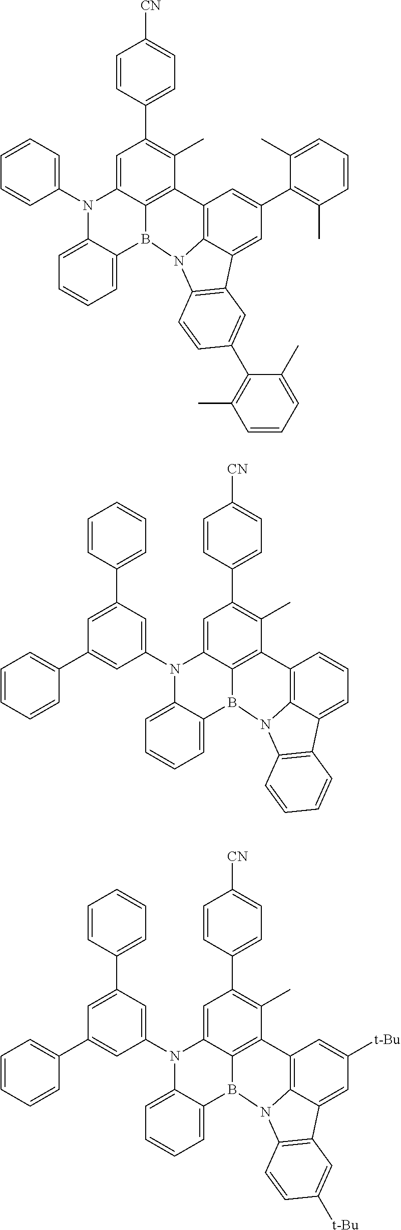

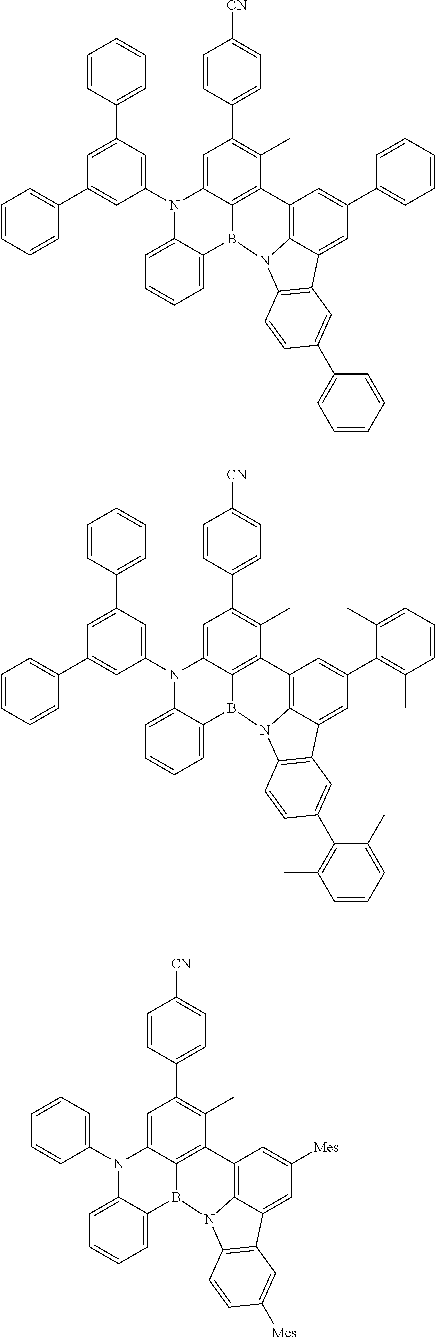

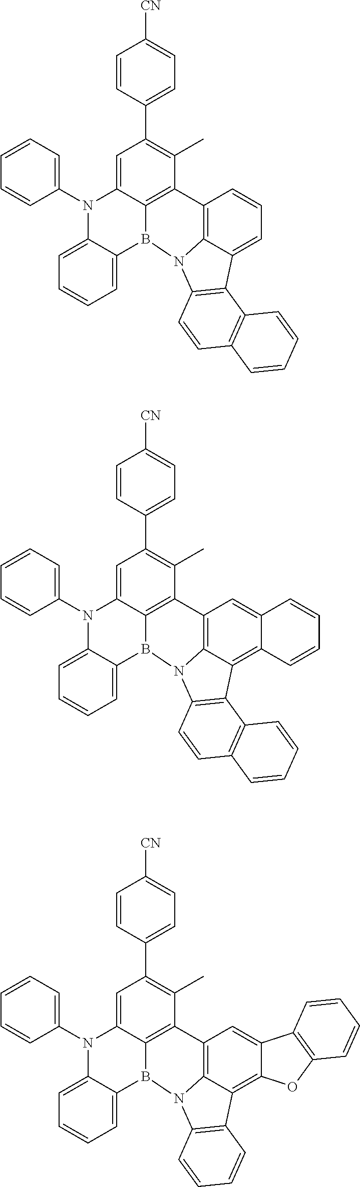 [SMILES: Cc1c(-c2ccc(C#N)cc2)cc2c3c1-c1cccc4c5c6ccccc6ccc5n(c14)B3c1ccccc1N2c1ccccc1 ; Cc1c(-c2ccc(C#N)cc2)cc2c3c1-c1cc4ccccc4c4c5c6ccccc6ccc5n(c14)B3c1ccccc1N2c1ccccc1 ; Cc1c(-c2ccc(C#N)cc2)cc2c3c1-c1cc4c5ccccc5oc4c4c5ccccc5n(c14)B3c1ccccc1N2c1ccccc1]

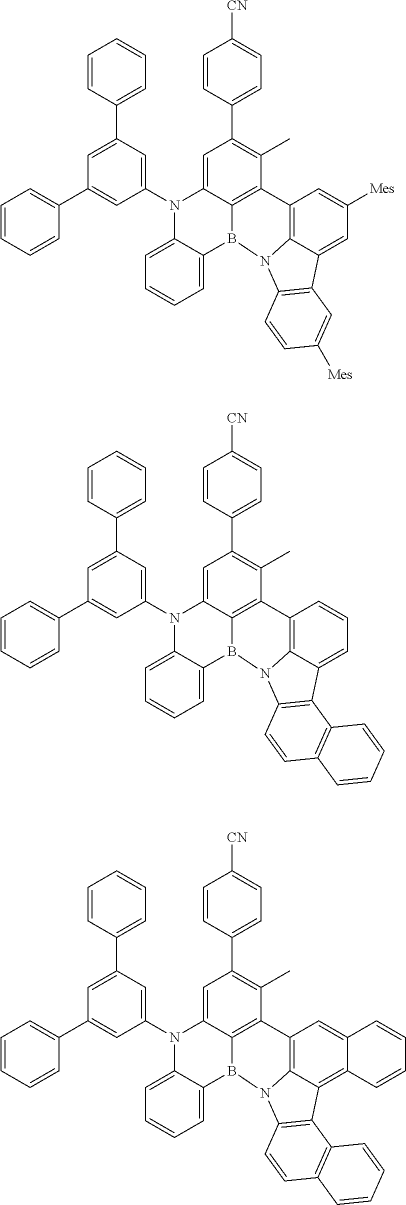

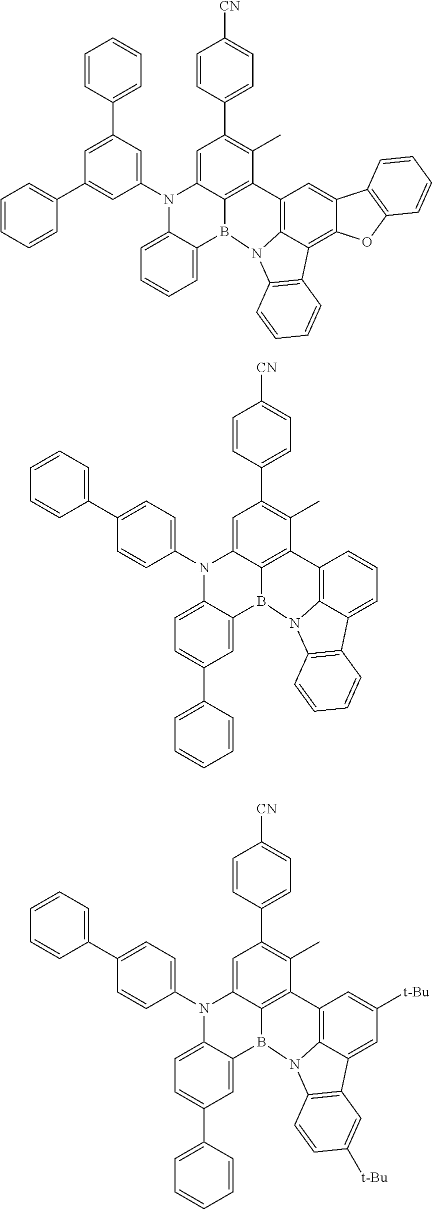

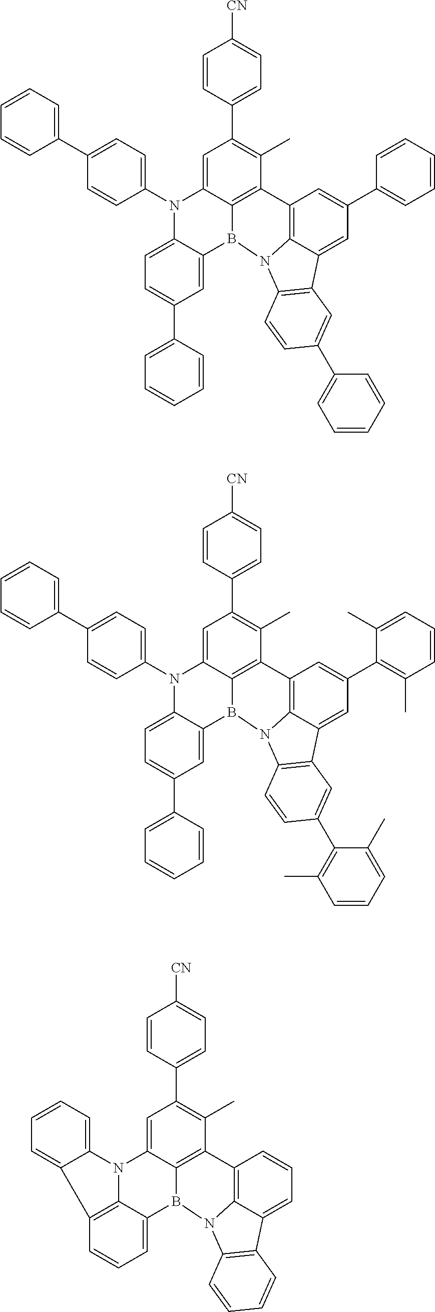 [SMILES: Cc1c(-c2ccc(C#N)cc2)cc2c3c1-c1cc(-c4ccccc4)cc4c5cc(-c6ccccc6)ccc5n(c14)B3c1cc(-c3ccccc3)ccc1N2c1ccc(-c2ccccc2)cc1 ; Cc1cccc(C)c1-c1ccc2c(c1)c1cc(-c3c(C)cccc3C)cc3c1n2B1c2cc(-c4ccccc4)ccc2N(c2ccc(-c4ccccc4)cc2)c2cc(-c4ccc(C#N)cc4)c(C)c-3c21 ; Cc1c(-c2ccc(C#N)cc2)cc2c3c1-c1cccc4c5ccccc5n(c14)B3c1cccc3c4ccccc4n-2c13]

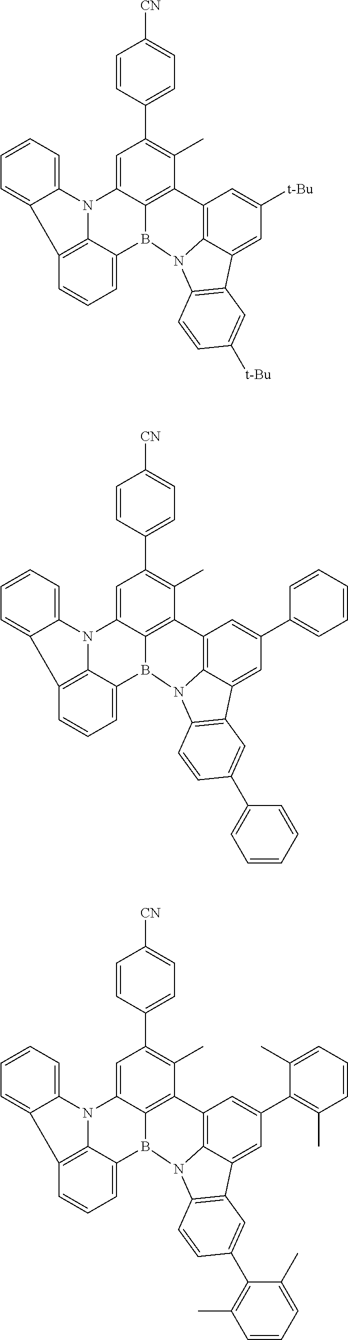 [SMILES: Cc1c(-c2ccc(C#N)cc2)cc2c3c1-c1cc(C(C)(C)C)cc4c5cc(C(C)(C)C)ccc5n(c14)B3c1cccc3c4ccccc4n-2c13 ; Cc1c(-c2ccc(C#N)cc2)cc2c3c1-c1cc(-c4ccccc4)cc4c5cc(-c6ccccc6)ccc5n(c14)B3c1cccc3c4ccccc4n-2c13 ; Cc1cccc(C)c1-c1ccc2c(c1)c1cc(-c3c(C)cccc3C)cc3c1n2B1c2c(cc(-c4ccc(C#N)cc4)c(C)c2-3)-n2c3ccccc3c3cccc1c32]

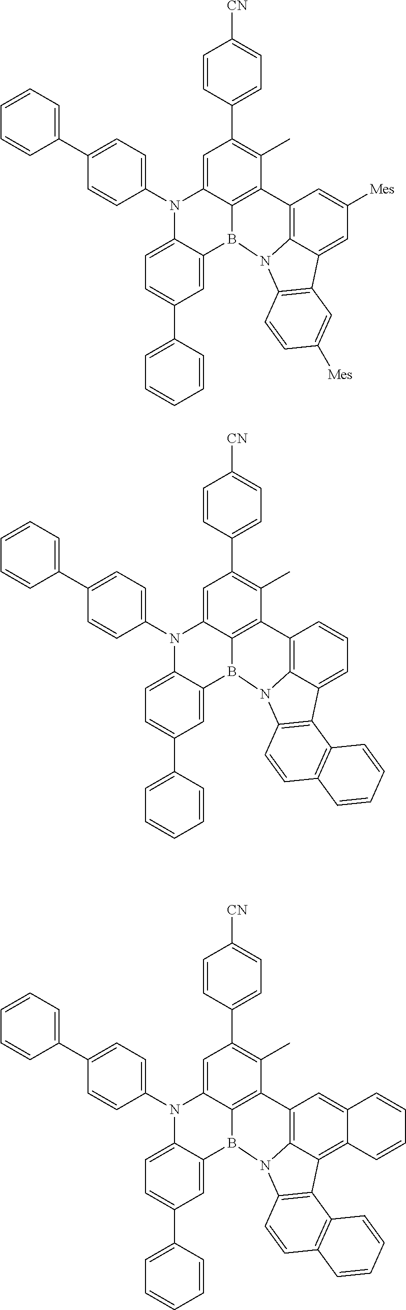

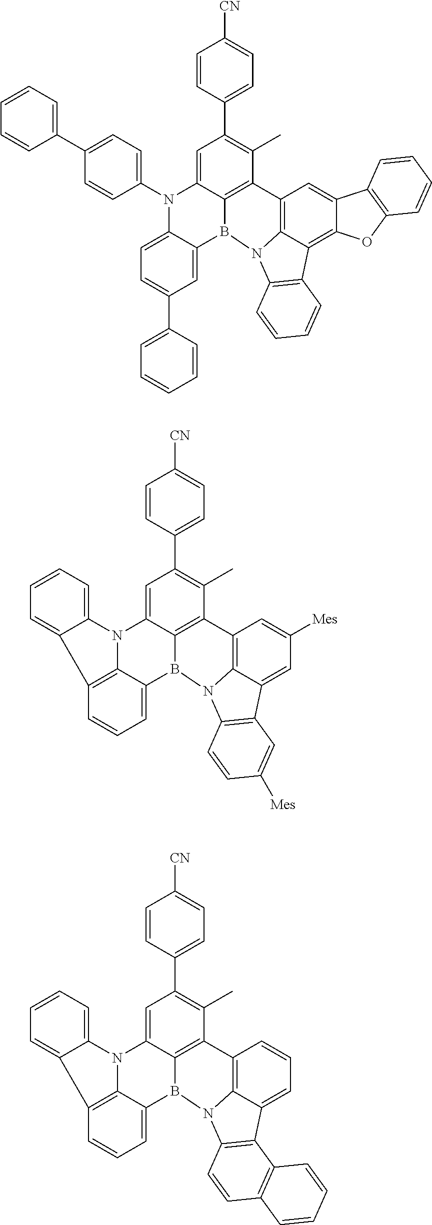

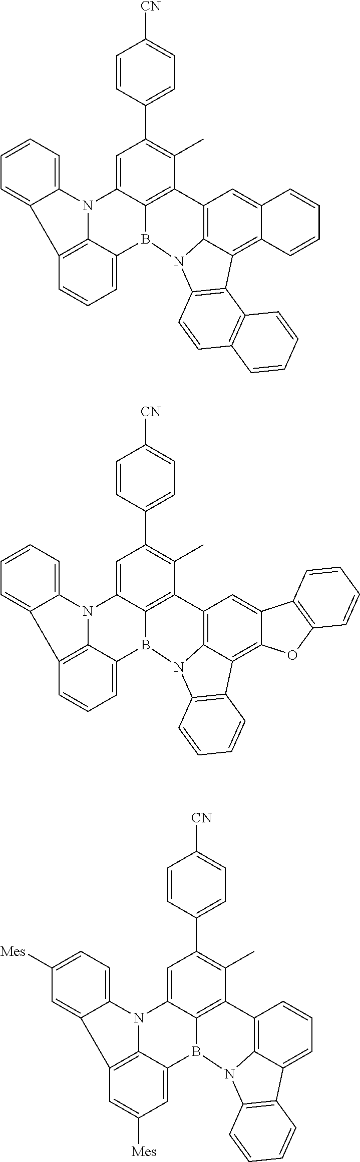

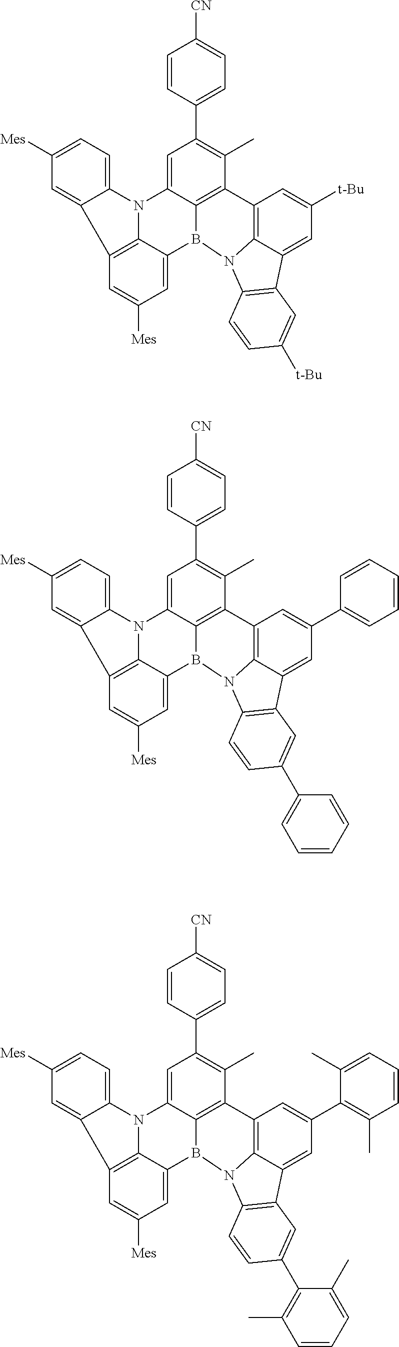

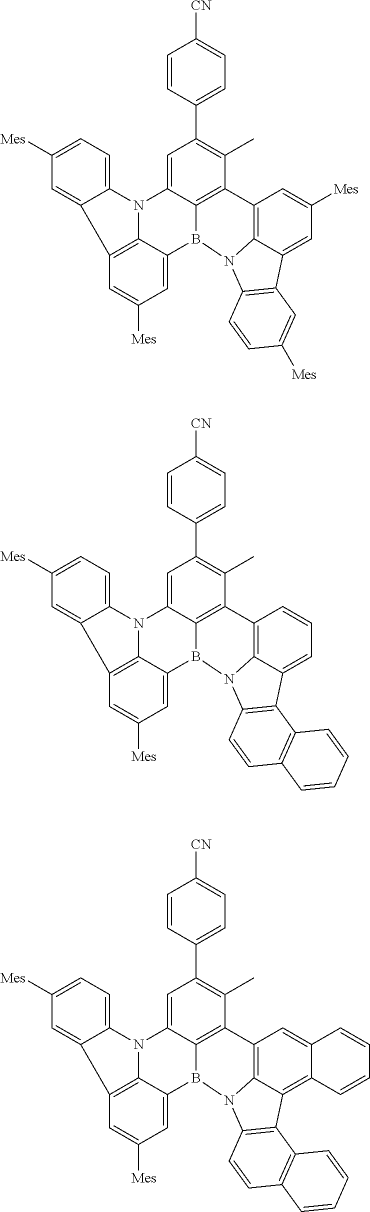

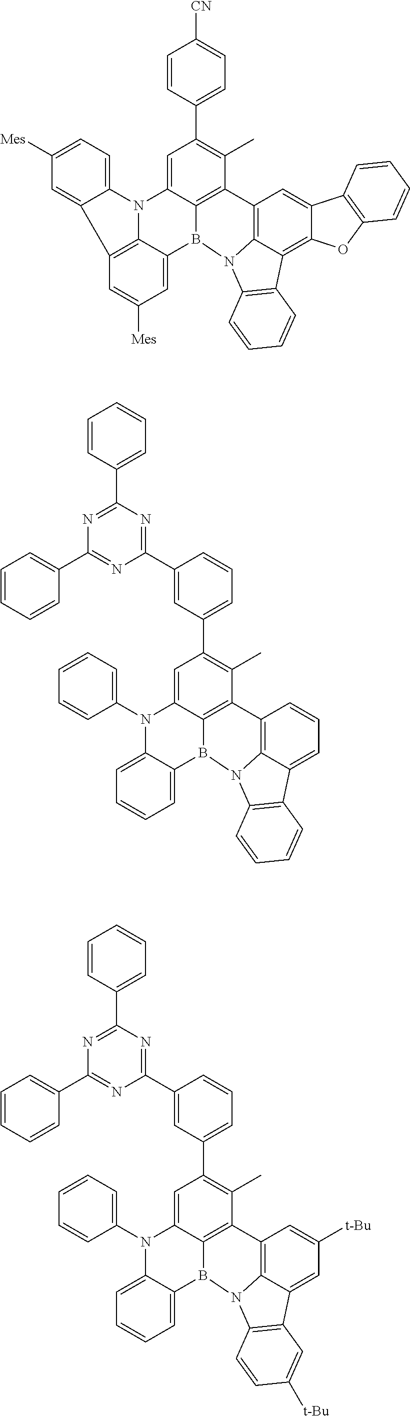

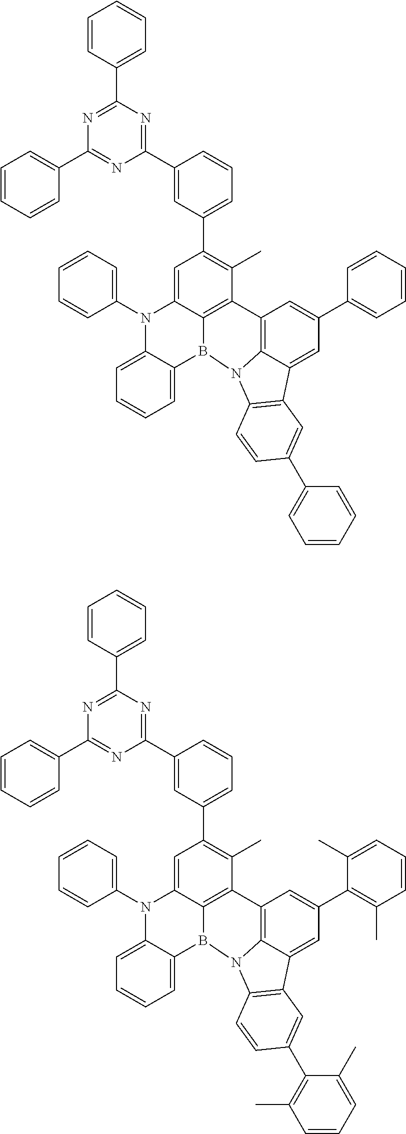 [SMILES: Cc1c(-c2cccc(-c3nc(-c4ccccc4)nc(-c4ccccc4)n3)c2)cc2c3c1-c1cc(-c4ccccc4)cc4c5cc(-c6ccccc6)ccc5n(c14)B3c1ccccc1N2c1ccccc1 ; Cc1cccc(C)c1-c1ccc2c(c1)c1cc(-c3c(C)cccc3C)cc3c1n2B1c2ccccc2N(c2ccccc2)c2cc(-c4cccc(-c5nc(-c6ccccc6)nc(-c6ccccc6)n5)c4)c(C)c-3c21]

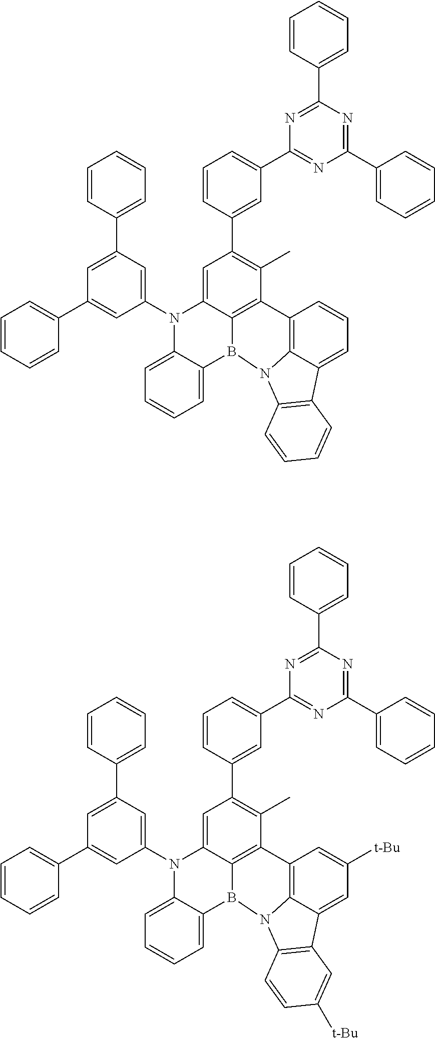 [SMILES: Cc1c(-c2cccc(-c3nc(-c4ccccc4)nc(-c4ccccc4)n3)c2)cc2c3c1-c1cccc4c5ccccc5n(c14)B3c1ccccc1N2c1cc(-c2ccccc2)cc(-c2ccccc2)c1 ; Cc1c(-c2cccc(-c3nc(-c4ccccc4)nc(-c4ccccc4)n3)c2)cc2c3c1-c1cc(C(C)(C)C)cc4c5cc(C(C)(C)C)ccc5n(c14)B3c1ccccc1N2c1cc(-c2ccccc2)cc(-c2ccccc2)c1]

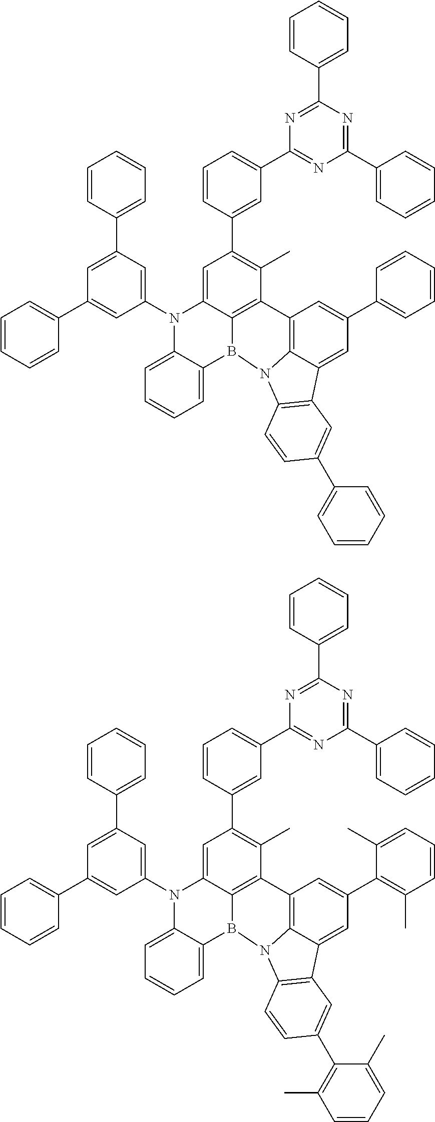

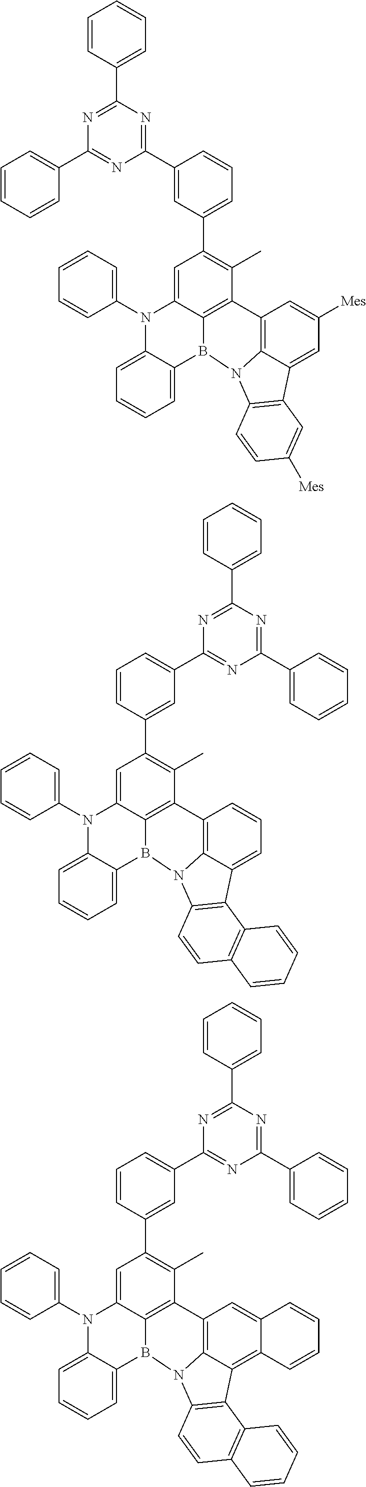

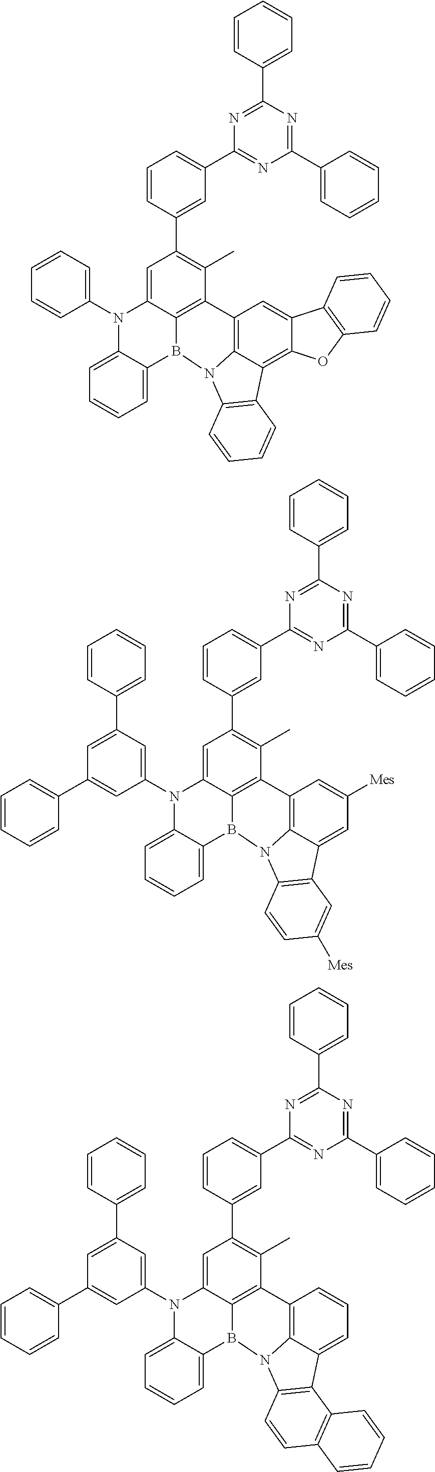

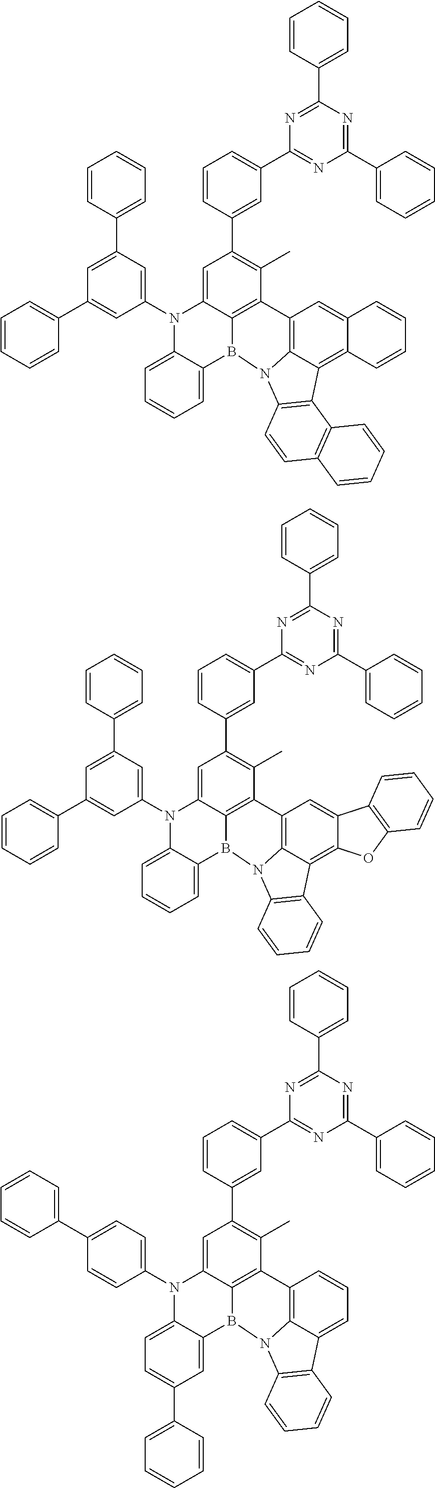

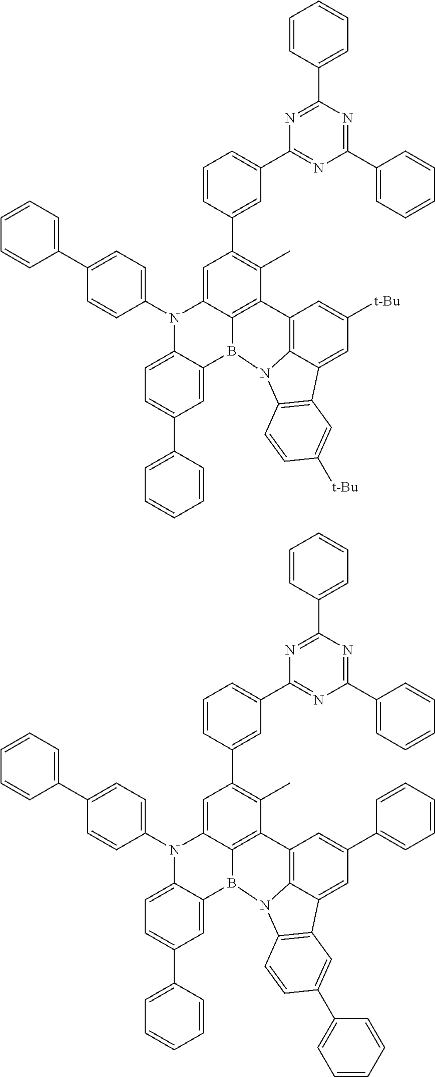 [SMILES: Cc1c(-c2cccc(-c3nc(-c4ccccc4)nc(-c4ccccc4)n3)c2)cc2c3c1-c1cc(C(C)(C)C)cc4c5cc(C(C)(C)C)ccc5n(c14)B3c1cc(-c3ccccc3)ccc1N2c1ccc(-c2ccccc2)cc1 ; Cc1c(-c2cccc(-c3nc(-c4ccccc4)nc(-c4ccccc4)n3)c2)cc2c3c1-c1cc(-c4ccccc4)cc4c5cc(-c6ccccc6)ccc5n(c14)B3c1cc(-c3ccccc3)ccc1N2c1ccc(-c2ccccc2)cc1]

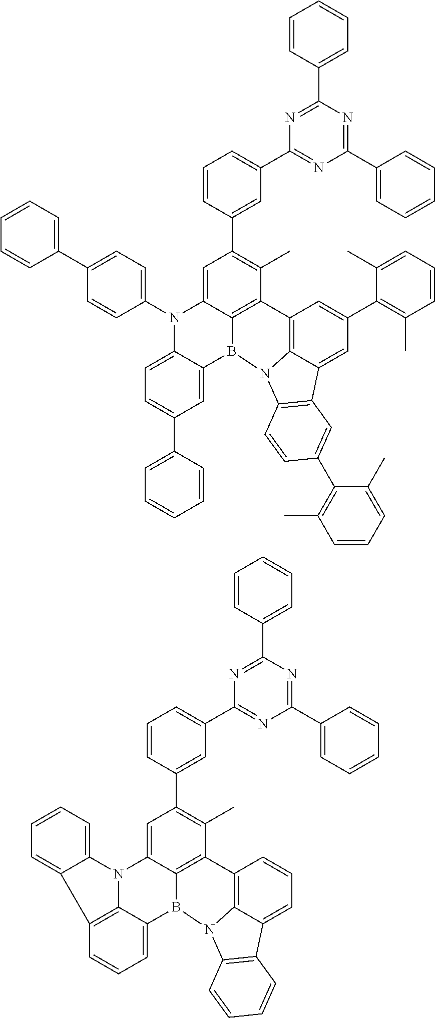

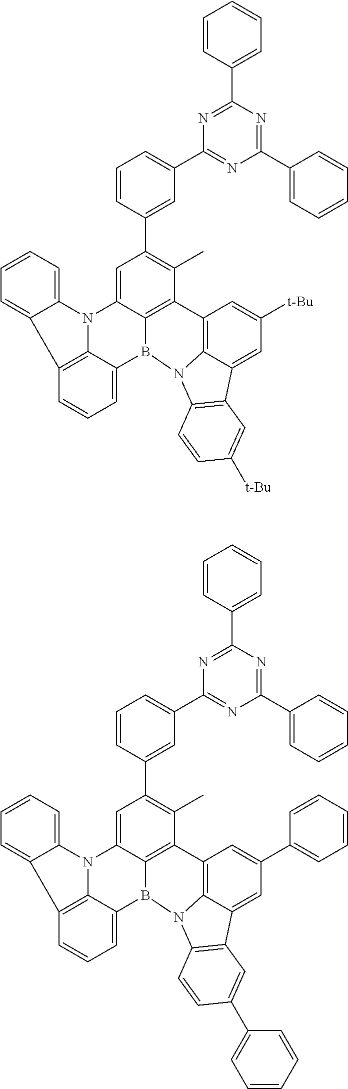 [SMILES: Cc1c(-c2cccc(-c3nc(-c4ccccc4)nc(-c4ccccc4)n3)c2)cc2c3c1-c1cc(C(C)(C)C)cc4c5cc(C(C)(C)C)ccc5n(c14)B3c1cccc3c4ccccc4n-2c13 ; Cc1c(-c2cccc(-c3nc(-c4ccccc4)nc(-c4ccccc4)n3)c2)cc2c3c1-c1cc(-c4ccccc4)cc4c5cc(-c6ccccc6)ccc5n(c14)B3c1cccc3c4ccccc4n-2c13]

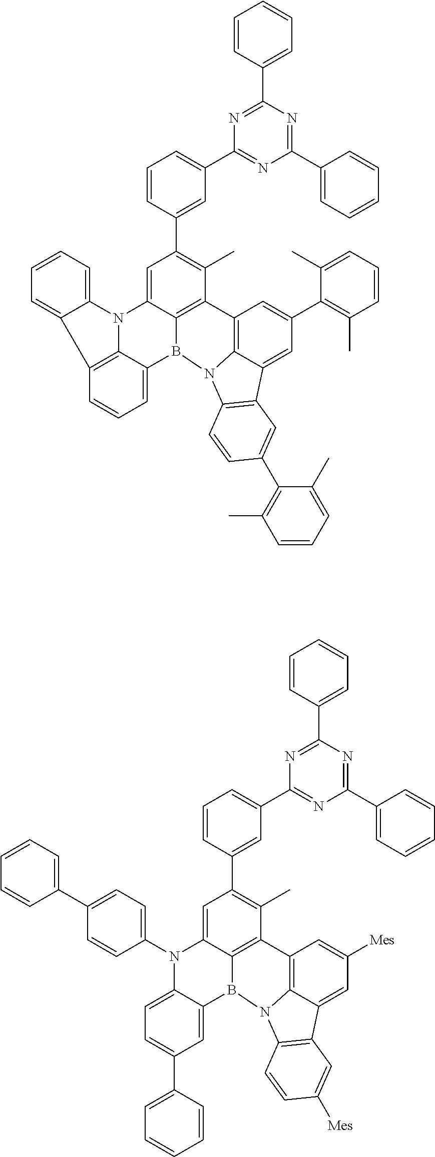

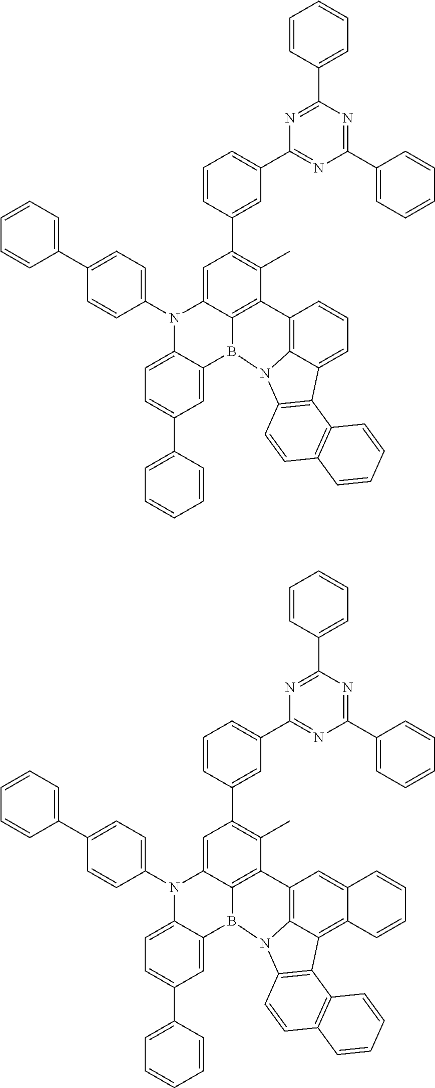 [SMILES: Cc1c(-c2cccc(-c3nc(-c4ccccc4)nc(-c4ccccc4)n3)c2)cc2c3c1-c1cccc4c5c6ccccc6ccc5n(c14)B3c1cc(-c3ccccc3)ccc1N2c1ccc(-c2ccccc2)cc1 ; Cc1c(-c2cccc(-c3nc(-c4ccccc4)nc(-c4ccccc4)n3)c2)cc2c3c1-c1cc4ccccc4c4c5c6ccccc6ccc5n(c14)B3c1cc(-c3ccccc3)ccc1N2c1ccc(-c2ccccc2)cc1]

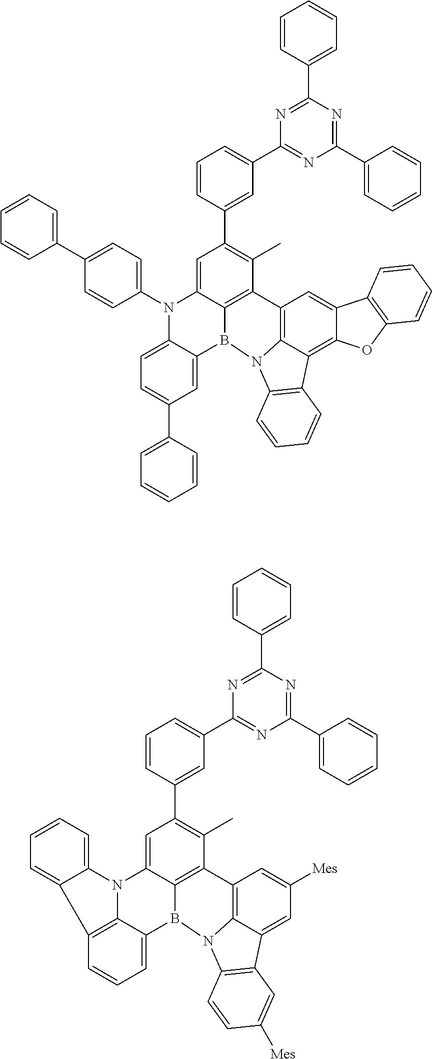

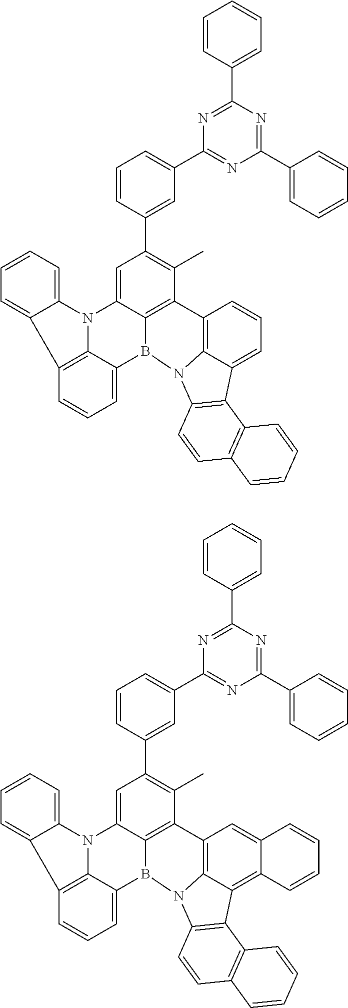

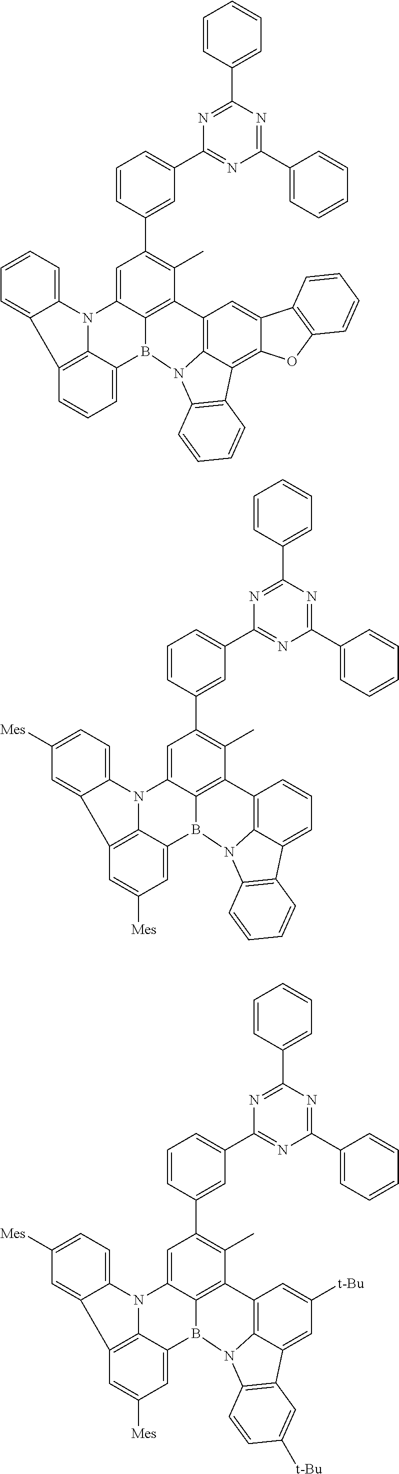

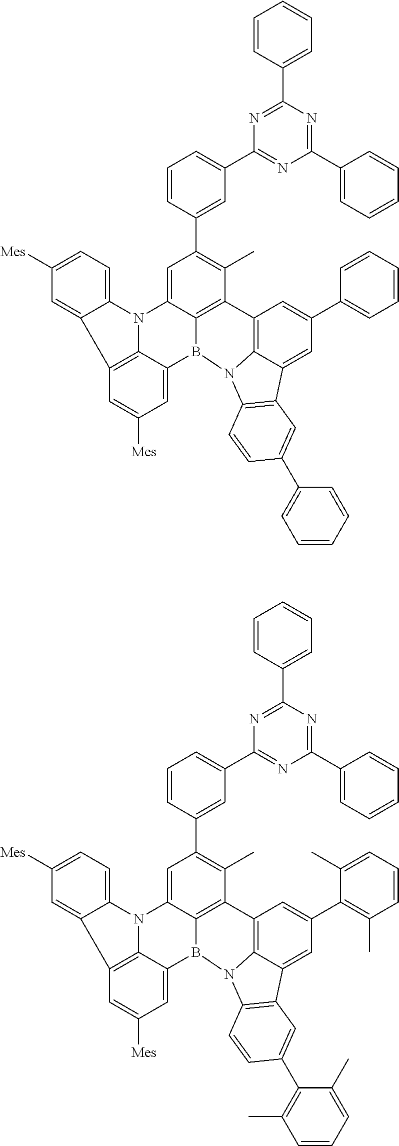

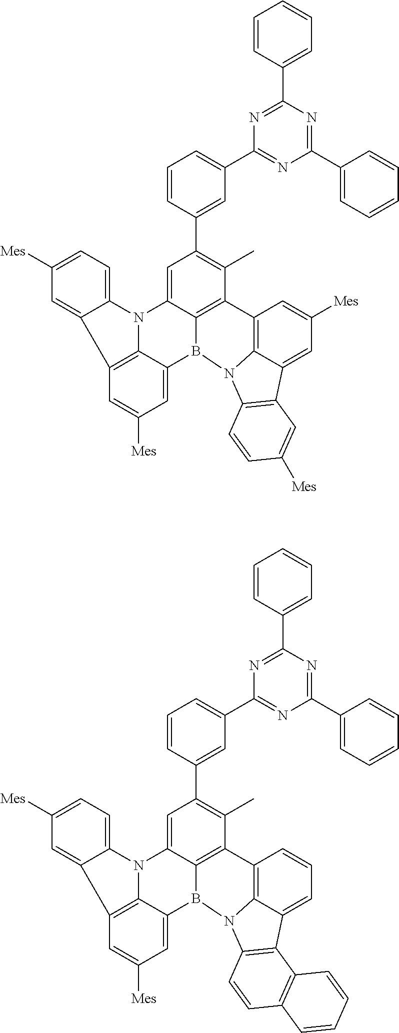

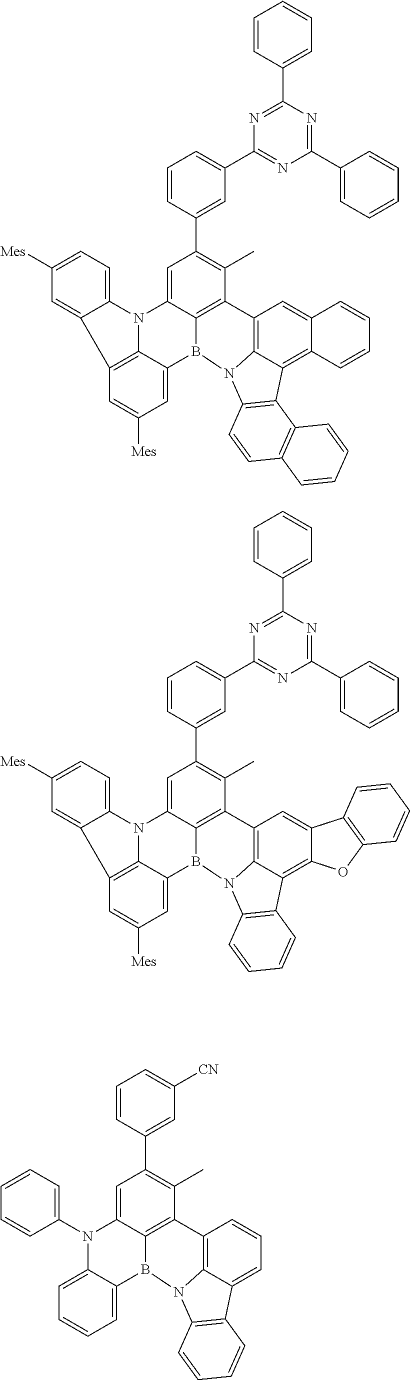

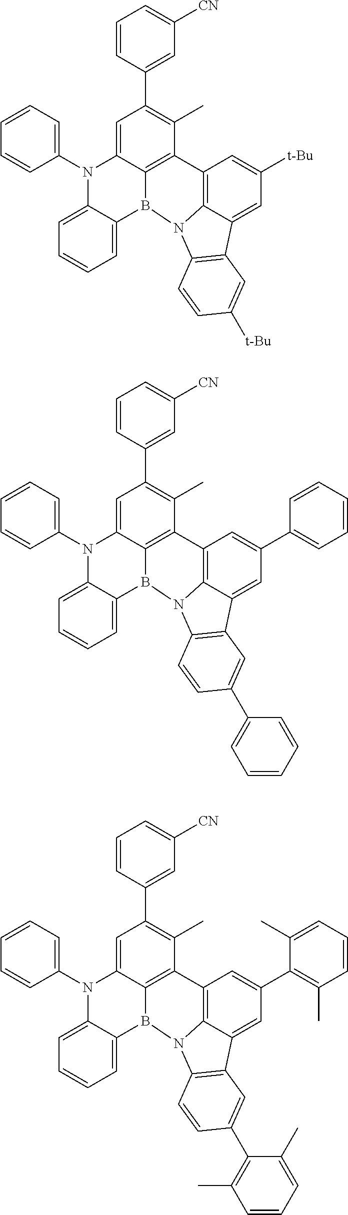 [SMILES: Cc1c(-c2cccc(C#N)c2)cc2c3c1-c1cc(C(C)(C)C)cc4c5cc(C(C)(C)C)ccc5n(c14)B3c1ccccc1N2c1ccccc1 ; Cc1c(-c2cccc(C#N)c2)cc2c3c1-c1cc(-c4ccccc4)cc4c5cc(-c6ccccc6)ccc5n(c14)B3c1ccccc1N2c1ccccc1 ; Cc1cccc(C)c1-c1ccc2c(c1)c1cc(-c3c(C)cccc3C)cc3c1n2B1c2ccccc2N(c2ccccc2)c2cc(-c4cccc(C#N)c4)c(C)c-3c21]

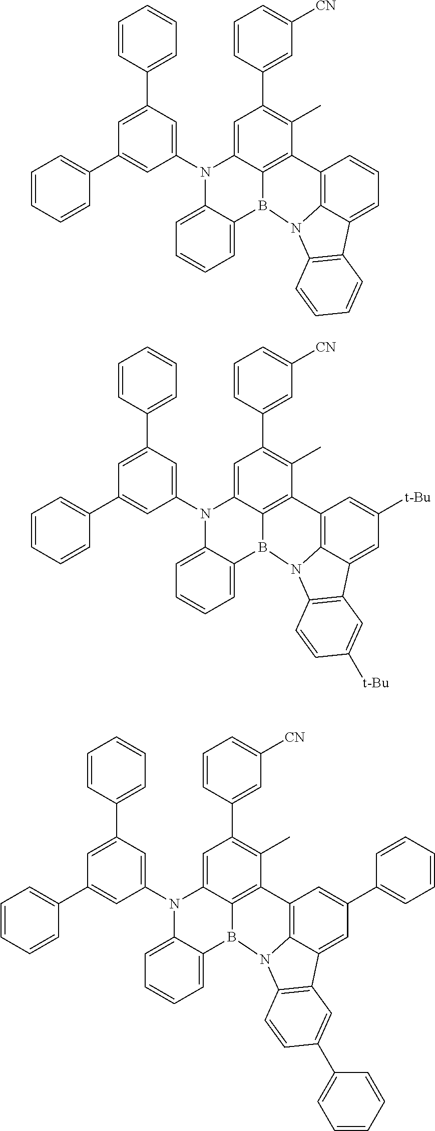

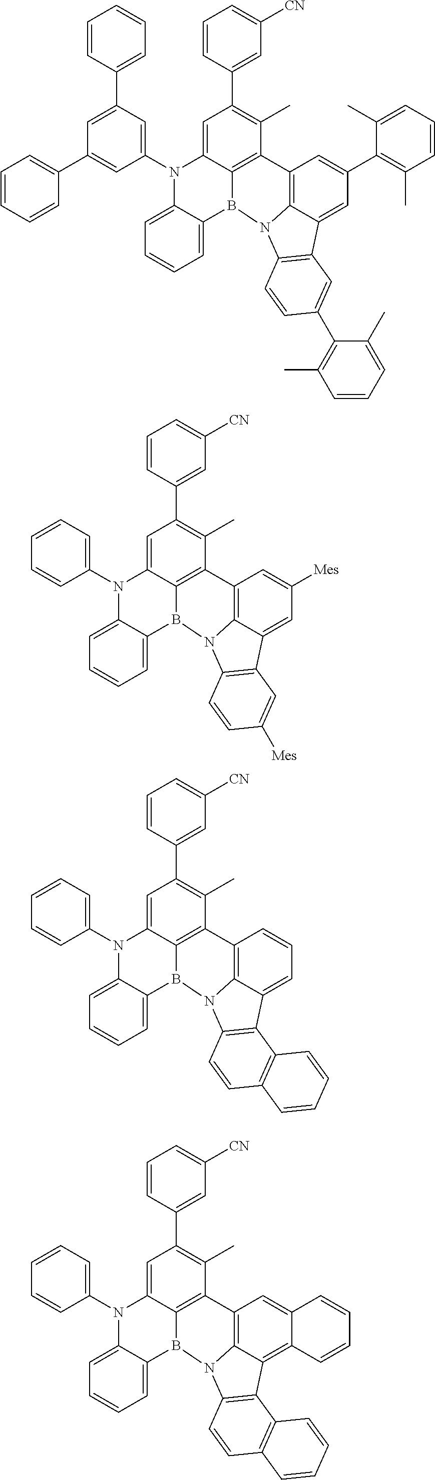

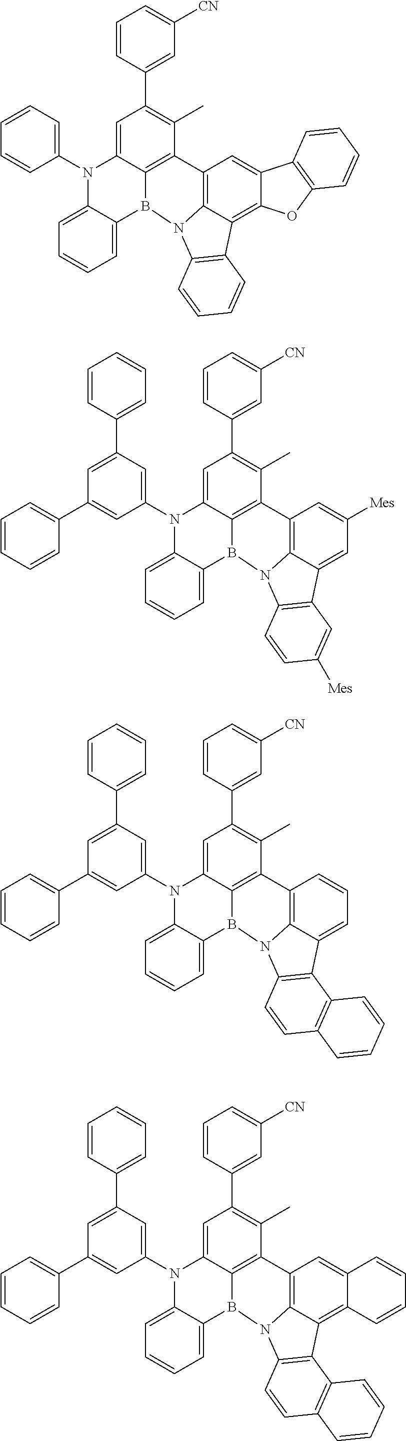

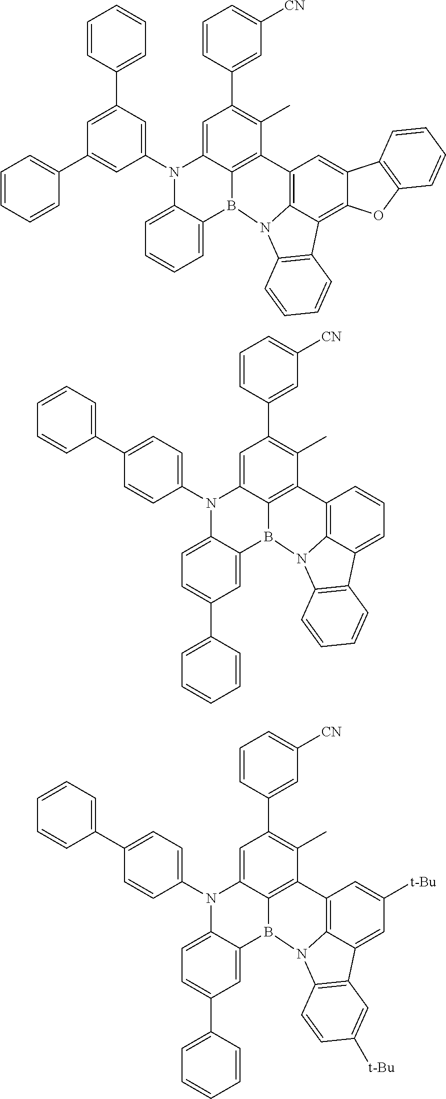

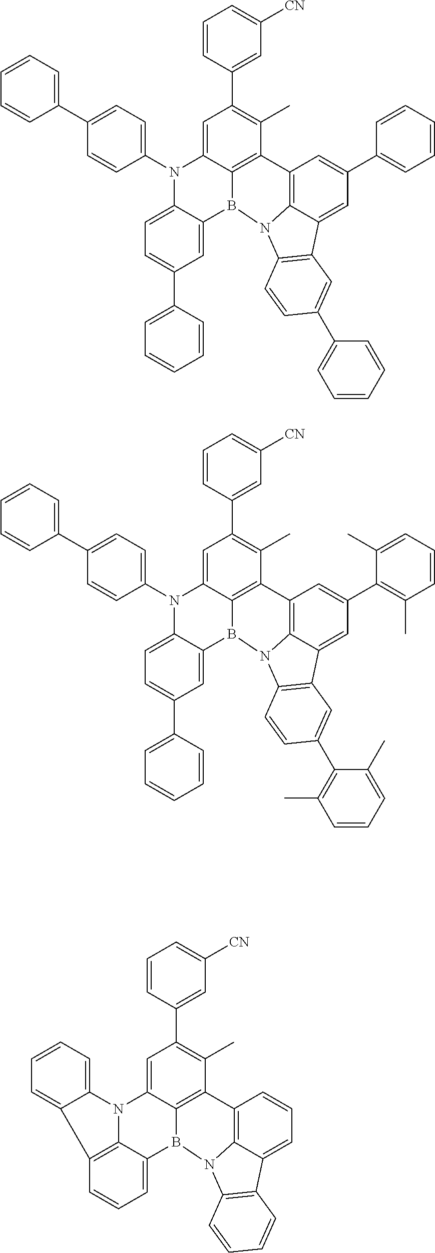 [SMILES: Cc1c(-c2cccc(C#N)c2)cc2c3c1-c1cc(-c4ccccc4)cc4c5cc(-c6ccccc6)ccc5n(c14)B3c1cc(-c3ccccc3)ccc1N2c1ccc(-c2ccccc2)cc1 ; Cc1cccc(C)c1-c1ccc2c(c1)c1cc(-c3c(C)cccc3C)cc3c1n2B1c2cc(-c4ccccc4)ccc2N(c2ccc(-c4ccccc4)cc2)c2cc(-c4cccc(C#N)c4)c(C)c-3c21 ; Cc1c(-c2cccc(C#N)c2)cc2c3c1-c1cccc4c5ccccc5n(c14)B3c1cccc3c4ccccc4n-2c13]

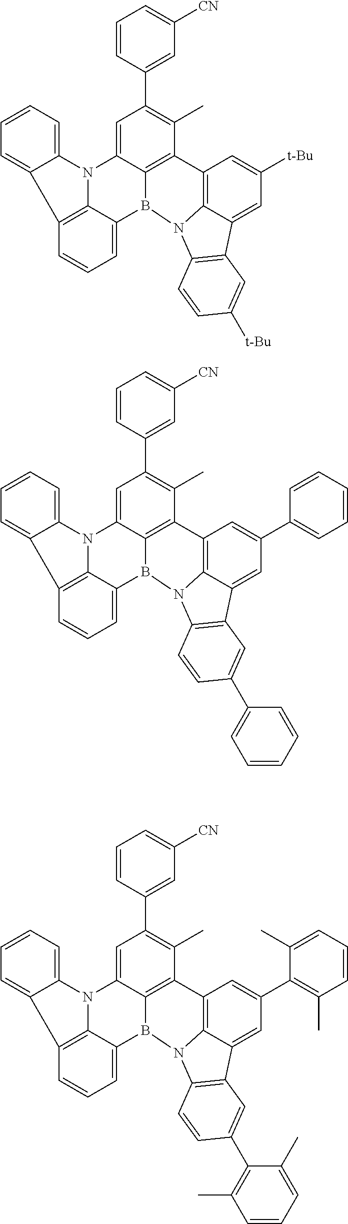 [SMILES: Cc1c(-c2cccc(C#N)c2)cc2c3c1-c1cc(C(C)(C)C)cc4c5cc(C(C)(C)C)ccc5n(c14)B3c1cccc3c4ccccc4n-2c13 ; Cc1c(-c2cccc(C#N)c2)cc2c3c1-c1cc(-c4ccccc4)cc4c5cc(-c6ccccc6)ccc5n(c14)B3c1cccc3c4ccccc4n-2c13 ; Cc1cccc(C)c1-c1ccc2c(c1)c1cc(-c3c(C)cccc3C)cc3c1n2B1c2c(cc(-c4cccc(C#N)c4)c(C)c2-3)-n2c3ccccc3c3cccc1c32]

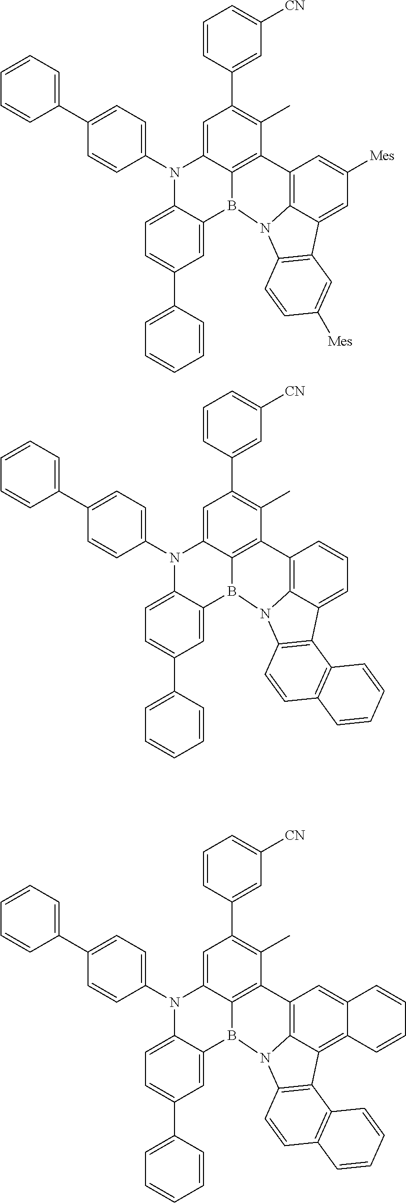

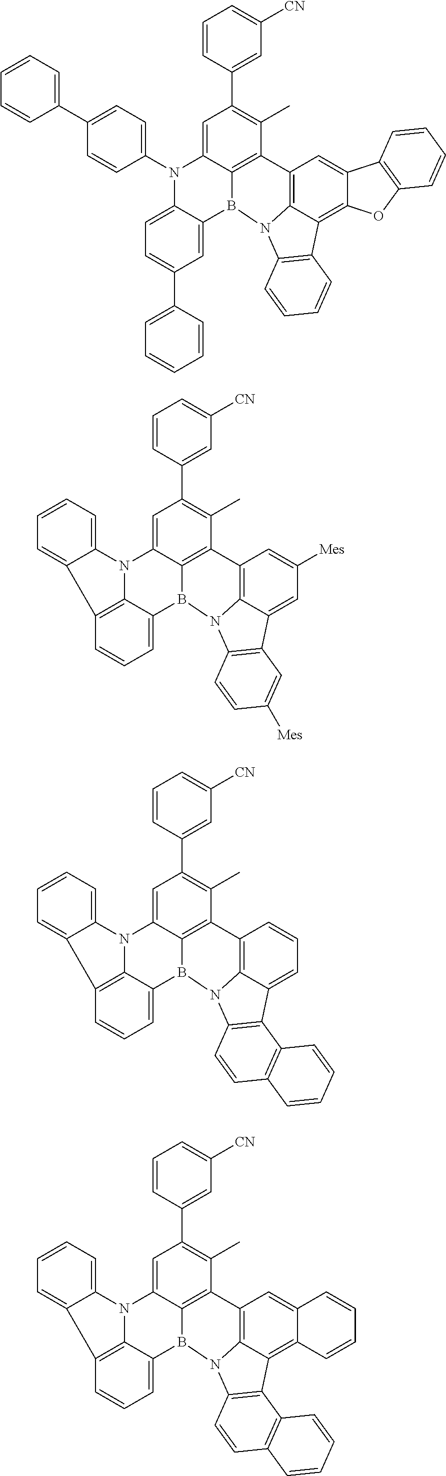

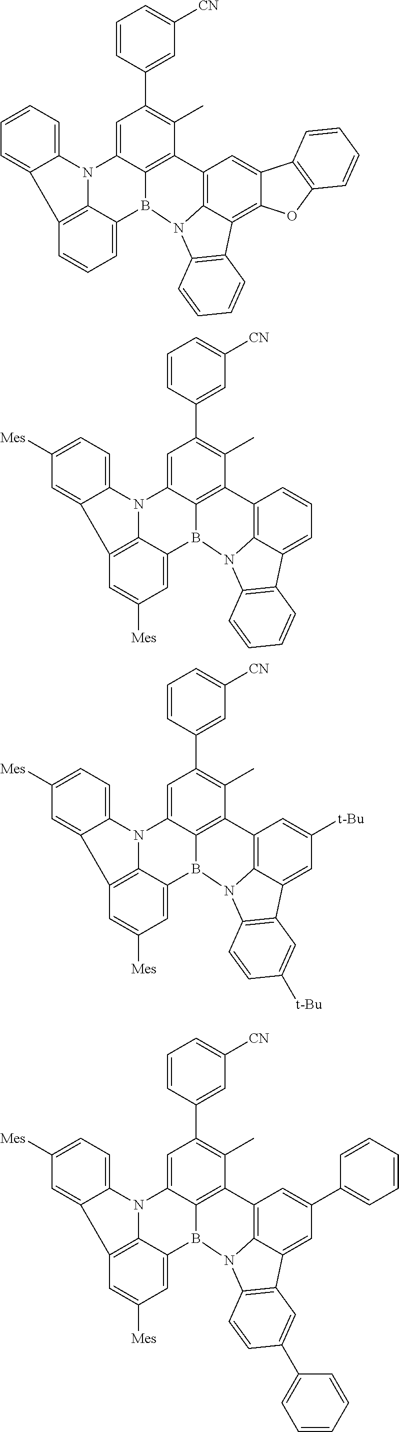

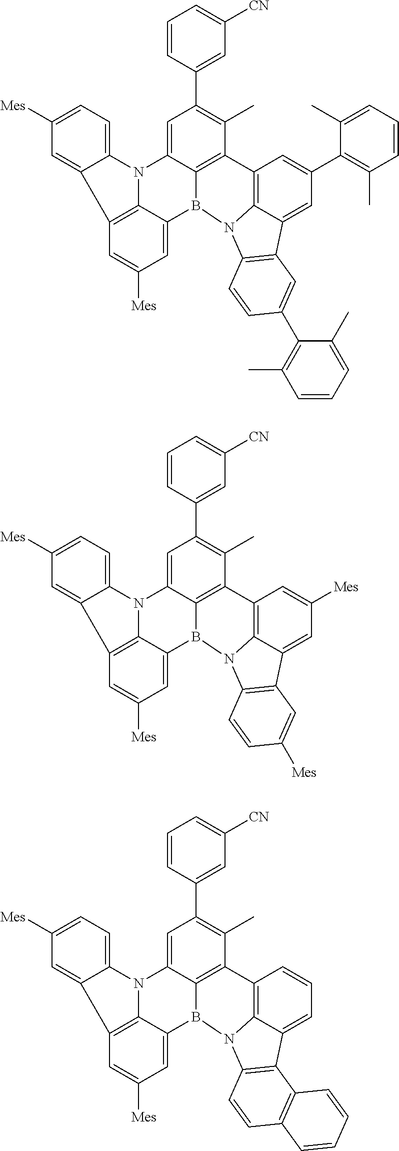

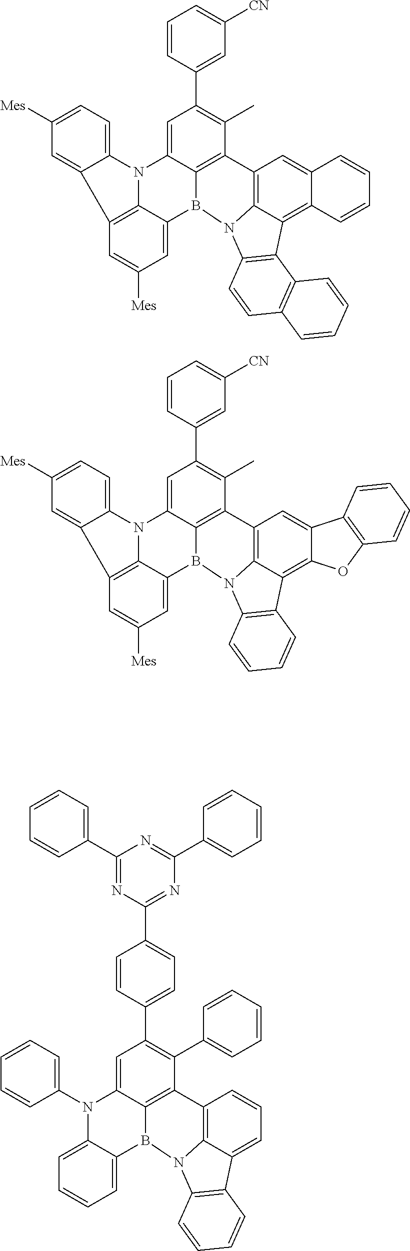

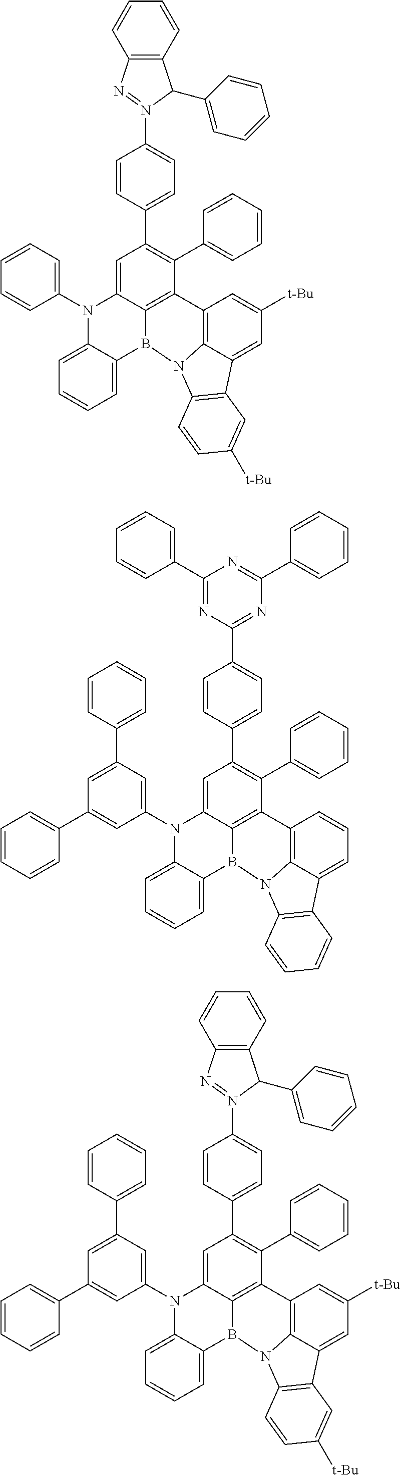

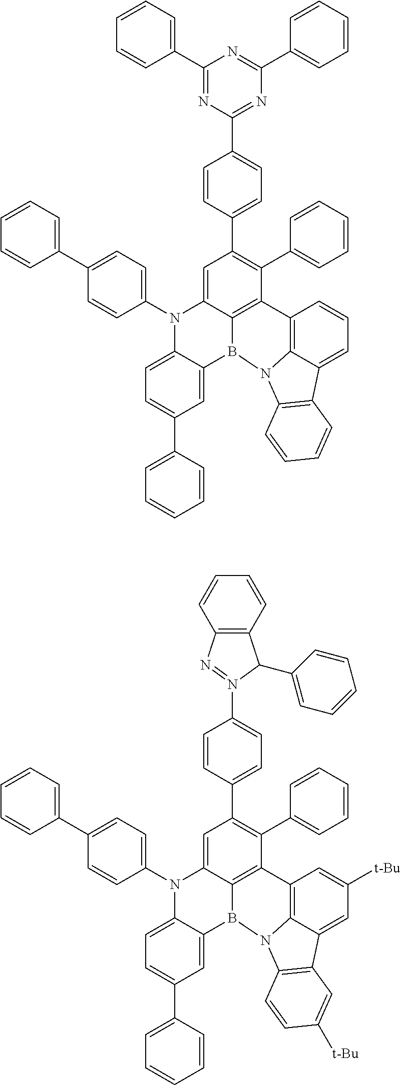

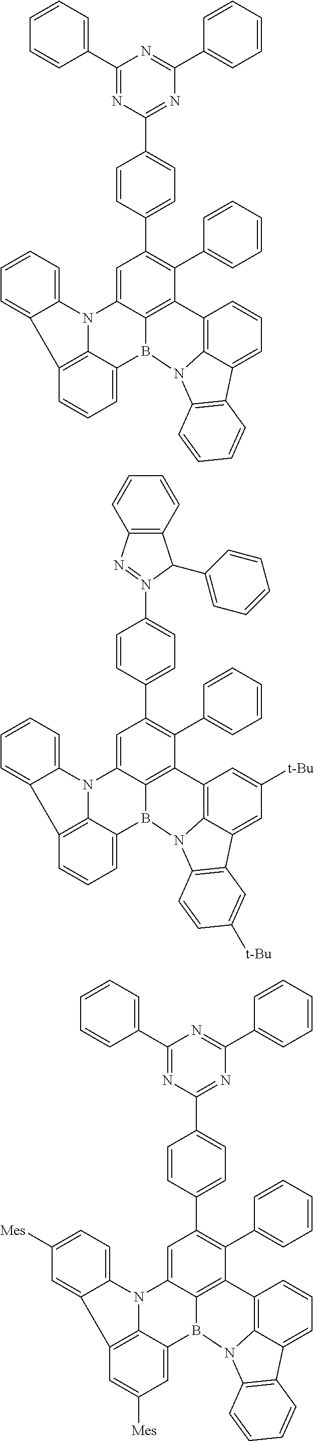

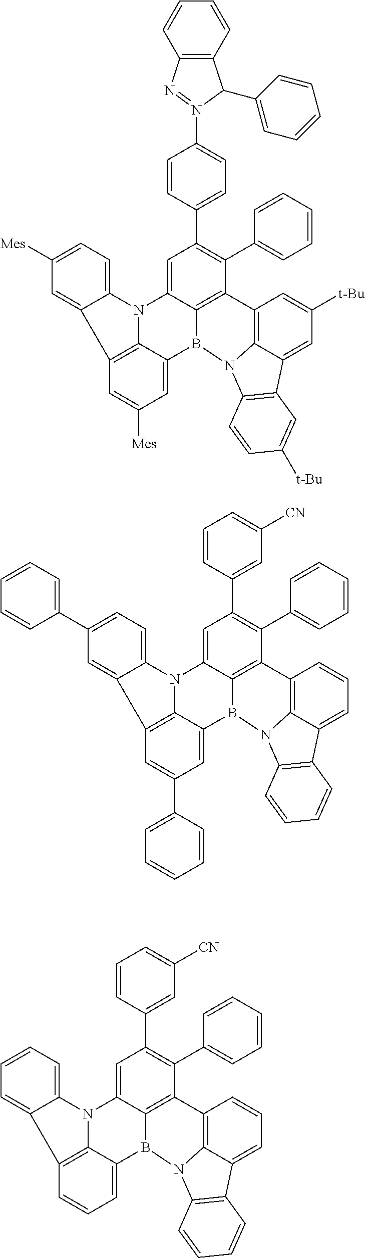

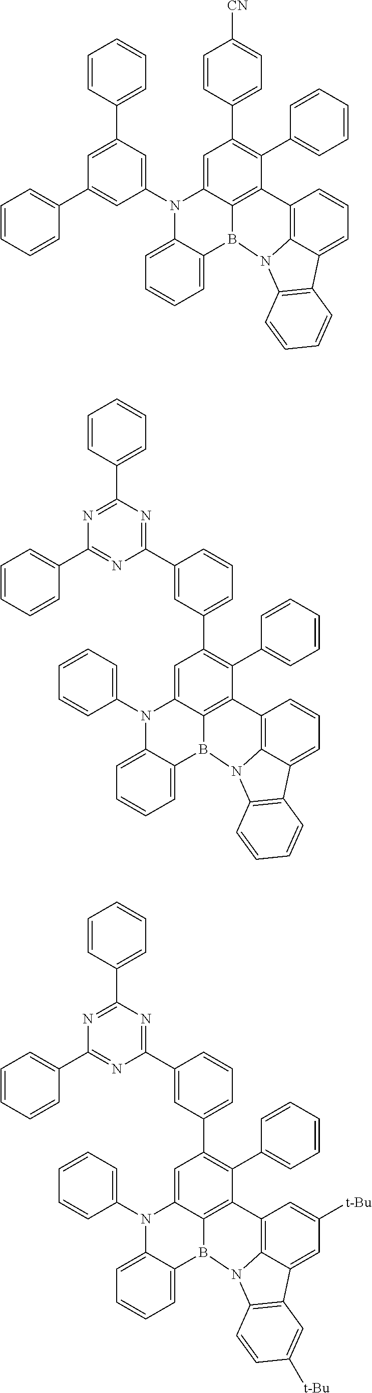 [SMILES: N#Cc1ccc(-c2cc3c4c(c2-c2ccccc2)-c2cccc5c6ccccc6n(c25)B4c2ccccc2N3c2cc(-c3ccccc3)cc(-c3ccccc3)c2)cc1 ; c1ccc(-c2nc(-c3ccccc3)nc(-c3cccc(-c4cc5c6c(c4-c4ccccc4)-c4cccc7c8ccccc8n(c47)B6c4ccccc4N5c4ccccc4)c3)n2)cc1 ; CC(C)(C)c1ccc2c(c1)c1cc(C(C)(C)C)cc3c1n2B1c2ccccc2N(c2ccccc2)c2cc(-c4cccc(-c5nc(-c6ccccc6)nc(-c6ccccc6)n5)c4)c(-c4ccccc4)c-3c21]

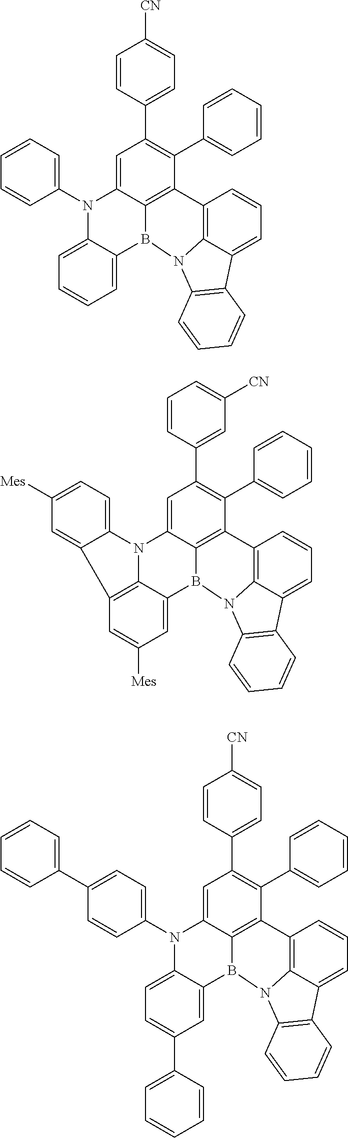

1. An organic molecule, comprising a structure represented by Formula I 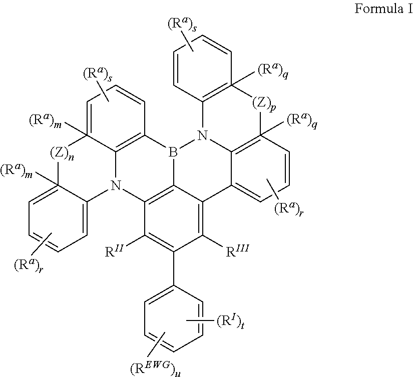
wherein
n, m, p, and q is each an integer selected from 0 and 1, wherein n+m=1 and p +q=1;
r is at each occurrence an integer independently selected from 0, 1, 2, 3 or 4;
s is at each occurrence an integer independently selected from 0, 1, 2 or 3;
t is an integer selected from 0, 1, 2, 3, or 4; and
u is an integer selected from 1, 2, 3, 4 or 5;
wherein t+u≤ 5;
Z is at each occurrence independently selected from the group consisting of a direct bond, CR³R⁴, C═CR³R⁴, C═O, C═NR³, NR³, O, SIR³R⁴, S, S(O) and S(O)₂;
R^{I}, R^{II} and R^{III} is at each occurrence independently from each other selected from the group consisting of
hydrogen,
deuterium,
C₁-C₆-alkyl and
C₆-C₁₂-aryl, which is optionally substituted with one or more C₁-C₆-alkyl substituents;
R^{EWG} is selected from the group consisting of F, CF₃, CN, a substituted or unsubstituted C₆-C₆₀-aryl, and a substituted or unsubstituted C₂-C₅₇-heteroaryl,
R^{a}, R³ and R⁴ is at each occurrence independently selected from the group consisting of: hydrogen, deuterium, N(R⁵)₂, OR⁵, Si(R⁵)₃, B(OR⁵)₂, B(R⁵)₂, OSO₂R⁵, CF₃, CN, F, Br, I, C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵;
R⁵ is at each occurrence independently from another selected from the group consisting of: hydrogen, deuterium, N(R⁶)₂, OR⁶, Si(R⁶)₃, B(OR⁶)₂, B(R⁶)₂, OSO₂R⁶, CF₃, CN, F, Br, I,
C₁-C₄₀-alkyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-alkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₁-C₄₀-thioalkoxy,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkenyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₂-C₄₀-alkynyl,
which is optionally substituted with one or more substituents R⁶ and
wherein one or more non-adjacent CH₂-groups are optionally substituted by R⁶C═CR⁶, C≡C, Si(R⁶)₂, Ge(R⁶)₂, Sn(R⁶)₂, C═O, C═S, C═Se, C═NR⁶, P(═O)(R⁶), SO, SO₂, NR⁶, O, S or CONR⁶;
C₆-C₆₀-aryl,
which is optionally substituted with one or more substituents R⁶; and
C₂-C₅₇-heteroaryl,
which is optionally substituted with one or more substituents R⁶;
R⁶ is at each occurrence independently from another selected from the group consisting of: hydrogen, deuterium, OPh, CF₃, CN, F,
C₁-C₅-alkyl,
wherein one or more hydrogen atoms are optionally, independently substituted by deuterium, CN, CF₃, or F;
C₁-C₅-alkoxy,
wherein one or more hydrogen atoms are optionally, independently substituted by deuterium, CN, CF₃, or F;
C₁-C₅-thioalkoxy,
wherein one or more hydrogen atoms are optionally, independently substituted by deuterium, CN, CF₃, or F;
C₂-C₅-alkenyl,
wherein one or more hydrogen atoms are optionally, independently substituted by deuterium, CN, CF₃, or F;
C₂-C₅-alkynyl,
wherein one or more hydrogen atoms are optionally, independently substituted by deuterium, CN, CF₃, or F;
C₆-C₁₈-aryl,
which is optionally substituted with one or more C₁-C₅-alkyl substituents;
C₂-C₁₇-heteroaryl,
which is optionally substituted with one or more C₁-C₅-alkyl substituents;
N(C₆-C₁₈-aryl)₂;
N(C₂-C₁₇-heteroaryl)₂, and
N(C₂-C₁₇-heteroaryl)(C₆-C₁₈-aryl);
wherein optionally, any of the substituents R^{a}, R³, R⁴, R⁵, and R⁶ independently form a mono- or polycyclic, aliphatic, aromatic, heteroaromatic and/or benzo-fused ring system with one or more substituents R^{a}, R³, R⁴, R⁵ and/or R⁶.

2. The organic molecule according to claim 1, wherein R^{EWG} is selected from the group consisting of
F, CF₃, CN,
a group E, which is
an aryl having 6 to 14 aromatic ring atoms or a heteroaryl group having 6 to 14 aromatic ring atoms, which each may be substituted by one or more substituents R⁵, and which contains, as constituents of the aromatic ring, one or more groups V,
wherein the one or more groups V are at each occurrence independently selected from the group consisting of ═N—, ═C(F)—, ═C(CN)— and ═C(CF₃)—, and
wherein the heteroaryl group is not bonded via a nitrogen atom.

3. The organic molecule according to claim 1, wherein R^{EWG} is selected from the following structures: 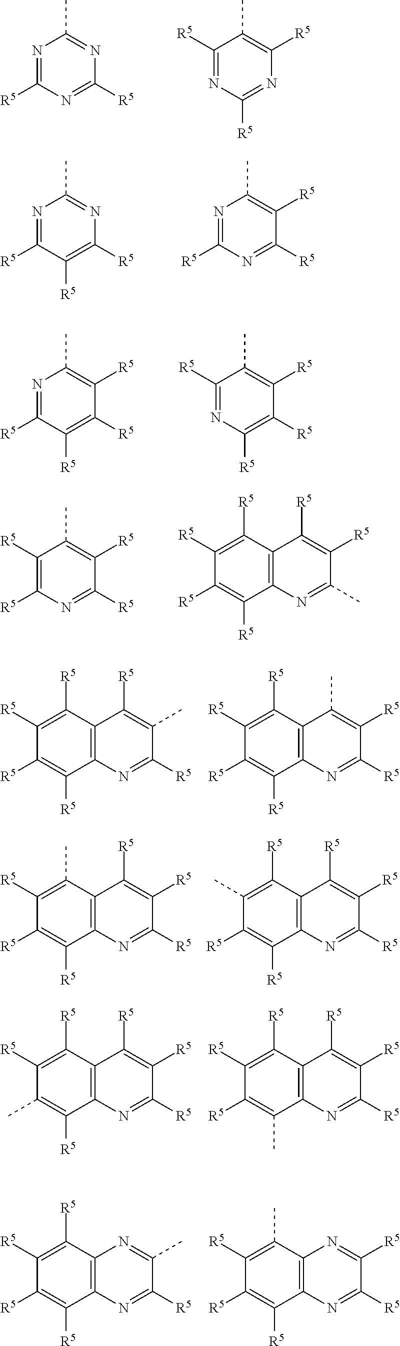 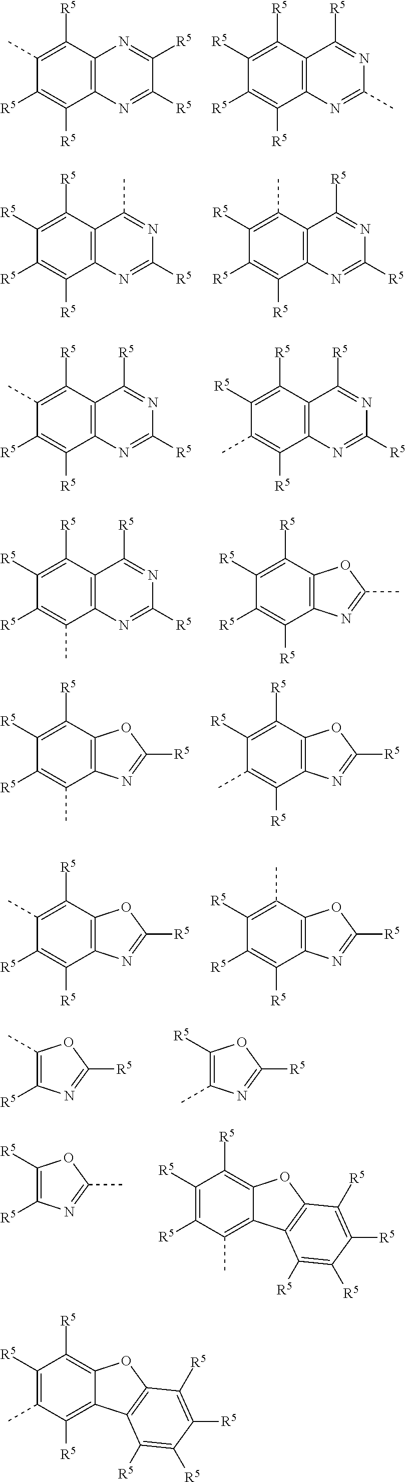 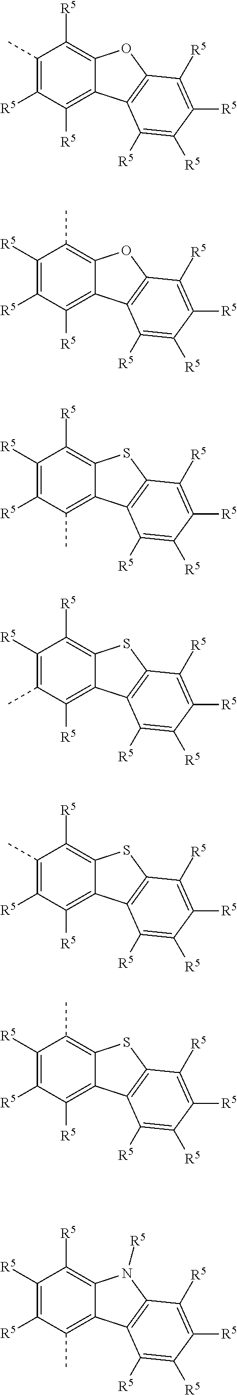 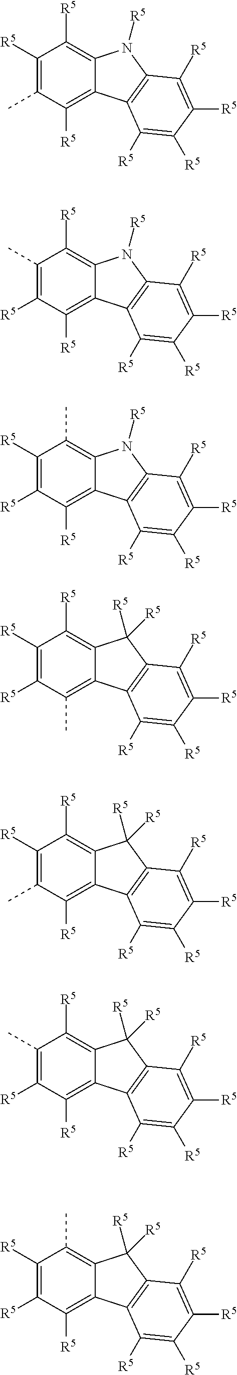 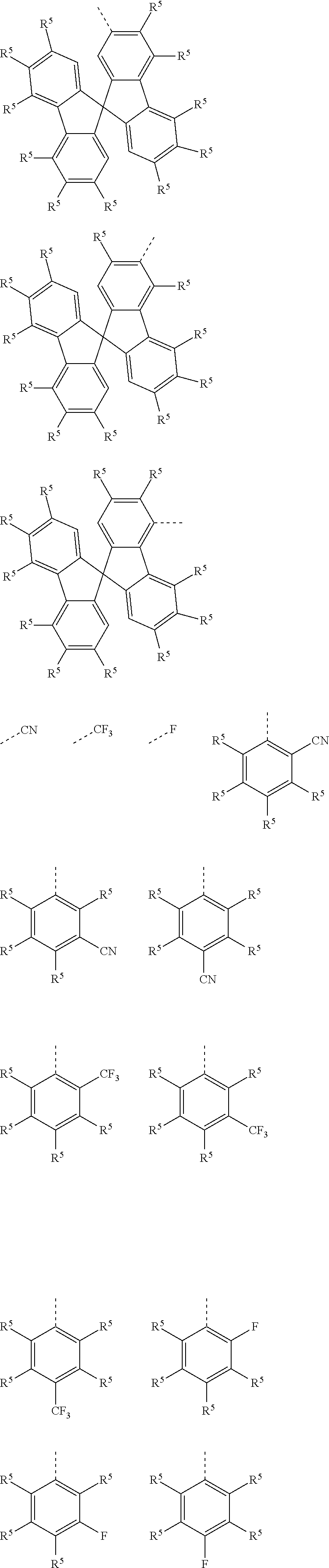 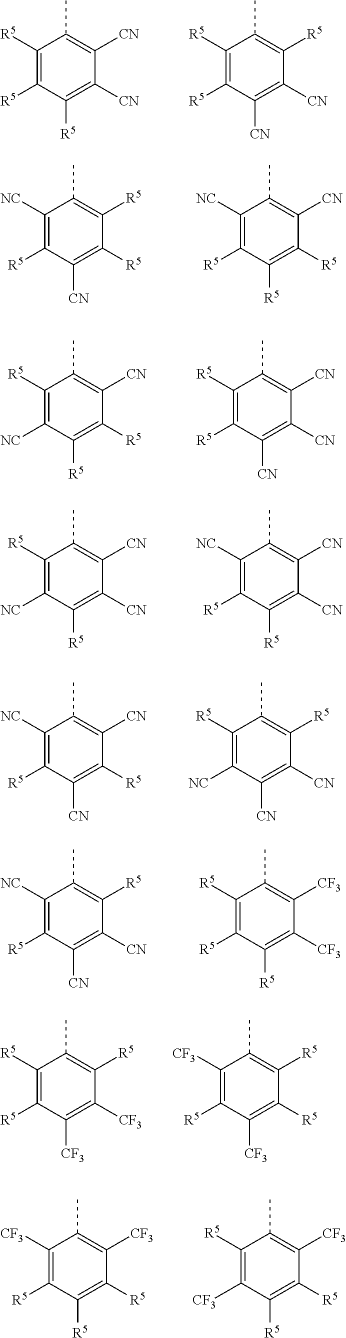 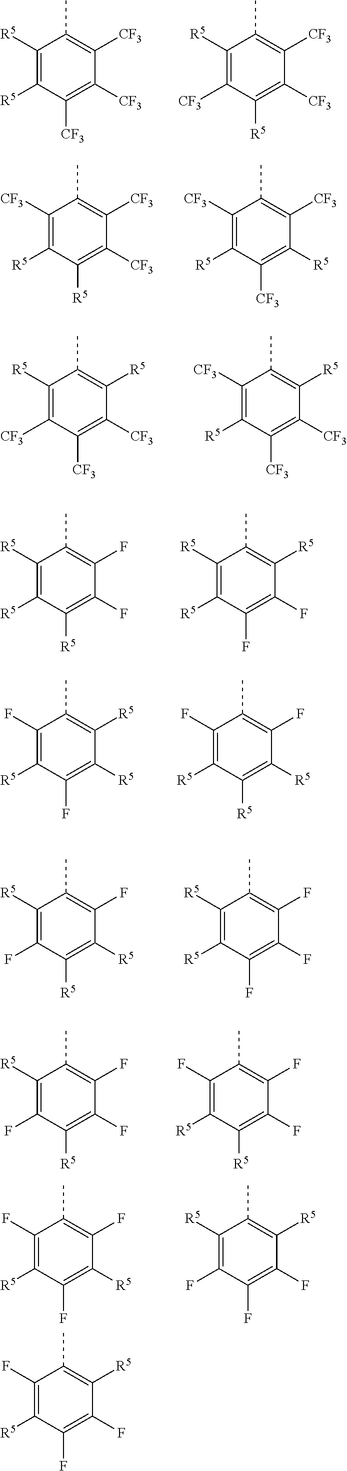
wherein
the dashed line represents a single bond linking the substituent R^{EWG} to the rest of the organic molecule as represented by Formula I; and
wherein, optionally, two or more adjacent substituents R⁵ may independently of each other form a mono- or polycyclic, aliphatic, aromatic and/or benzo-fused ring system, wherein one or more hydrogen atoms of the optionally so formed ring system may be substituted by R⁶.

4. The organic molecule according to any of claim 1, wherein Z is a direct bond.

5. The organic molecule according to claim 1, comprising a structure of Formula IIa, Formula IIb or Formula IIc:

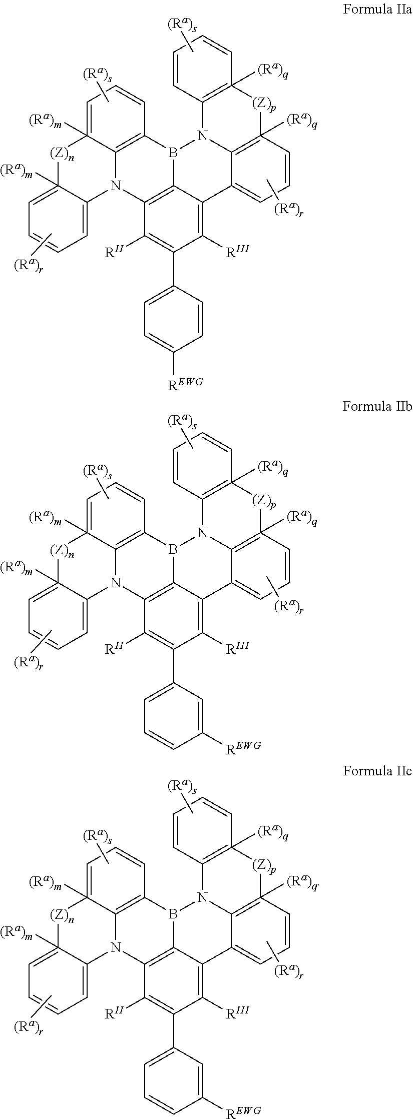

6. The organic molecule according to claim 1, comprising a structure of Formula IIIa, Formula IIIb, Formula IIIc or Formula IIId:

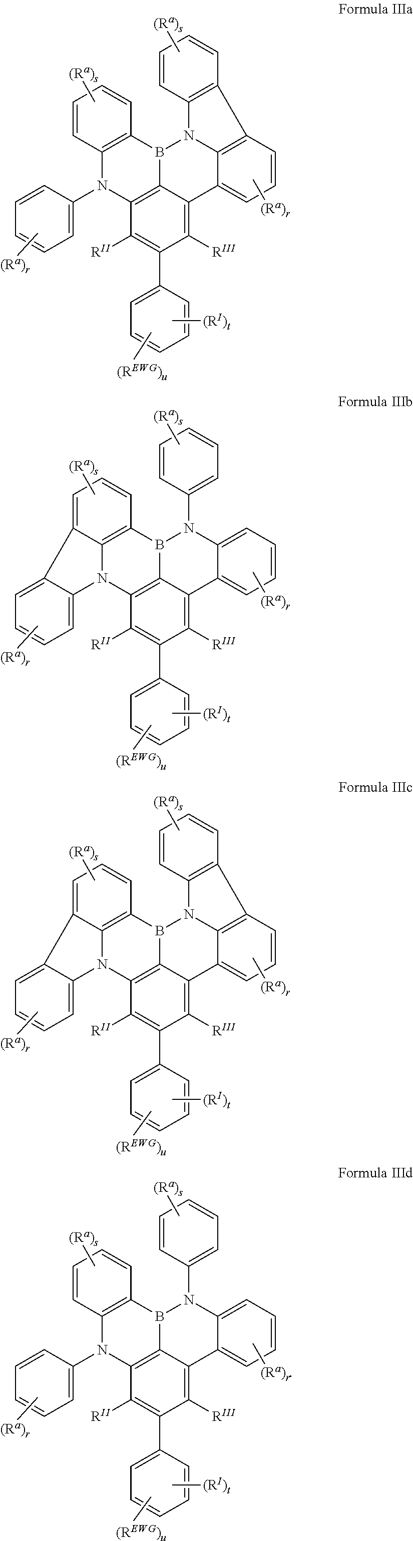

7. The organic molecule according to any of claim 1, comprising a structure of Formula IVa, or Formula IVb:

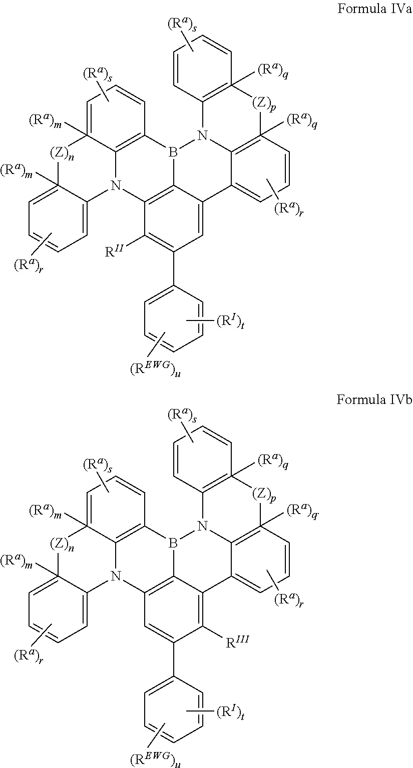

8. The organic molecule according to claim 1, wherein R^{a} is at each occurrence independently from another selected from the group consisting of:
hydrogen,
deuterium,
Me,
ⁱPr,
^{t}Bu,
CN,
CF₃,
Ph, which is optionally substituted with one or more substituents independently from each other selected from the group consisting of Me, ⁱPr, ^{t}Bu, CN, CF₃, and Ph,
pyridinyl, which is optionally substituted with one or more substituents independently from each other selected from the group consisting of Me, ⁱPr, ^{t}Bu, CN, CF₃, and Ph,
pyrimidinyl, which is optionally substituted with one or more substituents independently from each other selected from the group consisting of Me, ⁱPr, ^{t}Bu, CN, CF₃, and Ph,
carbazolyl, which is optionally substituted with one or more substituents independently from each other selected from the group consisting of Me, ⁱPr, ^{t}Bu, CN, CF₃, and Ph,
triazinyl, which is optionally substituted with one or more substituents independently from each other selected from the group consisting of Me, ⁱPr, ^{t}Bu, CN, CF₃, and Ph,
and N(Ph)₂, which is optionally substituted with one or more substituents independently from each other selected from the group consisting of Me, ⁱPr, ^{t}Bu, CN, CF₃, and Ph;
wherein two or more adjacent substituents R^{a} may form attachment points for a ring system selected from the group consisting of: 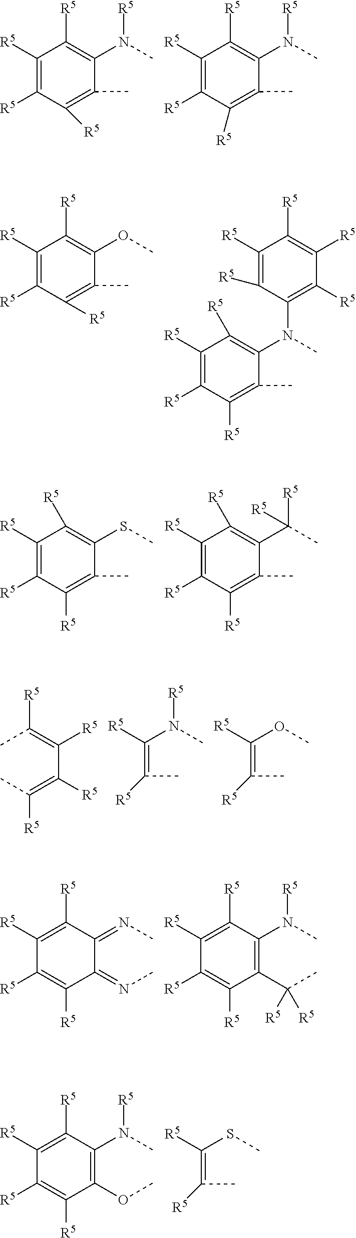 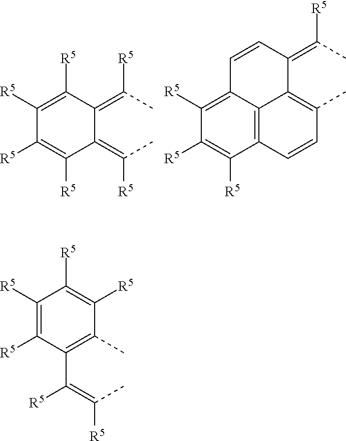
wherein each dashed line indicates a direct bond connecting one of the above shown ring systems to the positions of two adjacent substituents R^{a} such that a ring system of the group shown above is fused to the structure as shown in Formula I.

9. The organic molecule according to claim 1, comprising a structure of Formula Va, Formula Vb or Formula Vc: 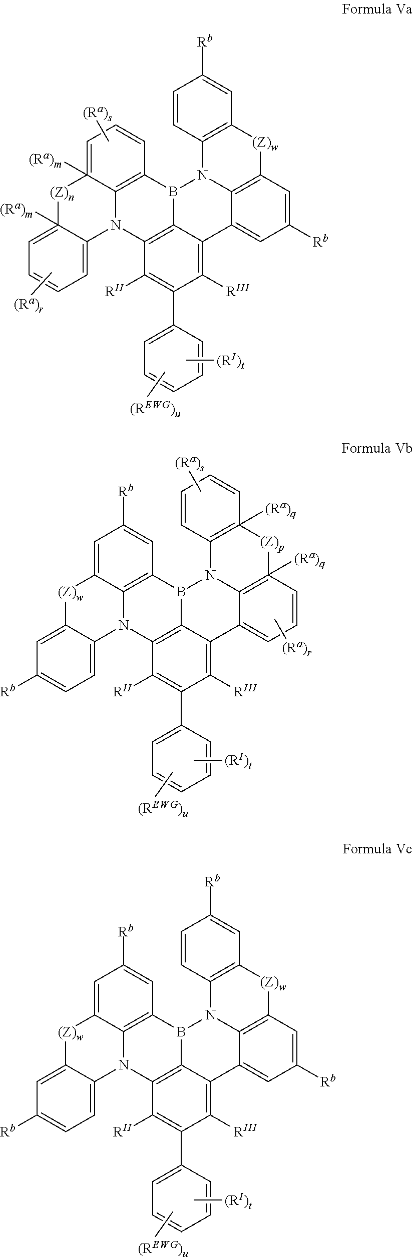
Formula Vc
wherein
w is at each occurrence independently an integer selected from the group of 0 and 1;
R^{b} is at each occurrence independently from another selected from the group consisting of hydrogen, deuterium, N(R⁵)₂, OR⁵, Si(R⁵)₃, B(OR⁵)₂, OSO₂R⁵, CF₃, CN, F, Br, I,
C₁-C₄₀-alkyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-alkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₁-C₄₀-thioalkoxy,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkenyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₂-C₄₀-alkynyl,
which is optionally substituted with one or more substituents R⁵ and
wherein one or more non-adjacent CH₂-groups are optionally substituted by R⁵C═CR⁵, C≡C, Si(R⁵)₂, Ge(R⁵)₂, Sn(R⁵)₂, C═O, C═S, C═Se, C═NR⁵, P(═O)(R⁵), SO, SO₂, NR⁵, O, S or CONR⁵;
C₆-C₆₀-aryl,
which is optionally substituted with one or more substituents R⁵; and
C₂-C₅₇-heteroaryl,
which is optionally substituted with one or more substituents R⁵.

10. A composition, comprising:
(a) an organic molecule according to claim 1,
(b) a host material, which differs from the organic molecule, and
(c) optionally, a dye and/or a solvent.

11. The composition according to claim 10, wherein the composition comprises 0.1-30% by weight of the organic molecule.

12. An optoelectronic device, comprising the organic molecule according to claim 1.

13. The optoelectronic device according to claim 12, wherein the optoelectronic device is selected from the group consisting of:
organic diodes,
organic light-emitting diodes (OLEDs),
light-emitting electrochemical cells,
OLED-sensors,
organic solar cells,
organic transistors,
organic field-effect transistors,
organic lasers, and
down-conversion elements.

14. The optoelectronic device according to claim 12, comprising:
a substrate,
an anode, and
a cathode, wherein the anode or the cathode is on the substrate, and
a light-emitting layer, which is arranged between the anode and the cathode and which comprises the organic molecule.

15. A method for generating light with a wavelength from 440 nm to 560 nm, the method comprising:
(i) providing an optoelectronic device according to claim 12; and
(ii) applying an electrical current to the optoelectronic device.
